(19) United States
(12) Patent Application Publication
(10) Pub. No.: US 2025/0141470 A1
(43) Pub. Date: May 1, 2025

(54) DATA PROCESSING METHODS AND APPARATUS FOR USE WITH FEATURE MAPS IN SPARSE CONVOLUTIONAL NEURAL NETWORKS

(71) Applicant: Western Digital Technologies, Inc., San Jose, CA (US)

(72) Inventors: Vikram Varadarajan Kalkunte, Pleasanton, CA (US); Matheus Almeida Ogleari, Santa Clara, CA (US); Anand K Kulkarni, San Jose, CA (US); Daniel Joseph Linnen, Limestone, TN (US)

(21) Appl. No.: 18/386,191

(22) Filed: Nov. 1, 2023

(51) Int. Cl. H03M 7/30; G06F 7/50; G06F 7/523

(52) U.S. Cl. CPC H03M 7/6058; G06F 7/50; G06F 7/523

(57) ABSTRACT

A convolutional neural network (CNN) system is provided that includes a flexible accelerator configured to convert an input feature map into a set of input sub-feature maps, each having a similar amount of sparsity. The system allows each of the sub-feature maps to be processed independently while taking advantage of the sparsity. In some aspects, the CNN system is configured with an index processor that receives data value indexes and weight indexes and generates data path processor commands for processing by a separate data path processor. In other aspects, unroll circuitry is configured to unroll feature maps to provide index-value compression. The unroll/compression scheme allows an input feature map to be read sequentially (tile-by-tile) so that an accumulate buffer can be implemented with a single read-only path and single write-only path. This can simplify memory control design, eliminating requirements for expensive cache-like structures while also reducing power.

### FIELD

The disclosure relates, in some aspects, to convolutional neural networks (CNNs). More specifically, but not exclusively, the disclosure relates to data processing methods such as compression schemes for reducing an amount of memory to be accessed for use with CNNs.

### INTRODUCTION

Deep learning (which also may be referred to as deep structured learning or hierarchical learning) relates to machine learning methods based on learning data representations or architectures, such as deep neural networks (DNNs), rather than to task-specific procedures or algorithms. Deep learning is applied to such fields as speech recognition, computer vision, and self-driving vehicles.

A convolutional neural network (CNN) is a type of DNN that uses a convolution mathematical operation in place of general matrix multiplication. CNNs are often designed to process pixel data for use in image recognition and processing. For example, a CNN can take in an input image, assign importance (e.g., learnable weights and biases) to various aspects/objects in the image, and then differentiate various aspects/objects from other aspects/objects within the image to provide image recognition. The CNN may employ multiple layers of processing between its input and output. Depending upon the size of the input image and the number of layers in the CNN, a massive amount of data may need to be processed.

One particularly useful CNN is the Flexible Accelerator for Sparse Tensors in CNN (FAST-CNN), described in U.S. Pat. No. 11,462,003, issued Oct. 4, 2022, entitled “Flexible accelerator for sparse tensors in convolutional neural networks,” to Gunnam et al., which is assigned to the assignee of the present application and is fully incorporated by reference herein. It would be advantageous to provide improvements to FAST CNN or other convolutional systems to, e.g., reduce the amount of memory that needs to be accessed by the CNN and to reduce the complexity of its index manipulation and arithmetic operations.

Aspects of the present disclosure are directed to these and other ends.

### SUMMARY

The following presents a simplified summary of some aspects of the disclosure to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present various concepts of some aspects of the disclosure in a simplified form as a prelude to the more detailed description that is presented later.

One embodiment of the disclosure provides a system that includes: a multiplication component comprising a plurality of multipliers, each of the plurality of multipliers configured to receive a data value and a weight value to generate a product value in a convolution operation of a machine learning application; an accumulator configured to receive the product value from each of the plurality of multipliers; a register bank configured to store an output of the convolution operation; and an unroll controller configured to control the operations of the accumulator and the register bank in accordance with an unroll sequence, wherein the accumulator is further configured to receive a portion of values stored in the register bank and combine the received portion of values with the product values to generate combined values; wherein the register bank is further configured to replace the portion of values with the combined values, wherein the data values comprise feature maps and wherein the feature maps are unrolled by the unroll controller in sequence to provide index-value compression.

Another embodiment of the disclosure provides a method that includes: receiving, using a multiplication component, a data value and a weight value into each of a plurality of multipliers to generate a plurality of product values in each iteration of a plurality of iterations of a convolution operation of a machine learning application; combining, using an accumulator, each of the plurality of product values in each iteration of the plurality of iterations, with one of a plurality of accumulator values in the accumulator to generate a plurality of combined values, wherein the plurality of accumulator values are received from a register bank; replacing, using the register bank, the plurality of accumulator values with the plurality of combined values in the register bank in each iteration of the plurality of iterations; and controlling the operations of the accumulator and the register bank in accordance with an unroll sequence, wherein the accumulator receives a portion of values stored in the register bank and combines the received portion of values with the product values to generate combined values; wherein the register bank replaces the portion of values with the combined values, wherein the data values comprise feature maps and wherein the feature maps are unrolled by the unroll controller in sequence to provide index-value compression.

Yet another embodiment of the disclosure provides an apparatus that includes: means for applying a data value and a weight value to each of a plurality of means for multiplying to generate a plurality of product values in each iteration of a plurality of iterations of a convolution operation of a machine learning application; means for accumulating each of the plurality of product values in each iteration of the plurality of iterations with one of a plurality of accumulator values to generate a plurality of combined values, wherein the plurality of accumulator values are received from a means for registering data; means for replacing the plurality of accumulator values with the plurality of combined values in the means for registering data in each iteration of the plurality of iterations; and means for controlling the operations of the means for accumulating and the means for registering in accordance with an unroll sequence, wherein the means for accumulating receives a portion of values stored in the means for registering data and combines the received portion of values with the product values to generate combined values; wherein the means for registering data replaces the portion of values with the combined values, wherein the data values comprise feature maps and wherein the feature maps are unrolled by the means for controlling in sequence to provide index-value compression.

### BRIEF DESCRIPTION OF THE DRAWINGS

FIG. 1 is an example block diagram of a computing system, in accordance with some embodiments of the present disclosure.

FIG. 2 is an example block diagram of an accelerator of the computing system of FIG. 1, in accordance with some embodiments of the present disclosure.

FIGS. 3A and 3B are examples for converting an input feature map into a plurality of sub-feature maps, in accordance with some embodiments of the present disclosure.

FIG. 4 is an example block diagram of a sparse tensor memory cluster of the accelerator of FIG. 2, in accordance with some embodiments of the present disclosure.

FIG. 5 is another example block diagram of the sparse tensor memory cluster of the accelerator of FIG. 2, in accordance with some embodiments of the present disclosure.

FIG. 6 is an example block diagram of a sparse tensor feature map memory unit of the sparse tensor memory clusters of FIGS. 4 and 5, in accordance with some embodiments of the present disclosure.

FIG. 7 is an example block diagram of a sparse tensor weight memory of the sparse tensor memory clusters of FIGS. 4 and 5, in accordance with some embodiments of the present disclosure.

FIG. 8 is an example block diagram of a sparse tensor compute cluster of the accelerator of FIG. 2, in accordance with some embodiments of the present disclosure.

FIG. 9 is another example block diagram of the sparse tensor compute cluster of the accelerator of FIG. 2, in accordance with some embodiments of the present disclosure.

FIG. 10 is an example block diagram of a sparse tensor compute unit of the sparse tensor compute clusters of FIGS. 8 and 9, in accordance with some embodiments of the present disclosure.

FIG. 11 is an example of processing a sub-feature map in the sparse tensor compute unit of FIG. 10, in accordance with some embodiments of the present disclosure.

FIG. 12 is an example flowchart outlining operations for processing the sub-feature map in the sparse tensor compute unit of FIG. 10, in accordance with some embodiments of the present disclosure.

FIG. 13 is another example of the sparse tensor compute unit of the sparse tensor compute clusters of FIGS. 8 and 9, in accordance with some embodiments of the present disclosure.

FIG. 14 is yet another example of the sparse tensor compute unit of the sparse tensor compute clusters of FIGS. 8 and 9, in accordance with some embodiments of the present disclosure.

FIG. 15 is one more example of the sparse tensor compute unit of the sparse tensor compute clusters of FIGS. 8 and 9, in accordance with some embodiments of the present disclosure.

FIG. 16 is an example flowchart outlining operations for processing a sub-feature map in the sparse tensor compute units of FIGS. 13-15 in a standard convolution operation or in a 1×1 fully connected convolution operation, in accordance with some embodiments of the present disclosure.

FIG. 17 is an example flowchart outlining operations for processing an input feature map using the accelerator of FIG. 2, in accordance with some embodiments of the present disclosure.

FIGS. 18A-18D show an example of processing a sub-feature map in the sparse tensor compute unit of FIG. 13, in accordance with some embodiments of the present disclosure.

FIGS. 19A-19E show an example of processing a sub-feature map in the sparse tensor compute unit of FIG. 15, in accordance with some embodiments of the present disclosure.

FIGS. 20A-20B show an example of a merging operation, in accordance with some embodiments of the present disclosure.

FIG. 21 shows an exemplary input feature map, a portion of an output feature map, and various exemplary weights, in accordance with some embodiments of the present disclosure.

FIG. 22 shows an exemplary convolution result, which in this example is 8×8 output feature map, in accordance with some embodiments of the present disclosure.

FIG. 23 shows an exemplary 3×3 kernel showing some sparsity, an exemplary 6×9 input feature-map, an exemplary output feature map not yet populated with values, and an expected output feature map with exemplary values, in accordance with some embodiments of the present disclosure.

FIG. 24 illustrates the same kernel, input feature-map, output feature map and expected output feature map of FIG. 23, but with arrows illustrating aspects of initial convolution operations, in accordance with some embodiments of the present disclosure.

FIG. 25 illustrates the same kernel, input feature-map, output feature map and expected output feature map of FIGS. 23 and 24, with arrows illustrating a first operational stage of the convolution operations, in accordance with some embodiments of the present disclosure.

FIG. 26 illustrates the same kernel, input feature-map, output feature map and expected output feature map of FIGS. 23-25, with arrows illustrating a second operational stage of the convolution operations, in accordance with some embodiments of the present disclosure.

FIG. 27 illustrates the same kernel, input feature-map, output feature map and expected output feature map of FIGS. 23-26, with additional intermediate values, in accordance with some embodiments of the present disclosure.

FIG. 28 provides a high level overview of an exemplary hardware architecture that to implement a CNN system, in accordance with some embodiments of the present disclosure.

FIG. 29 illustrates features of an exemplary index processor, in accordance with some embodiments of the present disclosure.

FIG. 30 illustrates an exemplary data path processor, in accordance with some embodiments of the present disclosure.

FIG. 31 illustrates exemplary components of a vector accumulator register, in accordance with some embodiments of the present disclosure.

FIG. 32 illustrates an array of accumulator elements that form a 2D registration file of a vector accumulator register, in accordance with some embodiments of the present disclosure.

FIG. 33 illustrates exemplary values for use within an accumulate buffer 3006, in accordance with some embodiments of the present disclosure.

FIG. 34 illustrates aspects of an exemplary depthwise convolution mode, in accordance with some embodiments of the present disclosure.

FIG. 35 illustrates an exemplary system that includes index processing circuitry and data path processing circuitry, in accordance with some embodiments of the present disclosure.

FIG. 36 illustrates an exemplary method that may be performed using index processing circuitry and data path processing circuitry, in accordance with some embodiments of the present disclosure.

FIG. 37 illustrates an exemplary system that includes that includes an unroll controller configured to provide index-value compression, in accordance with some embodiments of the present disclosure.

FIG. 38 illustrates an exemplary method for index-value compression, in accordance with some embodiments of the present disclosure.

### DETAILED DESCRIPTION

In the following detailed description, reference is made to the accompanying drawings, which form a part thereof. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

As noted above, the FAST-CNN system provides a particularly useful CNN system. FAST-CNN is configured to reduce overall computation time and/or the amount of data to be processed by exploiting sparsity. Sparsity relates to the number or percentage of non-zeroes within the data to be processed. Pruning synapses and neurons in a neural network based on sparsity can be used to reduce the amount of data to be computed, e.g., by more than ten times, with negligible accuracy loss. Sparsity may be either static or dynamic. Static sparsity is known beforehand and does not change from one set of input data to another set of input data. The sparsity in CNN weights is a type of static sparsity. For example, the weights that are zero or non-zero may be known before the computation on the input data has begun. Furthermore, the weights that are zero or non-zero may remain the same from one set of input data to the next.

Dynamic sparsity is the sparsity present in an input feature map of the input data. More specifically, from input data (e.g., an input image), one or more input feature maps may be generated by a CNN system. Each of the input feature maps may be combined with associated weights to perform a classification process. Each input feature map may have either zero values or non-zero values. The number or percentage of non-zero values in a given input feature map may determine the sparsity of that input feature map. Since each input feature map may be different from each other input feature map, and the location of the zero and non-zero values may change from one input feature map to another, the sparsity in an input feature map is dynamic sparsity. Since static sparsity is easier to identify and consider in a machine learning operation, many mechanisms that reduce the amount of data to be computed rely on static sparsity only. The irregularity caused by dynamic sparsity prevents many such mechanisms from fully leveraging the computation and data reduction.

The FAST-CNN system of U.S. Pat. No. 11,462,003 (incorporated by reference above) provided mechanisms and procedures to transform dynamic and random sparsity into a (more or less) structured sparsity for reducing both the amount of data to be computed, as well as for the computation time. In particular, FAST-CNN provides a flexible accelerator configured to convert an input feature map into a set of input sub-feature maps, each having a similar amount of sparsity. FAST-CNN allows each of the sub-feature maps to be processed independently while taking advantage of the sparsity.

Herein, improvements are provided to FAST CNN (or other suitable convolutional systems) to, e.g., reduce the amount of memory that needs to be accessed and to reduce the complexity of index manipulation and arithmetic operations. In some aspects, a compression scheme is provided that uses an unroll sequence for feature maps/weights that allows memory elements (e.g., feature maps, weights and accumulate buffer results) to be accessed only once. Hence, despite irregular accesses to input (feature-maps/weights) and output (accumulate buffer results) due to sparsity aware processing, the unroll/compression scheme allows sequential, one-time access on the memory units. Before describing the details of these and other improvements, further information regarding the FAST-CNN system will be provided.

### Exemplary Fast-CNN System

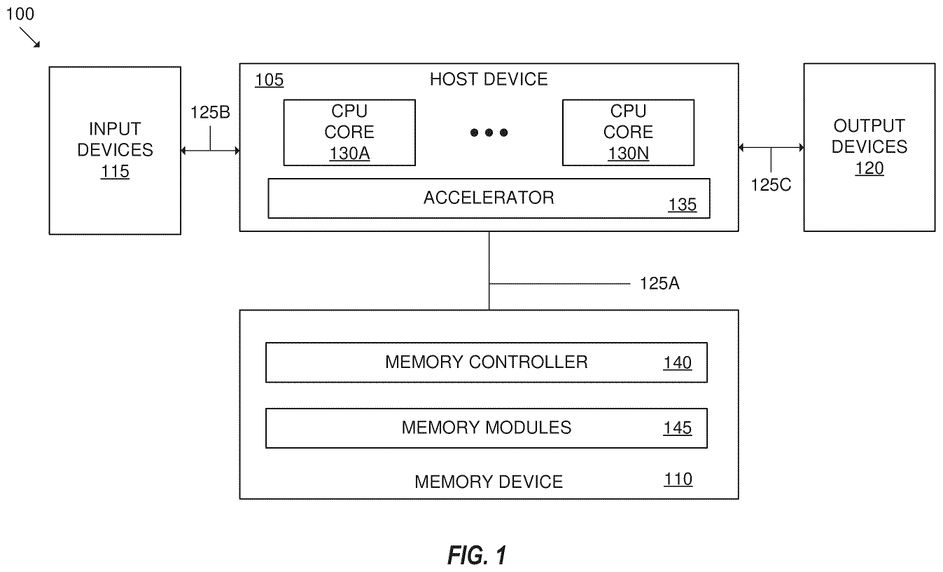

Referring now to FIG. 1, an example block diagram of a computing system 100 is shown, in accordance with some embodiments of the disclosure. The computing system 100 may include a host device 105 associated with a memory device 110. The host device 105 may be configured to receive input from one or more input devices 115 and provide output to one or more output devices 120. The host device 105 may be configured to communicate with the memory device 110, the input devices 115, and the output devices 120 via appropriate interfaces 125A, 125B, and 125C, respectively. The computing system 100 may be implemented in a variety of computing devices such as computers (e.g., desktop, laptop, servers, data centers, etc.), tablets, personal digital assistants, mobile devices, wearable computing devices such as smart watches, other handheld or portable devices, or any other computing unit suitable for performing operations using the host device 105.

The input devices 115 may include any of a variety of input technologies such as a keyboard, stylus, touch screen, mouse, track ball, keypad, microphone, voice recognition, motion recognition, remote controllers, input ports, one or more buttons, dials, joysticks, and any other input peripheral that is associated with the host device 105 and that allows an external source, such as a user, to enter information (e.g., data) into the host device and send instructions to the host device. Similarly, the output devices 120 may include a variety of output technologies such as external memories, printers, speakers, displays, microphones, light emitting diodes, headphones, plotters, speech generating devices, video devices, global positioning systems, and any other output peripherals that are configured to receive information (e.g., data) from the host device 105. The “data” that is either input into the host device 105 and/or output from the host device may include any of a variety of textual data, graphical data, video data, image data, sound data, position data, combinations thereof, or other types of analog and/or digital data that is suitable for processing using the computing system 100.

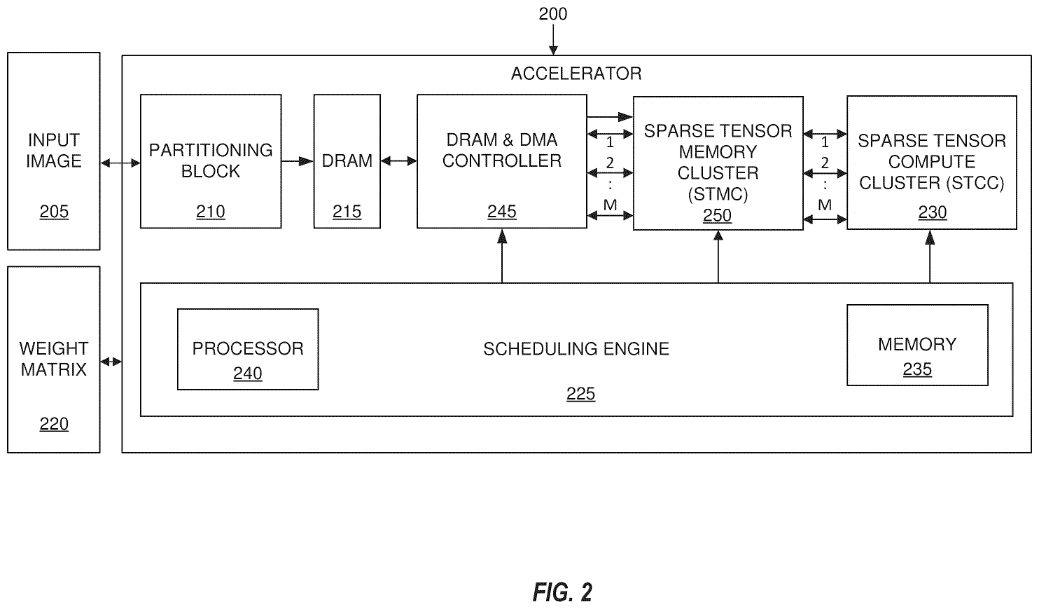

The host device 105 may include one or more Central Processing Unit (“CPU”) cores or processors 130A-130N that may be configured to execute instructions for running one or more applications associated with the host device. The CPU cores 130A-130N are shown as a non-limiting representative example of integrated circuits that can perform processing functions, and may be substituted and/or combined with Field Programmable Gate Array (“FPGA”), Graphical Processing Unit (“GPU”), custom Application Specific Integrated Circuit (“ASIC”), and the like. In some embodiments, the instructions and data needed to run the one or more applications may be stored within the memory device 110. The host device 105 may also be configured to store the results of running the one or more applications within the memory device 110. The host device 105 may also include an accelerator 135. The accelerator 135 may be used to perform machine learning operations. The accelerator 135 is discussed in greater detail in FIG. 2. Although the accelerator 135 is shown as being part of the host device 105 in FIG. 1, in other embodiments, the accelerator may be apart from the host device and communicatively coupled (e.g., through a bus or network connection) to the host device. In such a case, the accelerator 135 may also be communicatively coupled to the memory device 110, be a part of the memory device 110, or include its own separate memory device. The memory device 110 may be any type of volatile or non-volatile (persistent) storage device, including processor memory/caches, DRAM, or NAND storage devices.

To facilitate communication with the memory device 110, the memory device may include or be associated with a memory controller 140. Although the memory controller 140 is shown as being part of the memory device 110, in some embodiments, the memory controller may instead be part of the host device 105 or another element of the computing system 100 and operatively associated with the memory device. The memory controller 140 may be configured as a logical block or circuitry that receives instructions from the host device 105 (e.g., the accelerator 135) and performs operations in accordance with those instructions. The memory device 110 may include one or more memory modules 145 that store data and instructions. The memory modules 145 may be any of a variety of memory types, including a variety of volatile memories, non-volatile memories, or a combination thereof. For example, in some embodiments, one or more of the memory modules 145 or portions thereof may include NAND flash memory cores. In other embodiments, one or more of the memory modules 145 or portions thereof may include NOR flash memory cores, Static Random Access Memory (SRAM) cores, Dynamic Random Access Memory (DRAM) cores, Magnetoresistive Random Access Memory (MRAM) cores, Phase Change Memory (PCM) cores, Resistive Random Access Memory (ReRAM) cores, 3D XPoint memory cores, ferroelectric random-access memory (FeRAM) cores, and other types of memory cores that are suitable for use within the memory device 110. In some embodiments, one or more of the memory modules 145 or portions thereof may be configured as other types of storage class memory (“SCM”). Generally speaking, the memory modules 145 may include any of a variety of Random Access Memory (RAM), Read-Only Memory (ROM), Programmable ROM (PROM), Erasable PROM (EPROM), Electrically EPROM (EEPROM), hard disk drives, flash drives, memory tapes, cloud memory, or any combination of primary and/or secondary memory that is suitable for performing the operations described herein.

It is to be understood that only some components of the computing system 100 are shown and described in FIG. 1. However, the computing system 100 may include other components such as various batteries and power sources, networking interfaces, routers, switches, external memory systems, controllers, etc. Generally speaking, the computing system 100 may include any of a variety of hardware, software, and/or firmware components that are needed or considered desirable in performing the functions described herein. Similarly, the host device 105, the input devices 115, the output devices 120, and the memory device 110 including the accelerator 135, the memory controller 140, and the memory modules 145 may include other hardware, software, and/or firmware components that are considered necessary or desirable in performing the functions described herein. In addition, in certain embodiments, the memory device 110 may integrate some or all of the components of the host device, including, for example, the CPU cores 130A-130N and/or the accelerator 135.

Turning now to FIG. 2, an example accelerator 200 is shown, in accordance with some embodiments of the present disclosure. The accelerator 200 is analogous to the accelerator 135 of FIG. 1. Thus, although not shown, the accelerator 200 may be associated with a host device (e.g., the host device 105) and a memory device (e.g., the memory device 110). The accelerator 200 may be used to optimize machine learning operations, for example, in a CNN. Although the accelerator 200 is explained with respect to CNN, in other embodiments, the accelerator 200 may be used in other types of neural networks or machine learning applications as well. Generally speaking, the accelerator 200 may be used in any type of application (whether machine learning or otherwise) that desires to reduce computation data and computation time.

In some embodiments, the accelerator 200 may be used to consider dynamic and static sparsity in the input feature maps and the weights, respectively, and allocate computation amongst various compute engines based on the dynamic and static sparsity. The accelerator 200 may receive an input image 205 (e.g., from the host device 105) on which one or more machine learning operations are to be performed. It is to be understood that although the input image 205 is used herein as an example, the accelerator 200 may be used to process other types of data including video, text, and any other type of data that may benefit from being processed by the accelerator.

The input image 205 may be represented by an array of pixels. Simply as an example and without intending to be limited in any way, say the input image 205 is represented by a 1024×1024×3 array of pixels. Thus, the input image 205 is 1024 pixels high, 1024 pixels wide, and 3 colors (e.g., Red, Green, Blue) deep. In some embodiments, the 1024×1024×3 array of pixels may be divided into three input feature maps, with each input feature map representing one color and being of size 1024×1024×1 (also referred to herein as simply 1024×1024). Further, each input feature map may be represented as a matrix having a plurality of rows and a plurality of columns. Each row extends in an X-direction (left-right), while each column extends in a Y-direction (up-down). Each pixel of an input feature map may correspond to one cell (e.g., formed at the intersection of one row and one column) of the matrix. Thus, a 1024×1024 input feature map may be represented by a matrix having 1024 rows and 1024 columns, with the intersection of each row and each column forming one cell for one pixel.

In some embodiments, the input feature maps of the input image 205 may be generated by the accelerator 200. For example, in some embodiments, a partitioning block 210 may be configured to generate the input feature maps from the input image 205. In other embodiments, a feature map block (not shown) of the accelerator 200 may receive the input image 205, and generate the input feature maps therefrom, and send those input feature maps to the partitioning block 210. In yet other embodiments, the input feature maps of the input image 205 may be generated outside of the accelerator 200, and instead of the input image, the input feature maps may be input into the accelerator. The partitioning block 210 may be configured in software, hardware, firmware, or combinations thereof.

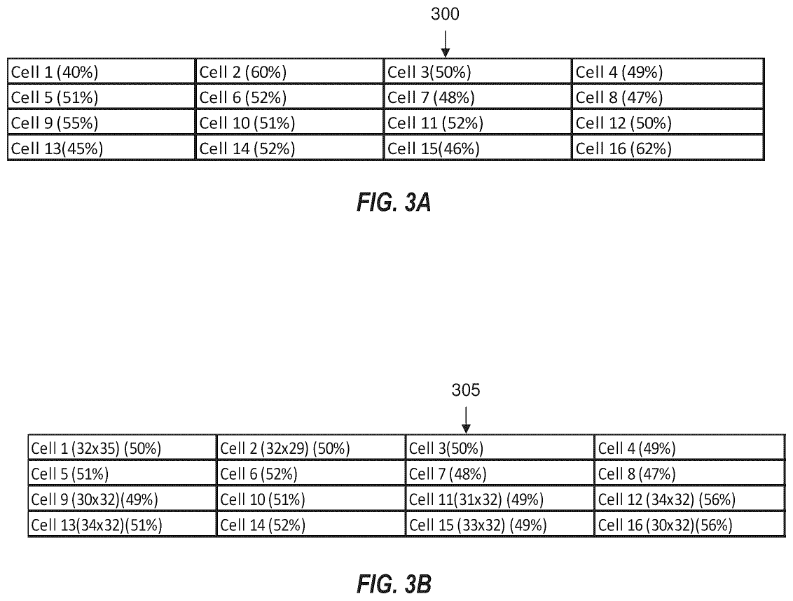

Each of the input feature maps of the input image 205 may be further sub-divided into one or more sub-feature maps in the partitioning block 210. The sub-division of an input feature map into one or more sub-feature maps in the partitioning block 210 is discussed in FIGS. 3A and 3B below. Each sub-feature map is also referred to herein as an “input tensor.” By dividing an input feature map into one or more sub-feature maps, each of the sub-feature maps may be independently processed to generate an output sub-feature map and to increase performance. The output sub-feature maps from each of the sub-feature maps may then be combined together to create an output feature map. When the image 205 includes multiple channels, the input feature maps of each channel may be sub-divided into one or more sub-feature maps, each of the sub-feature maps may be processed independently to generate an output sub-feature map, and the output sub-feature maps of each of the one or more sub-feature maps may be combined to generate a channel output feature map. The various channel output feature maps may then be combined to generate the output feature map. Such convolution operations that involve multiple channels are referred to herein as “depthwise separable convolution.” In some embodiments, the input feature maps and/or each of the sub-feature maps may be compressed to reduce storage space and further increase performance. The process of compressing as used throughout this disclosure is discussed in greater detail in U.S. application Ser. No. 16/726,084, titled “Flexible Accelerator For Sparse Tensors (FAST) in Machine Learning” and filed on Dec. 23, 2019, the entirety of which is incorporated by reference herein.

The partitioning block 210 may be associated with a DRAM 215 that may be configured to initially store the input feature maps of the input image 205, and upon sub-dividing the input feature maps into one or more sub-feature maps, store each of the one or more sub-feature maps. The DRAM 215 may also be used to store any intermediate outputs (e.g., the output sub-feature map, channel output feature map, etc.) and/or the output feature map. In some embodiments, the DRAM 215 may also be configured to store a weight matrix 220. In some embodiments, the DRAM 215 may also store various training models, schedules, and other information needed to process the input image 205. Further, although only the DRAM 215 is shown in the accelerator 200, in some embodiments, the accelerator may include additional and/or other types of memories. For the sake of simplicity, the DRAM 215 is used in the description, but other memory substitutes are contemplated for various embodiments. For example, in some embodiments, the accelerator 200 may additionally or alternatively include SRAM, storage class memory such as MRAM, ReRAM, and/or flash memories to store the input feature maps, the one or more sub-feature maps, various outputs, training models, schedules, and/or other information needed to process the input image 205. When such multiple memories are provided in the accelerator 200, in some embodiments, these memories may be interconnected with each other and configured to communicate with each other. In some embodiments, the DRAM 215 and any other memory in the accelerator 200 may be part of the memory device (e.g., the memory device 110) associated with the host device (e.g., the host device 105) of which the accelerator is part of. In some embodiments, one or more of the DRAM 215 and any other memory in the accelerator 200 may be separate from the memory device (e.g., the memory device 110).

In addition to the input image 205, the accelerator 200 also receives the weight matrix 220 (e.g., from the host device 105). The weight matrix 220 may include weights or filters that are to be applied to each of the sub-feature maps. The weight matrix 220 is also referred to herein as a kernel matrix or a filter matrix. The weight matrix 220 may include at least one row and at least one column, forming cells at the intersection of rows and columns. The weight matrix 220 may be used to perform the convolution operations on the input image 205. In some embodiments, the weight matrix 220 may also be sub-divided into one or more sub-weight maps similar to the input feature maps. In some embodiments, the weight matrix 220 and/or the sub-weight maps may also be compressed similar to the input feature maps/sub-feature maps. In some embodiments, the weight matrix 220 may be received by a scheduling engine 225. In other embodiments, the weight matric 220 may be received by the partitioning block 210 or by another component of the accelerator 200. Further, if the weight matrix 220 is sub-divided into sub-weight maps and/or compressed, these processes may occur within the scheduling engine 225 in some embodiments. In other embodiments, these processes may occur in the portioning block 210, in a separate partitioning block in the accelerator 200 dedicated to the weight matrix 220, and/or outside the accelerator. The weight matrix 220 and/or the sub-weight maps may be stored within the DRAM 215, the scheduling engine 225, or in any other memory of the accelerator 200.

The scheduling engine 225 is configured to perform a sparsity analysis, and assign, in some embodiments, each of the input feature maps to a compute unit based upon the sparsity. As used herein, “sparsity” means the number or percentage of non-zeroes in a given input data. In some embodiments, an input feature map that has more non-zeroes than zeroes is a less sparse input feature map or a dense input feature map, whereas an input feature map that has more zeroes than non-zeroes is a sparse input feature map. In other embodiments, a sparse input feature map may be defined as having at least a certain percentage of zeros (e.g., 80%), and a dense input feature map may have more zeroes than non-zeroes (e.g., 60:40). More generally, a sparse input feature map has more zeros than a dense input feature map. Thus, to perform the sparsity analysis, the scheduling engine 225 may determine the number or percentage of zeroes or non-zeroes in an input feature map. Further, the scheduling engine 225 may assign or allocate a sparse input feature map to a sparse tensor compute cluster 230 for processing. Thus, the sparse tensor compute cluster 230 is configured to process input feature maps having higher sparsity (e.g., number or percentage of zeroes above a threshold, or in other words, more zero values than non-zero values). The sparse tensor compute cluster 230 is discussed in greater detail below.

In some embodiments, the accelerator 200 may also include a dense tensor compute cluster (not shown in FIG. 2) and/or a vector accelerator (also not shown in FIG. 2). If provided, the dense tensor compute cluster may be configured to process feature maps having lower sparsity (e.g., dense input feature maps or input feature maps in which the number or percentage of zeroes is below a threshold, or in other words, having more non-zero values than zero values) and the vector accelerator may be used to process input feature maps that cannot be processed by either the dense tensor compute cluster or the sparse tensor compute cluster 230. For example, in some embodiments where the dense tensor compute cluster and/or a vector accelerator are provided, the dense tensor compute cluster and the sparse tensor compute cluster 230 may be configured with a defined or supported list of operations that the dense tensor compute cluster and the sparse tensor compute cluster, respectively, may be able to perform. If the processing requires performing an operation that is not supported by either of the dense tensor compute cluster or the sparse tensor compute cluster 230, then that operation may be performed by the vector accelerator. In some embodiments, the vector accelerator may be an open source vector accelerator based on RISC-V such as LACore. In other embodiments, other types of suitable vector accelerators may be used for the vector accelerator. The dense tensor compute cluster and the vector accelerator are discussed in greater detail in the U.S. application Ser. No. 16/726,084 mentioned above, again the entirety of which is incorporated by reference herein.

The scheduling engine 225 may include a memory 235 to store computer-readable instructions that may be executed by a processor 240 to perform the operations of the scheduling engine 225. The memory 235 may be part of the memory device (e.g., the memory device 110) of the host device (e.g., the host device 105) of which the accelerator 200 is part of, or may be provisioned from a separate memory. Further, the scheduling engine 225 may be implemented as software, hardware, firmware, or combination thereof. The processor 240 may be part of or may be similar to the CPU cores 130A-130N of the host device 105, or in the case when the accelerator is part of the memory device 110, part of a processor or controller of the memory device.

For processing an input feature map in the sparse tensor compute cluster 230, the accelerator 200 may also include a direct memory access controller 245 configured to transfer the sub-feature maps from the DRAM 215 to a sparse tensor memory cluster 250 with minimal intervention from the scheduling engine 225 or the sparse tensor compute cluster. The sparse tensor memory cluster 250 is also discussed in greater detail below. It is noted while direct memory access is used as an example for illustration, other type of memory access protocols/methods may be used, including memory access across communication buses and memory fabrics.

It is to be understood that only some components of the accelerator 200 are shown in FIG. 2. The accelerator 200 may include other or additional components that may be needed or considered desirable in performing the operations described herein.

Turning to FIGS. 3A and 3B, an example of dividing an input feature map into one or more sub-feature maps or input tensors in the partitioning block 210 is shown, in accordance with some embodiments of the present disclosure. Specifically, an input feature map that is a sparse input feature map and has been designated to be processed in the sparse tensor compute cluster 230 may be sub-divided into one or more sub-feature maps. Specifically, each input feature map for each channel may be divided into “M” sub-feature maps. “M” is dependent upon a number of sparse tensor compute units provided within the sparse tensor compute cluster 230 and/or the number of parse tensor feature map memory units in the sparse tensor memory cluster 250. For example, for five sparse tensor compute units in the sparse tensor compute cluster 230, each input feature map of each channel may be divided into five sub-feature maps. By dividing each input feature map into “M” sub-feature maps corresponding to “M” number of sparse tensor compute units in the sparse tensor compute cluster 230, each of the “M” sub-feature maps may be processed independently in one of the “M” sparse tensor compute units to increase performance and reduce computation time.

In some embodiments, each of the “M” sub-feature maps may be a matrix have overlapping (k−1, as an example) rows and (k−1, as an example) columns with neighboring sub-feature maps, where (k×k) is the size of the weight matrix 220. By overlapping rows and columns of one sub-feature map with a neighboring sub-feature map, each sub-feature map may be processed independently in the sparse tensor compute cluster 230 and the output sub-feature maps of each of the sub-feature maps may be combined together without needing any intra-cluster communication between the “M” sub-feature maps to create an output feature map. In other embodiments, the “M” sub-feature maps may have no overlapping rows and/or columns. Without overlapping, the intermediate results from neighboring sub-feature maps may need to be combined. In some embodiments, with a kernel size of 1×1, overlapping rows and/or columns of the neighboring sub-feature maps may not be needed.

Each input feature map may be divided into “M” sub-feature maps based on sparsity, and specifically, to convert the dynamic nature of sparsity in the input feature map into close to static sparsity. Simply as an example and without intending to be limiting in any way, say the input feature map of a particular channel of the input image 205 is 512×512 in size (e.g., 512 rows and 512 columns), and the number of sparse tensor compute units in the sparse tensor compute cluster 230 is 16 (in other words, “M”=16). Thus, the 512×512 input feature map may be divided into 16 sub-feature maps, with each sub-feature map being assigned to one of the 16 sparse tensor compute units of the sparse tensor compute cluster 230. To create the 16 sub-feature maps, the 512×512 input feature map may be initially divided into 16 equal sized or roughly equal sized partitions, such that each partition has a number of rows and a number of columns.

For example, FIG. 3A shows an example table 300 after dividing the 512×512 input feature map into 16 sub-feature maps (e.g., generally represented by cell 1-cell 16). Thus, each of the 16 partitions of the 512×512 input feature map may be 32×32 (e.g., 32 rows and 32 columns) in size. Each cell of the table 300 corresponds to one 32×32 partition of the input feature map. The value in the parenthesis in each cell in FIG. 3A indicates the percentage of non-zeroes in that particular cell. Thus, for example, cell 1 of the table 300 corresponds to the first partition (e.g., rows 1 to 32 and columns 1 to 32 of the input feature map) and includes 40% non-zeroes (and therefore, 60% zeroes), cell 2 corresponds to the second partition (e.g., rows 1 to 32 and columns 33-64) and includes 60% non-zeroes (and therefore, 40% zeroes), and so on. Cell 5 corresponds to the fifth partition (rows 33 to 64 and columns 1 to 32 of the input feature map) and includes 51% non-zeroes, and so on. In the example of FIG. 3A, there is no overlap in the rows and columns of the 16 sub-feature maps. However, as discussed above, in some embodiments, at least some of the sub-feature maps may have overlapping rows and/or columns with neighboring sub-feature maps. In such cases, the number of the sub-feature maps may vary from 16 in the example of FIG. 3A.

The initial partitions of the table 300 may be reorganized such that each partition includes the same or substantially similar number or percentage of non-zeroes and/or zeroes. In some embodiments, a percentage difference of non-zeroes (or zeroes) may be pre-determined such that any two given partitions may not have a greater than the pre-determined percentage difference in the non-zeroes. As an example, if the pre-determined percentage difference in the percentage of non-zeroes between any two given partitions is 3%, the initial partitions of FIG. 3A may be reorganized such that each partition has roughly equal number of non-zeroes, with no two partitions having greater than a 3% difference in the number of non-zeroes. Thus, referring to FIG. 3B, another table 305 is shown that shows how the cells from the table 300 are reorganized. For example, cell 1 in the table 300 has 40% non-zeroes, while cell 2 in the table 300 has 60% non-zeroes. Thus, the percentage difference in the non-zeroes between cell 1 and cell 2 in table 300 is greater than the pre-determined percentage difference of 3%. Thus, cells 1 and 2 may be reorganized as shown in the table 305 by allocating columns from cell 2 to cell 1. For example, three columns from cell 2 may be allocated to cell 1 such that each of cell 1 and cell 2 has about 50% non-zeroes, thereby equalizing the number of non-zeroes in those cells.

After the reorganization, cell 1 may have 32 rows and 35 columns, and is therefore 32×35 in size, as shown in the table 305 instead of the 32×32 size in the table 300. Similarly, after the organization, cell 2 may have 32 rows and 29 columns, as shown in the table 305. Thus, cells 1 and 2 are of different sizes, as shown in the table 305. Although cell 1 is allocated 3 columns from only one neighboring cell, in some embodiments, cell 1 may be allocated rows/columns from multiple neighboring cells. For example, in some embodiments, cell 1 may be allocated 2 columns from cell 2 and 1 row from cell 5. The number of rows and/or the number of columns that are allocated from one or more cells to a particular cell may be dependent upon the number of non-zeroes (or zeroes) that are present in a particular row and/or column, and the number of non-zeroes (or zeroes) that are needed to be reallocated to satisfy the pre-determined percentage difference. Likewise, the other cells in the table 300 may be balanced out by allocating one or more rows and/or one or more columns from one or more neighboring cells until the pre-determined difference is satisfied, as shown in the table 305.

By reorganizing the initial partitions shown in the table 300, the number of non-zeroes in the various initial partitions may be balanced to balance out the processing in the sparse tensor compute cluster 230. Each cell in the table 305 corresponds to one sub-feature map or one input tensor, which may be assigned to one sparse tensor feature map memory unit of the sparse tensor memory cluster 250 and one sparse tensor compute unit of the sparse tensor compute cluster 230. Although FIGS. 3A and 3B have been explained as going from the initial partition of the table 300 to the final partition of the table 305 in a single step, in other embodiments, multiple iterations of reallocating rows/columns to/from neighboring cells may be needed to achieve the pre-determined percentage difference. Further, although FIGS. 3A and 3B have been explained with respect to the pre-determined percentage difference of non-zeroes, in other embodiments, different metrics may be used. For example, in some embodiments, instead of the percentage of non-zeroes, a percentage of zeroes may be used. That is, in some aspects, the compression notation is “flipped” so that non-zero locations are exploited or otherwise noted, rather than zero locations. That is, an inverse mapping is used. Similarly, in some embodiments, instead of the percentage, a number of zeroes or non-zeroes may be used. In yet other embodiments, metrics other than “number” may be used. Each of the sub-feature maps of FIG. 3B may be stored within the DRAM 215.

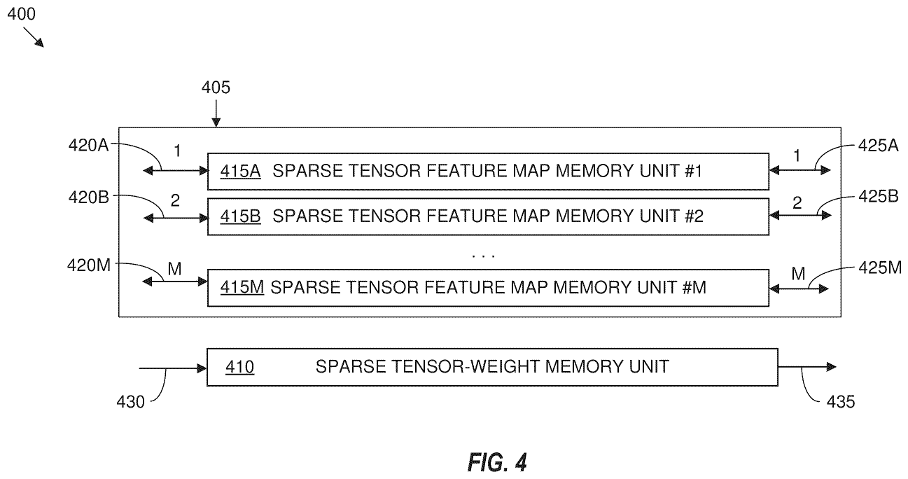

Referring to FIG. 4, an example of a sparse tensor memory cluster 400 is shown, in accordance with some embodiments of the present disclosure. The sparse tensor memory cluster 400 is analogous to the sparse tensor memory cluster 250 of FIG. 2. The sparse tensor memory cluster 400 includes a sparse tensor feature map memory 405 and a sparse tensor weight memory 410. The sparse tensor feature map memory 405 is configured to store the sub-feature maps received from the DRAM 215 and the direct memory access controller 245. The sparse tensor feature map memory 405 is also configured to store the various outputs received from the sparse tensor compute cluster 230. The sparse tensor feature map memory 405 includes a plurality of sparse tensor feature map memory units 415A-415M. The number of the plurality of sparse tensor feature map memory units 415A-415M may be dependent upon a designated number of sub-feature maps that may be desired to be processed in parallel. Each of the plurality of sparse tensor feature map memory units 415A-415M is independent from other sparse tensor feature map memory units and may be configured to store at least one sub-feature map independent from other sparse tensor feature map memory units.

Thus, in some embodiments, the plurality of sparse tensor feature map memory units 415A-415M are not configured to share the data stored therein with other ones of the plurality of sparse tensor feature map memory units. Further, each of the plurality of sparse tensor feature map memory units 415A-415M is configured to send the sub-feature map stored therein to a corresponding one of a sparse tensor compute unit of the sparse tensor compute cluster (e.g., the sparse tensor compute cluster 230). For example, in some embodiments, the sparse tensor feature map memory unit #i may be configured to send the input tensor stored therein to the sparse tensor compute unit #i, as discussed further below. Such one-to-one correspondence between a particular sparse tensor feature map memory unit and a sparse tensor compute unit is referred to herein as “static binding.” Thus, in some embodiments, the number of the plurality of sparse tensor feature map memory units 415A-415M in the sparse tensor feature map memory 405 is same as the number of sparse tensor compute units in the sparse tensor compute cluster (e.g., the sparse tensor compute cluster 230).

Further, each of the plurality of sparse tensor feature map memory units 415A-415M may be connected via a bi-directional bus 420A-420M, respectively, to receive sub-feature maps from the DRAM 215 via the direct memory access controller 245, as well as to send outputs received from the sparse tensor compute cluster 230 back to the DRAM via the direct memory access controller. Similarly, each of the plurality of sparse tensor feature map memory units 415A-415M may be connected via a bi-directional bus 425A-425M, respectively, to an associated one of the sparse tensor compute unit of the sparse tensor compute cluster (e.g., the sparse tensor compute cluster 230) to send the sub-feature maps stored therein to the sparse tensor compute cluster and to receive outputs back from the sparse tensor compute cluster.

Thus, for example, the sparse tensor feature map memory unit 415A may receive a sub-feature map from the DRAM 215 via the direct memory access controller 245 and the bus 420A for storing, and send that sub-feature map to an associated one of the sparse tensor compute unit of the sparse tensor compute cluster (e.g., the sparse tensor compute cluster 230) for processing via the bus 425A. Similarly, the sparse tensor feature map memory unit 415A may receive the output (e.g., the result from processing the sub-feature map) from the sparse tensor compute cluster (e.g., the sparse tensor compute cluster 230) via the bus 425A for storing, and send that output to the DRAM 215 via the direct memory access controller 245 and the bus 420A. The sparse tensor feature map memory units 415B-415M may function similar to the sparse tensor feature map memory unit 415A.

In some embodiments, each of the plurality of sparse tensor feature map memory units 415A-415M may also be configured to store index values of the sub-feature map that is stored therein. In addition to receiving a sub-feature map, each of the plurality of sparse tensor feature map memory units 415A-415M may also receive the index values associated with the sub-feature map from the DRAM 215. For example, if the sparse tensor feature map memory units 415A receives sub-feature map A from the DRAM 215, that sparse tensor feature map memory unit may also receive the index values corresponding to the sub-feature map A. The sparse tensor feature map memory units 415A may then send the index values of the sub-feature map A to the sparse tensor compute cluster (e.g., the sparse tensor compute cluster 230) along with sending the sub-feature map A. The index values capture the row numbers and column numbers of a particular sub-feature map in the input feature map. For example, an index value (X, Y) refers to the row number X and column number Y of the sub-feature map in the input feature map.

The sparse tensor weight memory 410 may be configured to store the weights that are to be applied to the sub-feature maps stored within the sparse tensor feature map memory units 415A-415M. Thus, the sparse tensor weight memory 410 may be connected via a uni-directional bus 430 to the DRAM 215 and the direct memory access controller 245 to receive the weights and via a bus 435 to the sparse tensor compute cluster (e.g., the sparse tensor compute cluster 230) for sending the weights to the sparse tensor compute cluster. Since the sparse tensor weight memory 410 does not need to receive any results back from the sparse tensor compute cluster and does not need to send any results back to the DRAM 215, the bus 430 and the bus 435 may be uni-directional buses configured to send data in a single direction. In other embodiments, the bus 430 and/or the bus 435 may be bi-directional similar to the bi-directional bus 420A-420M/the bi-directional bus 425A-425M.

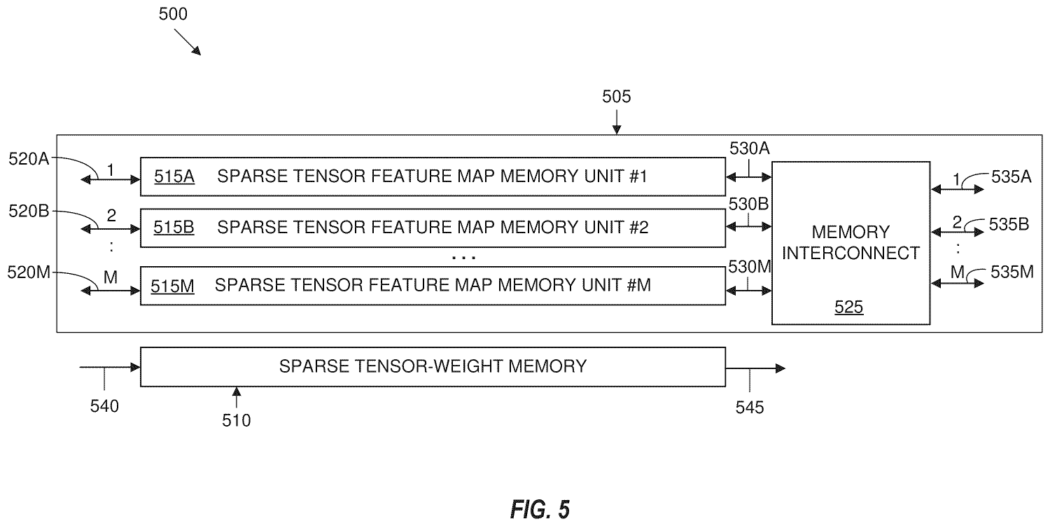

Turning to FIG. 5, an example of a sparse tensor memory cluster 500 is shown, in accordance with some embodiments of the present disclosure. The sparse tensor memory cluster 500 is analogous to the sparse tensor memory cluster 250 of FIG. 2. The sparse tensor memory cluster 500 is also substantially similar to the sparse tensor memory cluster 400. For example, similar to the sparse tensor memory cluster 400, the sparse tensor memory cluster 500 includes a sparse tensor feature map memory 505 and a sparse tensor weight memory 510. Also similar to the sparse tensor feature map memory 405, the sparse tensor feature map memory 505 includes a plurality of sparse tensor feature map memory units 515A-515M connected via a bi-directional bus 520A-520M to the DRAM 215 and the direct memory access controller 245. However, unlike the sparse tensor feature map memory 405 in which each of the plurality of sparse tensor feature map memory units 515A-515M is independent, does not share the data stored therein with other ones of the plurality of sparse tensor feature map memory units, and sends the data stored therein to the corresponding one of the sparse tensor compute unit, the plurality of sparse tensor feature map memory units 515A-515M of the sparse tensor feature map memory 505 are interconnected to one another and to other sparse tensor compute units via a memory interconnect 525.

Further, in some embodiments, the memory interconnect 525 may be configured to override the static binding discussed above. For example, in some embodiments, the memory interconnect 525 may enable a sparse tensor feature map memory unit #i to communicate with sparse tensor compute unit #1−M (“M” is the number of the sparse tensor compute units in the associated sparse tensor compute cluster) depending upon the configuration of the memory interconnect. In some embodiments, the memory interconnect 525 may be two-by-two switch that enables a sparse tensor feature map memory unit #i to communicate with the sparse tensor compute unit #i or sparse tensor compute unit #i+1. In other embodiments, the memory interconnect 525 may be a multi-stage interconnect such as a mesh network or Benes Network that allows a sparse tensor feature map memory unit #i to communicate with each of the sparse tensor compute units #1−M. In yet other embodiments, the memory interconnect 525 may be configured in other ways to allow a sparse tensor feature map memory unit #i to communicate with one or more sparse tensor compute units in addition to the sparse tensor compute unit #i. Similarly, in some embodiments, the memory interconnect 525 may enable a particular one of the plurality of sparse tensor feature map memory units 515A-515M to be interconnected with one or more of the other ones of the plurality of sparse tensor feature map memory units. For example, depending upon the configuration of the memory interconnect 525, a sparse tensor feature map memory unit #i may be interconnected with one or more of the sparse tensor feature map memory units #(i+1)−M.

Each of the plurality of sparse tensor feature map memory units 515A-515M may be connected to the memory interconnect 525 via a bi-directional bus 530A-530M. Thus, each of the plurality of sparse tensor feature map memory units 515A-515M may be configured to send the sub-feature map (and corresponding index values) stored therein to the memory interconnect 525 and receive a sub-feature map (e.g., that is stored in another sparse tensor feature map memory unit) or an output from the memory interconnect via their respective one of the bi-directional bus 530A-530M. Similarly, the memory interconnect 525 may be connected to the sparse tensor compute cluster (e.g., the sparse tensor compute cluster 230) via a bi-directional bus 535A-535M to send sub-feature maps (and the index values) to and receive outputs from the sparse tensor compute cluster. By using the memory interconnect 525, the flexibility in storing information within the plurality of sparse tensor feature map memory units 515A-515M may be increased and the static binding of the sparse tensor memory cluster 400 may be overridden.

The sparse tensor weight memory 510 is similarly configured as the sparse tensor weight memory 410. Thus, the sparse tensor weight memory 510 may be configured to store the weights that are to be applied to the sub-feature maps stored within the sparse tensor feature map memory units 515A-515M. Further, the sparse tensor weight memory 510 may be connected via a uni-directional bus 540 to the DRAM 215 and the direct memory access controller 245 to receive the weights and via a bus 545 to the sparse tensor compute cluster (e.g., the sparse tensor compute cluster 230) for sending the weights to the sparse tensor compute cluster. In other embodiments, the bus 540 and/or the bus 545 may be bi-directional.

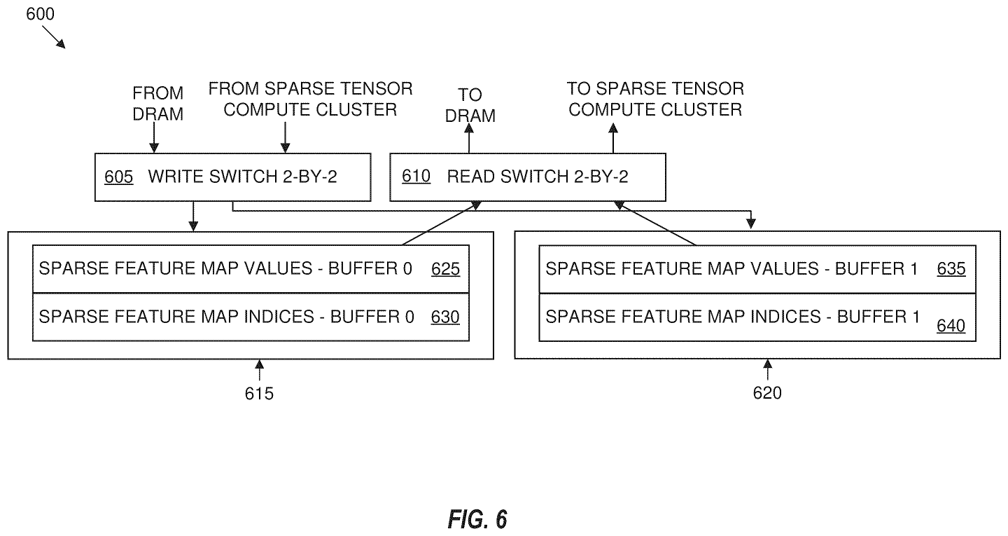

Referring to FIG. 6, an example sparse tensor feature map memory unit 600 is shown, in accordance with some embodiments of the present disclosure. The sparse tensor feature map memory unit 600 is analogous to each of the plurality of sparse tensor feature map memory units 415A-415M and the plurality of sparse tensor feature map memory units 515A-515M. The sparse tensor feature map memory unit 600 includes a write switch 605, a read switch 610, a first set of buffers 615, and a second set of buffers 620. The write switch 605 is configured to write the sub-feature maps received from the DRAM 215 (or from another sparse tensor feature map memory unit if interconnected) to the first set of buffers 615 and/or the second set of buffers 620. The write switch 605 is also configured to write the outputs (e.g., the output sub-feature maps) received from the sparse tensor compute cluster (e.g., the sparse tensor compute cluster 230) to the first set of buffers 615 and/or the second set of buffers 620. In some embodiments, the write switch 605 may be a 2×2 switch configured for double buffering control to receive data from two sources and write data to two sets of buffers (e.g., the first set of buffers 615 and the second set of buffers 620). In other embodiments, the write switch 605 may be configured in other ways.

The read switch 610 may be configured to read data stored within the first set of buffers 615 and the second set of buffers 620. For example, the read switch 610 may read data written by the write switch 605 in the first set of buffers 615 and/or the second set of buffers 620 to send the read data to the DRAM 215 (via the direct memory access controller 245). Similarly, the read switch 610 may read data written by the write switch 605 in the first set of buffers 615 and/or the second set of buffers 620 to send the read data to the sparse tensor compute cluster (and particularly the sparse tensor compute unit) of the sparse tensor compute cluster that is associated with the sparse tensor feature map memory unit 600. For example, the write switch 605 may receive a sub-feature map (and corresponding index values) from the DRAM 215 and store the sub-feature map (and the index values) within the first set of buffers 615 and/or the second set of buffers 620. The read switch 610 may then read that sub-feature map (and the index values) from the first set of buffers 615 and/or the second set of buffers 620 and send the read data to the sparse tensor compute cluster. Similarly, the write switch 605 may receive an output sub-feature map from the sparse tensor compute cluster and write that output sub-feature map within the first set of buffers 615 and/or the second set of buffers 620. The read switch 610 may read that output from the first set of buffers 615 and/or the second set of buffers 620 and transmit that output tensor to the DRAM 215.

In some embodiments, the read switch 610 may also be 2×2 switch configured for double buffering control to read data from two sets of buffers (e.g., the first set of buffers 615 and the second set of buffers 620). In other embodiments, the read switch 610 may be a 1×1 switch configured to read data from a single set of buffers or the read switch may be configured to read data from more than two sets of buffers.

Each of the first set of buffers 615 and the second set of buffers 620 may include two buffers in some embodiments. For example, in some embodiments, the first set of buffers 615 may include a first value buffer 625 and a first indices buffer 630. Similarly, in some embodiments, the second set of buffers 620 may include a second value buffer 635 and a second indices buffer 640. Although only two sets of buffers (e.g., the first set of buffers 615 and the second set of buffers 620) are shown in the sparse tensor feature map memory unit 600, in other embodiments, a single set of buffers or greater than two sets of buffers may be provided depending upon the configuration of the write switch 605 and/or the read switch 610. Similarly, although each of the first set of buffers 615 and the second set of buffers 620 is shown to have two buffers each, in other embodiments, either or both of the first set of buffers and the second set of buffers may include greater than two buffers or possibly a single buffer each.

The first value buffer 625 and the second value buffer 635 may be configured to store data values of the sub-feature map or the output sub-feature map, while the first indices buffer 630 and the second indices buffer 640 may be configured to store the index values of the sub-feature maps or the output sub-feature maps. For example, in some embodiments, the data values of sub-feature map A may be stored within the first value buffer 625 and the index values of that sub-feature map may be stored within the first indices buffer 630. In other embodiments, the data values of a particular sub-feature map (or the output sub-feature map) may be stored within one of the first set of buffers 615 or the second set of buffers 620 and the index values of that particular sub-feature map (or output sub-feature map) may be stored within the other one of the first set of buffers or the second set of buffers. Further, in some embodiments, the first set of buffers 615 may be designated to store the data values and the index values of the sub-feature maps, while the second set of buffers may be configured to store the data values and index values of the output sub-feature maps. In other embodiments, each of the first set of buffers 615 and the second set of buffers 620 may store both—the sub-feature maps and the output sub-feature maps (and their corresponding index values). Thus, each sub-feature map and each output sub-feature map may be associated with two buffers—a value buffer (e.g., the first value buffer 625, the second value buffer 635) to store the data values of the sub-feature map or the output sub-feature map and an indices buffer (e.g., the first indices buffer 630, the second indices buffer 640) to store the index values of that sub-feature map or the output sub-feature map.

Additionally, although the data values and the index values of a particular sub-feature map or the output sub-feature map are shown as being stored in separate buffers (e.g., the first value buffer 625, the second value buffer 635, the first indices buffer 630, the second indices buffer 640), in some embodiments, the data values and the index values of a particular sub-feature map or the output sub-feature map may be stored within a single buffer. In other words, in some embodiments, the first value buffer 625 and the first indices buffer 630 may be merged together to form a single buffer. Similarly, in some embodiments, the second value buffer 635 and the second indices buffer 640 may be merged together to form a single buffer.

Each buffer in the first set of buffers 615 and the second set of buffers 620 may be an SRAM memory configured as a single port read/write register file, a first-in-first-out data structure, a set of registers, or the like. By using SRAM memory for the buffers in the first set of buffers 615 and the second set of buffers 620, complex and more expensive cache structures may be avoided. In other embodiments, one or more buffers in the first set of buffers 615 and/or the second set of buffers 620 may be other types of memories. Further, each buffer in the first set of buffers 615 and the second set of buffers 620 may be configured with a particular size to be able to accommodate the data values and index values of at least one sub-feature map or at least one output sub-feature map.

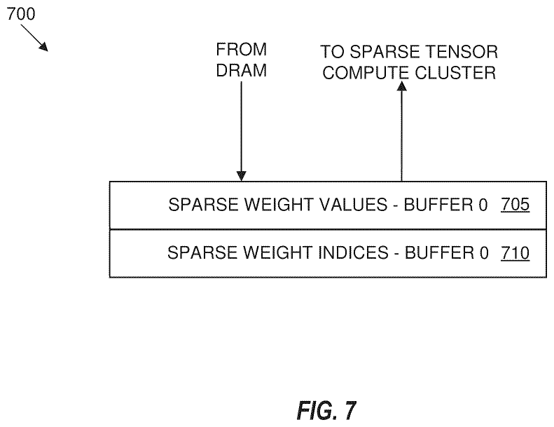

Referring now to FIG. 7, an example sparse tensor weight memory 700 is shown, in accordance with some embodiments of the present disclosure. The sparse tensor weight memory 700 is analogous to the sparse tensor weight memory 410 and the sparse tensor weight memory 510. The sparse tensor weight memory 700 includes a first buffer 705 configured to store the weight values and a second buffer 710 to store the index values of the weight values from the weight matrix 220. Thus, the first buffer 705 is similar to the first value buffer 625 and the second value buffer 635, while the second buffer 710 is similar to the first indices buffer 630 and the second indices buffer 640. The first buffer 705 and the second buffer 710 may receive and store weight values/index values from the DRAM 215 and send those values to the sparse tensor compute cluster (e.g., the sparse tensor compute cluster 230). In some embodiments, greater than one buffer for storing the weight values and/or greater than one buffer for storing the index values of the weight matrix may be used.

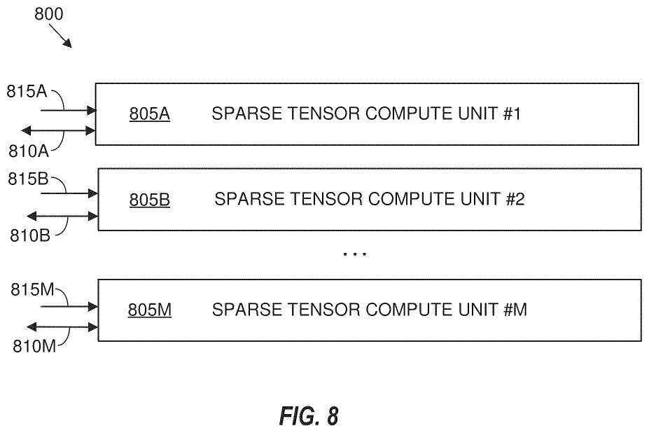

Turning to FIG. 8, an example sparse tensor compute cluster 800 is shown, in accordance with some embodiments of the present disclosure. The sparse tensor compute cluster 800 is analogous to the sparse tensor compute cluster 230. The sparse tensor compute cluster 800 includes a plurality of sparse tensor compute units 805A-805M. The number of the plurality of sparse tensor compute units 805A-805M may be dependent upon a designated number of sub-feature maps that may be desired to be processed in parallel. For example, to process five sub-feature maps in parallel, five sparse tensor compute units may be provided, with each sparse tensor compute unit being configured to process one sub-feature map at a time. In some embodiments, the number of the plurality of sparse tensor compute units 805A-805M is same as the number of the plurality of sparse tensor feature map memory units 415A-415M or 515A-515M, with a sparse tensor compute unit #i being associated with sparse tensor feature map memory unit #i. In other embodiments, different numbers of the plurality of sparse tensor compute units 805A-805M and the plurality of sparse tensor feature map memory units 415A-415M or 515A-515M may be used.

Further, in some embodiments, each of the plurality of sparse tensor compute units 805A-805M may be independent from other sparse tensor compute units, and process data independent from other ones of the plurality of sparse tensor compute units. Each of the plurality of sparse tensor compute units 805A-805M receives a sub-feature map (and corresponding index values) from the plurality of sparse tensor feature map memory units 415A-415M or 515A-515M via a bi-directional bus 810A-810M, respectively. The bi-directional bus 810A-810M may also be used to send the output sub-feature maps back to the plurality of sparse tensor feature map memory units 415A-415M or 515A-515M.

For example, if the sparse tensor memory cluster 400 having the static binding is used, in some embodiments, the sparse tensor compute unit #i may be configured to receive the sub-feature map (and corresponding index values) stored within the sparse tensor feature map memory unit #i via the bi-directional bus #i. In such embodiments, the sparse tensor compute unit #i may also be configured to send the output sub-feature map to the sparse tensor feature map memory unit #i via the bi-directional bus #i. Thus, a one-to-one correspondence between a particular sparse tensor compute unit and a sparse tensor feature map memory unit exists. For example, during static binding, the sparse tensor compute unit 805A may receive a sub-feature map (and corresponding index values) from the sparse tensor feature map memory unit 415A via the bi-directional bus 810A, and send the resulting output sub-feature map back to the sparse tensor feature map memory unit 415A via the bi-directional bus 810A.

In other embodiments, if the sparse tensor memory cluster 500 is used, a sparse tensor compute unit #i may still be associated with sparse tensor feature map memory unit #i. However, depending upon the configuration of the memory interconnect 525, a sparse tensor compute unit #i may receive a sub-feature map from a sparse tensor feature map memory unit #(i+1)−M via the bi-directional bus 810A-810M. Further, depending upon the configuration of the memory interconnect 525, a sparse tensor compute unit #i may be able to send the output sub-feature map to a sparse tensor feature map memory unit #(i+1)−M in addition to the sparse tensor feature map memory unit #i.

In addition to the sub-feature maps, each of the plurality of sparse tensor compute units 805A-805M receives weight values (and corresponding index values) via a uni-directional bus 815A-815M from the sparse tensor weight memory 410 or the sparse tensor weight memory 510. In some embodiments, the same weight may be transmitted to each, or at least a group, of the plurality of sparse tensor compute units 805A-805M via the uni-directional bus 815A-815M. In other embodiments, different weights may be transmitted to each, or at least a group, of the plurality of sparse tensor compute units 805A-805M via the uni-directional 815A-815M. Further, in some embodiments, a single weight may be transmitted to the plurality of sparse tensor compute units 805A-805M at a time, while in other embodiments, more than one weight may be simultaneously transmitted to one or more of the plurality of sparse tensor compute units at a time.

The output sub-feature maps obtained from processing a sub-feature map may be transmitted back to the corresponding one of the sparse tensor feature map memory unit. For example, in some embodiments, the sparse tensor compute unit 805A may receive a sub-feature map from the sparse tensor feature map memory unit 415A or 515A, process the sub-feature map to obtain an output sub-feature map, and send the output sub-feature map back to the sparse tensor feature map memory unit 415A or 515A. The sparse tensor feature map memory unit 415A or 515A may then send the output sub-feature map to the DRAM 215, to another sparse tensor feature map memory unit, and/or to another sparse tensor compute unit based upon the configuration.

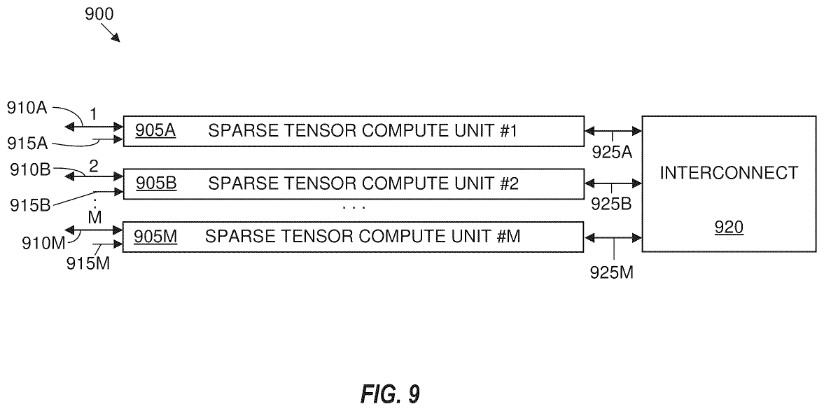

Turning to FIG. 9, an example sparse tensor compute cluster 900 is shown, in accordance with some embodiments of the present disclosure. The sparse tensor compute cluster 900 is analogous to the sparse tensor compute cluster 230. The sparse tensor compute cluster 900 is also substantially similar to the sparse tensor compute cluster 800. For example, similar to the sparse tensor compute cluster 800, the sparse tensor compute cluster 900 includes a plurality of sparse tensor compute units 905A-905M connected via a bi-directional bus 910A-910M to at least one of the sparse tensor feature map memory units 415A-415M or 515A-515M, as discussed above. Also similar to the sparse tensor compute cluster 800, each of the plurality of sparse tensor compute units 905A-905M is connected via a uni-directional bus 915A-915M to the sparse tensor weight memory 410 or 510 to receive the weights.

However, unlike the sparse tensor compute cluster 800 in which each of the plurality of sparse tensor compute units 805A-805M is independent and does not share the data being processed therein with other ones of the plurality of sparse tensor compute units, the plurality of sparse tensor compute units 905A-905M of the sparse tensor compute cluster 900 are interconnected via an interconnect 920. The interconnect 920 may be configured to override the static binding discussed above. Thus, in some embodiments, the interconnect 920 may enable a sparse tensor compute unit #i to communicate with other ones of the sparse tensor compute units #1−M depending upon the configuration of the interconnect. For example, in some embodiments, the interconnect 920 may be two-by-two switch that enables a sparse tensor compute unit #i to communicate with the sparse tensor compute unit #i+1. In other embodiments, the interconnect 920 may be a multi-stage interconnect such as a mesh network or Benes Network that allows a sparse tensor compute unit #i to communicate with each of the other sparse tensor compute units #1−M.

Each of the plurality of sparse tensor compute units 905A-905M may be connected to the interconnect 920 via a bi-directional bus 925A-925M. Thus, each of the plurality of sparse tensor compute units 905A-905M may be configured to send the output sub-feature map resulting from processing a particular sub-feature map directly to another one of the plurality of sparse tensor compute units via the interconnect 920 and the bi-directional bus 925A-925M instead of first sending those results to the sparse tensor memory cluster 400 or 500. By using the interconnect 525, the flexibility in assigning and processing sub-feature maps may be increased.

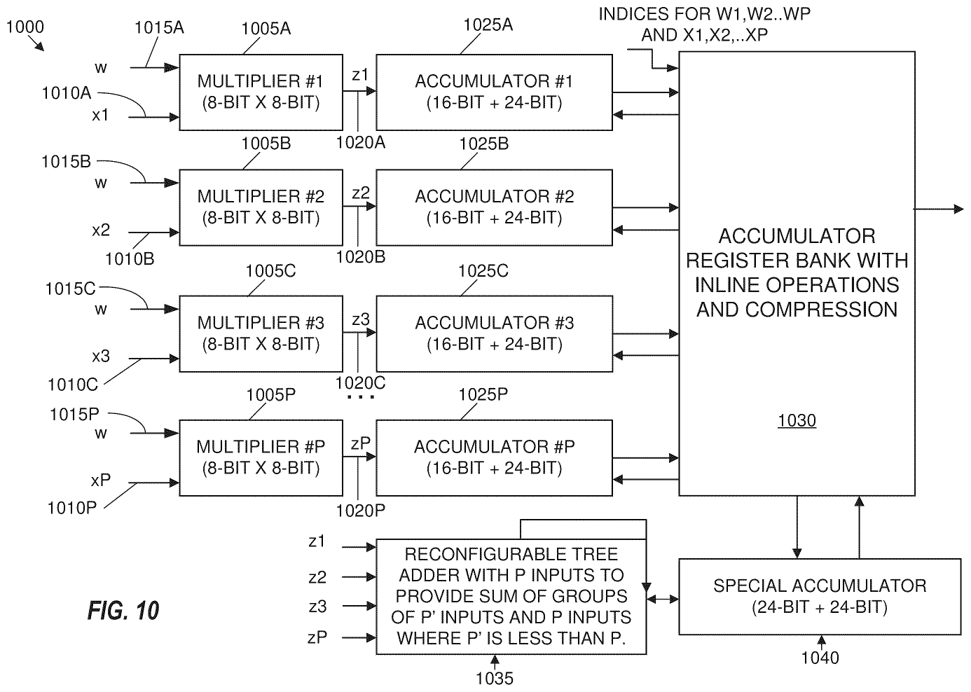

Turning to FIG. 10, an example block diagram of a sparse tensor compute unit 1000 is shown, in accordance with some embodiments of the present disclosure. The sparse tensor compute unit 1000 is analogous to one of the plurality of sparse tensor compute units 805A-805M or 905A-905M. The sparse tensor compute unit 1000 is configured to perform various machine learning operations such as multiplication, addition, etc., that may need to be performed during a convolution operation in a CNN. Thus, the sparse tensor compute unit 1000 receives a sub-feature map (and corresponding index values) from the sparse tensor memory cluster 400 or 500, as discussed above, or an output sub-feature map from another sparse tensor compute unit. The sparse tensor compute unit 1000 also receives weight values from the sparse tensor weight memory 410 or 510.

The sparse tensor compute unit 1000 includes a plurality of multipliers 1005A-1005P, each of which is configured to multiply a data value of a sub-feature map with a weight value of the weight matrix 220. In some embodiments, the number of the plurality of multipliers 1005A-1005P may be dependent upon the number of cells in the sub-feature map. For example, for a 2×2 sub-feature map having a total of four cells across two rows and two columns, in some embodiments, the number of the plurality of multipliers 1005A-1005P may be four to enable the data value in each cell to be processed independently. In other embodiments, the number of the plurality of multipliers 1005A-1005P may be greater than or less than the number of cells in a sub-feature map.

For example, in some embodiments, the number of the plurality of multipliers 1005A-1005P may be dependent upon the number of cells having non-zero values in the sub-feature map. For example, in the 2×2 sub-feature map above having four cells, if only three cells have non-zero values, the number of the plurality of multipliers 1005A-1005P may be three to process the three non-zero values in parallel. Alternatively, the number of the plurality of multipliers 1005A-1005P may still be four, however, only three of the four multipliers may be engaged/used to process the three non-zero values. In other embodiments, the number of the plurality of multipliers 1005A-1005P may be two, and two of the three non-zero values may be processed in parallel in a first round and the third non-zero value may be processed in a second round in one of the two multipliers after the first round.

In some embodiments, all of the P multiplier units may be used in each clock cycle. For example, if the number of the plurality of multipliers 1005A-1005P is 4 and there are 3 non-zero values (d1,d2,d3) in a 2×2 cell on which weights w1 and w2 are to be applied. At clock cycle 1, all 4 multipliers may be utilized as follows: d1*w1, d2*w1, d3*w1 and d1*w2. Generally speaking, if P is the total number of data values in the sub-feature map being processed by the sparse tensor compute cluster 1000 and Q is the number of non-zero values in the sub-feature map, in some embodiments (e.g., in CONV2D layers, i.e. convolution 2D), Q multipliers may be engaged and max(1, ceiling(P−Q)/Q) unique weights may be transmitted to the Q multipliers to ensure full utilization of the plurality of multipliers 1005A-1005P. For example, in case of 1 unique weight value, the unique weight value may be transmitted to each of the Q multipliers. In the case of 2 unique weight values, the first weight value may be transmitted to the Q multipliers and the second weight value may be transmitted to the remaining number of multipliers. In the case of 1×1 CONV and FC layers, P weight values may be transmitted to P multipliers. Thus, in some embodiments, only non-zero data values of the sub-feature map are input into the plurality of multipliers 1005A-1005P. Since a product with a zero data value is zero, any zero values in the input sub-feature map need not be processed through the plurality of multipliers 1005A-1005P, thereby saving computing resources and time. Rather, in some embodiments, after the computation results of the non-zero values are filled in the output feature map, the remaining index values may be filled with zero values.

In some embodiments, the number of the plurality of multipliers 1005A-1005P may be dependent upon the size of the weight matrix 220 (also referred to herein as a kernel matrix or filter matrix). The weight matrix 220 may also include a plurality of cells, as discussed above. For example, the weight matrix 220 may have two rows and two columns forming four cells. Thus, the number of the plurality of multipliers 1005A-1005P that are provided or engaged may be four to process four data values in parallel. Thus, the number of the plurality of multipliers 1005A-1005P may be dependent upon a variety of factors.

In some embodiments, only non-zero weight values may be input into the plurality of multipliers 1005A-1005P. Thus, for example, if the weight matrix 220 has four cells and only three of those cells have non-zero values, only three weight values may be input into the plurality of multipliers 1005A-1005P. In some embodiments, the number of non-zero weight values may not impact the number of the plurality of multipliers 1005A-1005P, but rather, may impact the number of iterations that are needed to process a sub-feature map, as discussed below. Similar to the zero data values, the appropriate index values of where the result of multiplying with that zero-weight value would be located in the output sub-feature map may be computed. Those index values may then be populated with a value of zero.

Further, in some embodiments, each sparse tensor compute unit (e.g., the plurality of sparse tensor compute units 805A-805M, 905A-905M) in a sparse tensor computer cluster (e.g., the sparse tensor compute cluster 800, 900) may have the same number of multipliers (e.g., the plurality of multipliers 1005A-1005P), while in other embodiments, the number of multipliers in one or more sparse tensor compute units of a sparse tensor compute cluster may be different than other ones of the sparse tensor compute units in the sparse tensor compute cluster.

Additionally, each of the plurality of multipliers 1005A-1005P may be sized based upon the size of the data values and the weight values that are to be processed therein. In some embodiments, each of the plurality of multipliers 1005A-1005P may be an electronic circuit configured to multiply two binary numbers. Generally speaking, each of the plurality of multipliers 1005A-1005P may be implemented in any of a variety of ways using software, hardware, firmware, or combinations thereof.

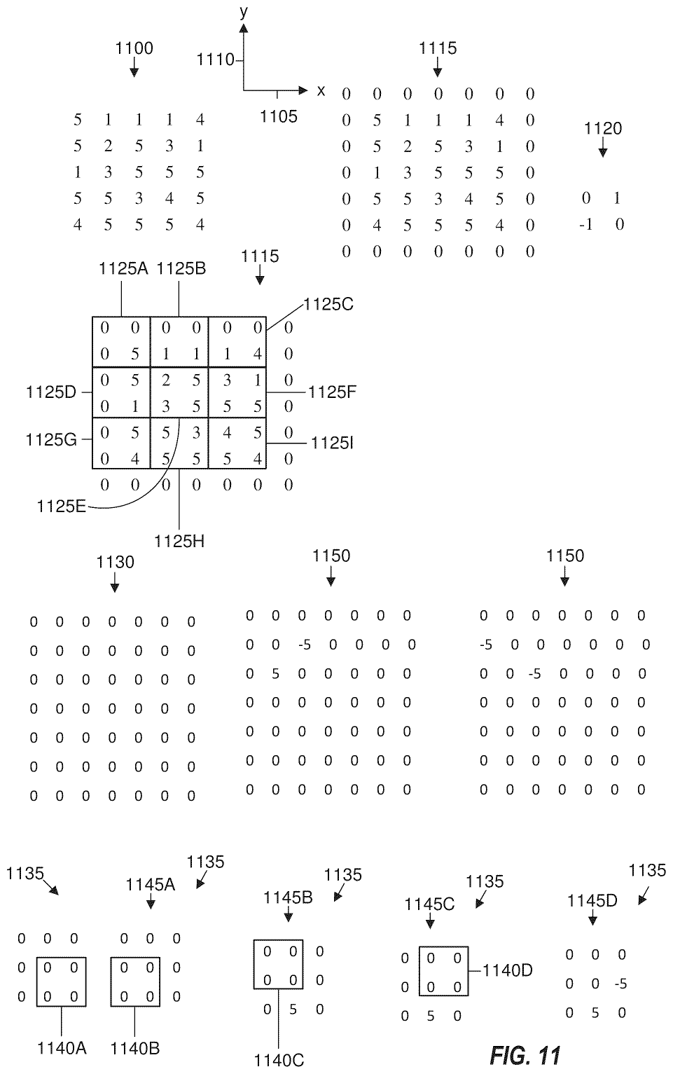

Each of the plurality of multipliers 1005A-1005P, thus, receives a data value 1010A-1010P from a sub-feature map. For example, and referring to FIG. 11 in conjunction with FIG. 10, the sparse tensor compute unit 1000 is explained with respect to an example 5×5 input feature map 1100. It is to be understood that the input feature map 1100 is simply an example and is not intended to be limiting in any way. The present disclosure may be used to process input feature maps of any size and having any data values therein. The input feature map 1100 may be generated from the input image 205. The input feature map 1100 may include a plurality of cells, each cell being formed at the intersection of a row (that extends in an X-direction 1105) and a column (that extends in a Y-direction 1110). Each of the plurality of cells in the input feature map 1100 includes a data value that is to be processed in the sparse tensor compute unit 1000.

In some embodiments, the input feature map 1100 may be padded by zeroes on all sides to ensure that the output feature map is of the same size as the input feature map. For example, a row of zeroes may be added above the first row and below the last row of the input feature map 1100, and a column of zeroes may be added to the left hand side of the first column and to the right hand side of the last column of that input feature map for padding. By padding zeroes to the input feature map 1100, a padded feature map 1115 having a 7×7 size may be obtained. In some embodiments, the partitioning block 210 may perform the padding. In other embodiments, the padding may be added by another component of the accelerator 200. Without zero padding, the output feature map may be of a different size than the input feature map.

Further, in some embodiments, sub-feature maps may be created from the padded feature map 1115, and weight values from a kernel matrix 1120 may be applied to those sub-feature maps. It is to be understood that the kernel matrix 1120 is simply an example and is not intended to be limiting in any way. The kernel matrix 1120 may assume other sizes (e.g., the number of rows and number of columns may vary from that shown) and the values within the kernel matrix may also vary. The kernel matrix 1120 may be said to be of a kernel size, k. In a square kernel matrix (e.g., the kernel matrix 1120) having equal number of rows and columns, the kernel size, k, is equal to the number of rows or columns in the kernel matrix in some embodiments. In other embodiments, the kernel size, k, for a square or non-square kernel matrix may be considered an input parameter that may be determined/optimized using external training processes involving supervised examples and backpropagation of error gradients. Thus, for the kernel matrix 1120 having two rows and two columns, the description below is assuming that the kernel size, k, is two.

In some embodiments, the padded feature map 1115 may be divided into sub-feature maps in the partitioning block 210 or other component of the accelerator 200, as discussed above in FIGS. 3A and 3B. For example and as shown in FIG. 11, the padded feature map 1115 may be divided, as discussed above, to create a plurality of sub-feature maps 1125A-1125I. Since the last row and the last column of the padded feature map 1115 includes all zero values, those values do not have an impact on the output values, and therefore, need not be processed. (This represents a form of run-length compression, discussed further below.) Each of the plurality of sub-feature maps 1125A-1125I may be processed in parallel in different sparse tensor compute units (e.g., the sparse tensor compute unit 1000). For example, in some embodiments, the sub-feature map 1125A may be processed in a first sparse tensor compute unit, the sub-feature map 1125B may be processed in a second sparse tensor compute unit, and so on.

Further, in FIG. 11, each of the plurality of sub-feature maps 1125A-1125I includes two rows and two columns. Although each of the plurality of sub-feature maps 1125A-1125I is of the same size as other sub-feature maps in FIG. 11, it is to be understood that the sub-feature maps may be of varying sizes, as discussed above. Further, although each of the plurality of sub-feature maps 1125A-1125I has the same number of rows and the columns as the kernel matrix 1120, in some embodiments, one or more of the plurality of sub-feature maps may have varying number of rows and/or columns than the kernel matrix. Depending upon the number of the plurality of multipliers 1005A-1005P in the sparse tensor compute unit 1000, multiple data values in each of the plurality of sub-feature maps 1125A-1125I may be processed in parallel. For example, if the sub-feature map 1125A is being processed in the sparse tensor compute unit 1000, and assuming that the plurality of multipliers 1005A-1005P includes four multipliers at least, the data values in each of the four cells of that sub-feature map may be processed in parallel.

Thus, to process the sub-feature map 1125A, the data values from that sub-feature map may be input into the plurality of multipliers 1005A-1005P. For example, the data value “0” having the index value (1,1) (e.g., row 1, column 1) of the sub-feature map 1125A may be loaded into the multiplier 1005A, the data value “0” having the index value (1,2) (e.g., row 1, column 2) may be loaded into the multiplier 1005B, the data value “1” having the index value (2,1) (e.g., row 2, column 1) may be loaded into the multiplier 1005C, and the data value “5” having the index value (2,2) (e.g., row 2, column 2) may be loaded into the multiplier 1005P. In some embodiments, the corresponding index values of the data values may also be input into the respective one of the plurality of multipliers 1005A-1005P. The data values that are zero in value are loaded into the plurality of multipliers 1005A-1005P herein simply for ease of illustration. In other embodiments, only non-zero data values may be loaded into the plurality of multipliers 1005A-1005P.

In addition to the data values, each of the plurality of multipliers 1005A-1005P receives a weight value 1015A-1015P from the sparse tensor weight memory 410 or 510. The weight value 1015A-1015P may be a value from a cell of the kernel matrix 1120. In some embodiments, the sparse tensor compute unit 1000 may be configured to process one unique weight at a time. In such cases, a single weight value may be broadcast to each of the plurality of multipliers 1005A-1005P at a time. For example, in a first iteration of processing the sub-feature map 1125A, a first weight value from the kernel matrix 1120 may be transmitted to each of the multipliers 1005A, 1005B, 1005C, and 1005P (collectively referred to below as the plurality of multipliers 1005A-1005P). Thus, the same weight value is broadcast to each of the plurality of multipliers 1005A-1005P.

Upon finishing processing of the sub-feature map 1125A with the first weight value, a second weight value from the kernel matrix 1120 may be transmitted to each of the plurality of multipliers 1005A-1005P in a second iteration. Upon finishing processing of the sub-feature map 1125A with the second weight value, a third weight value from the kernel matrix 1120 may be transmitted to each of the plurality of multipliers 1005A-1005P in a third iteration, and upon finishing processing of the sub-feature map with the third weight value, a fourth weight value from the kernel matrix may be transmitted to each of the plurality of multipliers in a fourth iteration. Thus, the processing of the sub-feature map 1125A may require four iterations. During each iteration, the input weight value is multiplied with each of the data values in the sub-feature map 1125A. Further, each iteration may include one or more rounds depending upon the number of the plurality of multipliers 1005A-1005P. Specifically, if the number of the plurality of multipliers 1005A-1005P includes enough number of multipliers to process all the data values of a sub-feature map in parallel, then each iteration may include a single round. On the other hand, if the number of the plurality of multipliers 1005A-1005P is less than the number of data values in the sub-feature map, then each iteration may include multiple rounds. Upon completing the four iterations with the sub-feature map 1125A, the output of the sparse tensor compute unit 1000 may be the output sub-feature map corresponding to the sub-feature map 1125A.

Further, in some embodiments, the order in which the weight values from the kernel matrix 1120 are transmitted to the plurality of multipliers 1005A-1005P may be pre-determined. For example, in some embodiments, the weight value from the kernel matrix 1120 having index value (1,1) may be loaded into each of the plurality of multipliers 1005A-1005P in the first iteration. As indicated above, the index value captures the row number and column number of a particular cell in the kernel matrix 1120. Thus, the index value (1,1) corresponds to row 1 column 1 of the kernel matrix 1120. The weight value corresponding to the index value (1,1) in the kernel matrix 1120 is “0.” Thus, the weight value of “0” is loaded into each of the plurality of multipliers 1005A-1005P in the first iteration. Similar to the data values, zero weight values are described as being input into the plurality of multipliers 1005A-1005P simply for ease of illustration. In other embodiments, only non-zero weight values may be input into the plurality of multipliers 1005A-1005P. In the second iteration, the weight value in the index value (1,2) (e.g., the weight value “1”) is broadcast to each of the plurality of multipliers 1005A-1005P. In the third iteration, the weight value corresponding to the index value (2,2) (e.g., having the weight value “0”) is loaded into each of the plurality of multipliers 1005A-1005P, while in the fourth iteration, the weight value of “−1” corresponding to the index value (1,1) is broadcast to each of the plurality of multipliers. In other embodiments, the weight values may be input into the plurality of multipliers 1005A-1005P in a different order in the various iterations.

Thus, in the first iteration of processing the sub-feature map 1125A, each of the plurality of multipliers 1005A-1005P receives one data value from the sub-feature map and the weight value of “0” corresponding to the index value (1,1) in the kernel matrix 1120. Each of the plurality of multipliers 1005A-1005P computes a product (e.g., z=w*x) between its respective data value (e.g., the data values 1010A-1010P) and the weight value (e.g., the weight values 1015A-1015P) to obtain a product. For example, the multiplier 1005A may multiply the data value 1010A with the weight value 1015A to obtain a product value 1020A. Similarly, the multiplier 1005B may multiply the data value 1010B with the weight value 1015B to obtain a product value 1020B, the multiplier 1005C may multiply the data value 1010C with the weight value 1015C to obtain a product value 1020C, and the multiplier 1005P may multiply the data value 1010P with the weight value 1015P to obtain a product value 1020P. The product values 1020A-1020P may be represented as a product matrix such that each of the product values 1020A-1020P has the same index value as the data value that was input into the respective one of the plurality of multipliers 1005A-1005P. For example, since the data value having the index value of (1,1) was input into the multiplier 1005A, the product value 1020A also has the index value of (1,1) in the product matrix. Thus, the product matrix based on the product values 1020A-1020P may look like:

$$\begin{matrix}0 & 0 \\ 0 & 0\end{matrix}$$

Each of the product values 1020A-1202P is input into a corresponding accumulator 1025A-1025P, respectively. Each of the accumulators 1025A-1025P may include a register (or other type of memory) configured to receive and temporarily store the respective one of the product values 1020A-1020P. In some embodiments, each of the accumulators 1025A-1025P may also include a computing element (e.g., an addition element) to perform the computations discussed below. Although P separate ones of the accumulators 1025A-1025P are shown in FIG. 10, in some embodiments, one or more of the P accumulators may be combined together to form a larger accumulator that receives the product values 1020A-1020P. Additionally, in some embodiments, the size of each of the accumulators 1025A-1025P may be computed using the formula: (2k−1)×(2k−1), where k is the kernel size of the kernel matrix 1120. Since in the current example, the kernel size, k, of the kernel matrix 1120 is 2, each of the accumulators 1025A-1025P may be sized to at least store a 3×3 matrix.

Further, upon transmitting the product values 1020A-1020P to the accumulators 1025A-1025P, the second iteration of processing the sub-feature map 1125A may start in the plurality of multipliers 1005A-1005P. Thus, in the second iteration, the weight value corresponding to the index value (1,2) of the kernel matrix 1120 may be transmitted to each of the plurality of multipliers 1005A-1005P. Since the data values of the sub-feature map 1125A are already in the plurality of multipliers 1005A-1005P from the first iteration, those data values need not be input again.

Further, upon receiving the product values 1020A-1020P, each of the accumulators 1025A-1025P may process those values based upon values received from a register bank 1030. The register bank 1030 is configured to store the output sub-feature map resulting from convolving the sub-feature map 1125A with the kernel matrix 1120. The register bank 1030 may be a group of registers, flip flops, or other memory units. While the register bank 1030 is explained here in terms of registers, in other embodiments, flip flops or other types of memory units may be used in the register bank. In some embodiments, the register bank 1030 may be part of one or more of the accumulators 1125A-1125P. Further, in some embodiments, the register bank 1030 may include a plurality of row registers and a plurality of column registers that are connected together to form one or more shift registers. In some embodiments, the plurality of row registers may be connected together to form a shift register to enable the values stored therein to be shifted right or left by at least one position. Similarly, in some embodiments, the plurality of column registers may be connected together to form a shift register to enable the values stored therein to be shifted up or down by at least one position.

Further, the size of the register bank 1030 may be based upon the size of the padded feature map 1115 (or the size of the output feature map). Thus, for a 7×7 size of the padded feature map 1115, the register bank 1030 may be initialized with a size of 7×7. In other words, the register bank 1030 may include 49 registers such that 7 registers in each row are connected together to form a shift register and 7 registers in each column are connected together to form a shift register. Further, in some embodiments, at the start of the first iteration, the register bank 1030 may be initialized with all zero values, as shown in register bank 1130 in FIG. 11. Additionally, in some embodiments, at the start of the first iteration, a portion of the register bank 1130 may be loaded into each of the accumulators 1025A-1025P.

For example, each of the accumulators 1025A-1025P may include a register 1135 having a size of (2k−1)×(2k−1) or 3×3, as discussed above. When the register bank 1130 is initialized with all 0 values at the beginning of the first iteration, the register 1135 of each of the accumulators 1025A-1025P may be loaded with values from a 3×3 portion of the register bank 1130. The 3×3 portion from the register bank 1130 that is copied into the register 1135 may be determined based on the following formula:

$$Register = register bank ( i : i + acc\_length - 1 , j : j + acc\_length - 1 )$$

In the formula above, the first term corresponds to the row numbers of the register bank 1130 and the second term corresponds to the column numbers of the register bank. Further, in the formula above, “i” is the start of the row number and “j” is the start of the column number of the sub-feature map 1125A in the padded feature map 1115, and acc_length is the size of the register 1135. In other words, (i, j) is the index value of the sub-feature map 1125A. For example, the size of the register 1135 in the example above is 3 since the register is 3×3. The size of the register 1135 is computed similar to the kernel size of the kernel matrix 1120. Thus, for the sub-feature map 1125A, “i” in the formula above is 1, “j” is 1, and acc_length is 3. Thus, the register 1135 of each of the accumulators 1025A-1025P may be initialized with rows (1:3, 1:3) of the register bank 1130. Since the values in rows 1:3 and columns 1:3 of the register bank 1130 are all zeroes at the time of initialization, the values in the register 1135 are initialized with all zeroes. In addition to the product values 1020A-1020P, the register bank 1030 also receives the index values corresponding to each data value in the sub-feature map 1125A and the index values corresponding to each weight value in the kernel matrix 1120 to compute the portion of the register bank 1030 that is to be loaded into each of the accumulators 1025A-1025P.

Thus, at the start of the first iteration, the register bank 1030 is initialized with the 0 values shown in the register bank 1130 and the register 1135 of each of the accumulators 1025A-1025P is initialized with a 3×3 portion from the register bank 1130. Each of the accumulators 1025A-1025P reads a portion of its respective register 1135 in each iteration and adds the current product values (e.g., the product values 1020A-1020P) to the product values computed in previous iterations. For example, for the first iteration in which the weight value corresponding to the index value (1,1) is transmitted to the plurality of multipliers 1005A-1005P, the accumulators 1025A-1025P read a portion 1140A of their respective instance of the register 1135, as shown in FIG. 11. The order in which portions of the register 1135 are read may be determined by the definition of the convolution operation. Thus, in some embodiments, the portion 1140A is read first. In other embodiments, depending upon the definition of the convolution operation, another portion of the register 1135 may be read first. The accumulators 1025A-1025P add the product values 1020A-1020P in the product matrix above with the values in the portion 1140A. Specifically, the accumulators 1025A-1025P may perform the following matrix addition:

$$[ \begin{matrix}0 & 0 \\ 0 & 0\end{matrix} ] + [ \begin{matrix}0 & 0 \\ 0 & 0\end{matrix} ] = [ \begin{matrix}0 & 0 \\ 0 & 0\end{matrix} ]$$

In the equation above, the first matrix is the product matrix derived from the product values 1020A-1020P and the second matrix corresponds to the values in the portion 1140A. The result of the matrix addition may be stored back into the portion 1140A of the register 1135 of each of the accumulators 1025A-1025P. Thus, after the first iteration, the register 1135 of each of the accumulators 1025A-1025P has the values shown in register 1145A of FIG. 11.

In the second iteration, the sub-feature map 1125A continues to be loaded into the plurality of multipliers 1005A-1005P, as discussed above, and the weight value of “1” corresponding to the index (1, 2) in the kernel matrix 1120 is transmitted to each of those multipliers. The product values 1020A-1020P may be represented by combining the product values 1020A-1020P in a product matrix, z in the second iteration as:

$$\begin{matrix}0 & 0 \\ 0 & 5\end{matrix}$$

The above product values 1020A-1020P may be transmitted to the accumulators 1025A-1025P. The accumulators 1025A-1025P may read a portion 1140B from the register 1145A, which is obtained by shifting from the location of the portion 1140A left column-wise by one position. The accumulators 1025A-1025P may perform matrix addition on the values in the product matrix of the second iteration with the values in the portion 1140B as follows:

$$[ \begin{matrix}0 & 0 \\ 0 & 5\end{matrix} ] + [ \begin{matrix}0 & 0 \\ 0 & 0\end{matrix} ] = [ \begin{matrix}0 & 0 \\ 0 & 5\end{matrix} ]$$

The result of the matrix addition above may be stored back in the portion 1140B. Thus, after the second iteration, the register 1135 has values shown in register 1145B.

In the third iteration, the sub-feature map 1125A continues to be loaded into the plurality of multipliers 1005A-1005P, as discussed above, and the weight value of “1” corresponding to the index (2, 2) in the kernel matrix 1120 is transmitted to each of those multipliers. The product values 1020A-1020P may be represented by a product matrix, z in the second iteration as:

$$\begin{matrix}0 & 0 \\ 0 & 0\end{matrix}$$

The above product values 1020A-1020P may be transmitted to the accumulators 1025A-1025P. The accumulators 1025A-1025P may read a portion 1140C of the register 1145B, which is obtained by shifting the location of the portion 1140B of the register 1145A up row-wise by one position. The accumulators 1025A-1025P may perform matrix addition on the values in the product matrix of the third iteration with the values in the portion 1140C as follows:

$$[ \begin{matrix}0 & 0 \\ 0 & 0\end{matrix} ] + [ \begin{matrix}0 & 0 \\ 0 & 0\end{matrix} ] = [ \begin{matrix}0 & 0 \\ 0 & 0\end{matrix} ]$$

The result of the matrix addition above may be stored in the portion 1140C. Thus, after the third iteration, the register 1135 has the values shown in register 1145C.

In the fourth iteration, the sub-feature map 1125A continues to be loaded into the plurality of multipliers 1005A-1005P, as discussed above, and the weight value of “−1” corresponding to the index (2, 1) in the kernel matrix 1120 is transmitted to each of those multipliers. The product values 1020A-1020P may be represented by a product matrix, z in the second iteration as:

$$\begin{matrix}0 & 0 \\ 0 & - 5\end{matrix}$$

The above product values 1020A-1020P may be transmitted to the accumulators 1025A-1025P. The accumulators 1025A-1025P may read a portion 1140D of the register 1145C, which is obtained by shifting the location of the portion 1140C to the right column-wise by one position. The accumulators 1025A-1025P may perform matrix addition on the values in the product matrix of the fourth iteration with the values in the portion 1140D as follows:

$$[ \begin{matrix}0 & 0 \\ 0 & - 5\end{matrix} ] + [ \begin{matrix}0 & 0 \\ 0 & 0\end{matrix} ] = [ \begin{matrix}0 & 0 \\ 0 & - 5\end{matrix} ]$$

The result of the matrix addition above may be stored in the portion 1140D. Thus, after the fourth iteration, the register 1135 has the values shown in register 1145D.

Since in the example of FIG. 11, there are only four iterations, upon completing the four iterations for the sub-feature map 1125A, the accumulators 1025A-1025P load the values stored in the register 1135 (e.g., the values in the register 1145D) back into the register bank 1130. Further, the values of the register 1145D may be loaded back into the register 1130 in the same location from where those values were initially initialized. Thus for example, the following formula may be used to determine where the values from the register 1145A are uploaded to the register 1130:

$$Register bank = register ( i : i + acc\_length - 1 , j : j + acc\_length - 1 )$$

Thus, for the sub-feature map 1125A, the values in the register 1145D may be loaded into rows (1:3, 1:3) of the register bank 1130. Thus, after loading the values in the register 1145D to the register bank 1130, the register bank 1030 may have values similar to register bank 1150. Further, the loaded values in the register bank 1150 may be circular shifted right by one column. For example, the shifting operation may be performed in accordance with the following formula:

$$Register bank = circshift ( register bank , kernal size - 1 , 2 )$$

The directionality of shifting may be dependent upon the convolution definition. Thus, in other embodiments, the register bank 1150 may be shifted in other ways. Thus, the values in the register 1150 may be shifted to obtain values shown in register 1155. The values in the register 1150 may be subject to one or more in-line operations in the register bank 1030. For example, the register bank 1030 may perform a non-linear Rectified Linear Unit (ReLU) operation and a pooling operation. Thus, in some embodiments, the register bank 1030 may include a ReLU processing unit and pooling operation processing unit to perform the ReLU and pooling operations, respectively. In other embodiments, a separate component may be associated with the sparse tensor compute unit 1000 to perform the ReLU and pooling operations.

In some embodiments, a ReLU operation may implement the following activation function: ƒ(x)=max (ax). In other embodiments, the ReLU operation may implement other activation functions. The ReLU operation may generate one output for each input. Thus, for A inputs, the ReLU operation may generate A outputs. A pooling operation may then reduce the A results to B results. For example, a pooling operation having a kernel size of 2×2 may reduce A inputs into A/4 inputs. Thus, depending upon the kernel size of the pooling operation, the register bank 1030 may reduce A inputs into B inputs. The register bank 1130 may also be associated with B pooling units, with each pooling unit configured to perform a down sampling operation on one of the A results of the ReLU operation. The pooling operation may perform a max pooling operation in which a maximum value from a group of cell values is determined, an average pooling operation in which an average of a group of cell values is determined, or a sum pooling operation in which a sum of a group of cell values is determined. In other embodiments, other pooling operations may be performed. The results of the pooling operation may represent the output sub-feature map, which may be sent back to the associated sparse tensor memory cluster 400, 500 or to another sparse tensor compute unit. In some embodiments, the output sub-feature map may be compressed before being sent to the sparse tensor memory cluster 400, 500.

In some embodiments, before compressing the output sub-feature map, the output sub-feature map may be combined with other output sub-feature maps generated from the other sparse tensor compute units. To combine the various output sub-feature maps, in some embodiments, the output sub-feature maps may be “stitched” together to obtain the output feature map. For example, in some embodiments, if the input feature map is divided into four sub-feature maps [A, B, C, D], which generate four respective output sub-feature maps A′, B′, C′, and D′, the output feature maps may be given as [A′, B′, C′, D′].

Further, each of the product values 1020A-1020P is also input into an adder 1035 and stored in a special accumulator 1040. The adder 1035 may be used to compute sums of groups of the product values 1020A-1020P. For example, the adder 1035 may be used to compute sums of groups of P′ inputs and P inputs where P′ is less than P. The special accumulator 1040 may handle the accumulations that may be needed for fully connected layers and 1×1 convolutions, by taking outputs of the adder 1035 and previously accumulated results from the register bank 1030.

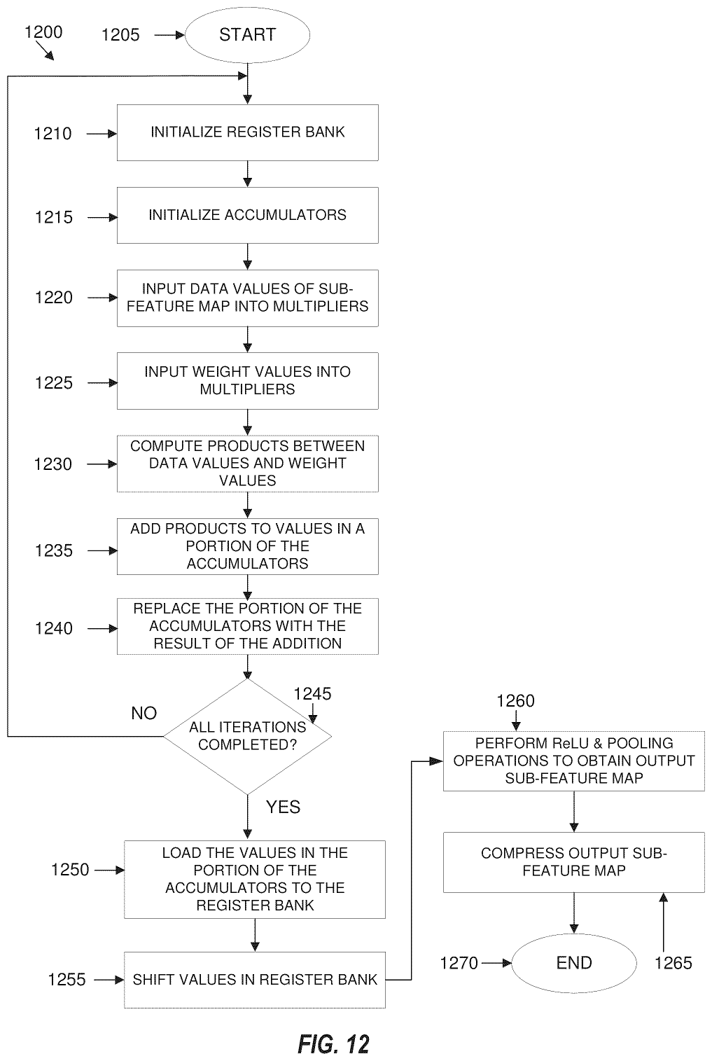

Turning now to FIG. 12, an example flowchart outlining operations of a process 1200 is shown, in accordance with some embodiments of the present disclosure. The process 1200 may be implemented in the sparse tensor compute unit 1000. In some embodiments, a controller may be associated with the sparse tensor compute unit 1000 to perform the process 1200. The controller may be associated with a memory for storing computer-readable instructions, which may be performed by a processor associated with the controller. In other embodiments, the scheduling engine 225 may be configured to perform the process 1200. The process 1200 may include other or additional operations depending upon the particular embodiment.

Upon starting at operation 1205, the register bank 1030 is initialized at operation 1210. As indicated above, at the start of the first iteration, the register bank 1030 may be initialized with all zero values. Further, upon initializing the register bank 1030, each of the accumulators 1025A-1025P may be initialized at operation 1215 such that a portion of the register bank is loaded into each of those accumulators. The portion of the register bank 1030 that is loaded into the each of the accumulators is based upon the index values of the sub-feature map in the input feature map being processed. At operation 1220, data values from the sub-feature map (e.g., the sub-feature map 1125A) are input into the plurality of multipliers 1005A-1005P as discussed above. In some embodiments, the operations 1210/1215 and 1220 may be occur in parallel. At operation 1225, one weight value from the kernel matrix 1220 is transmitted to each of the plurality of multipliers 1005A-1005P.

Each of the plurality of multipliers 1005A-1005P computes a product between the data value of the sub-feature map received therein and the weight value at operation 1230 to obtain a product value (e.g., the product values 1020A-1020P). The product values may be represented as a product matrix. At operation 1235, the values in the product matrix are added to values read from a window of the portion loaded into the accumulators 1025A-1025P at the operation 1215. For example, in the first iteration, the values in the product matrix may be added to the portion 1140A. In the second iteration, the values in the product matrix may be added to the portion 1140B, while in the third iteration, the values in the product matrix may be added to the portion 1140C, and in the fourth iteration, the values in the product matrix may be added to the portion 1140D. Thus, in each iteration, the window (e.g., the portions 1140A-1140D) may be shifted by one position (e.g., from the initial position of the portion 1140A—shift left column wise to the position of the portion 1140B—shift up row wise to the position of the portion 1140C—shift right column wise to the position of the portion 1140D). The shifting pattern described above may be applied even if the register 1135 is greater than 3×3 in size.

The result of the addition in each iteration is stored back in the accumulators 1025A-1025P at operation 1240. Then, at operation 1245, it is determined whether all the iterations have been completed. Again, the number of iterations may be dependent upon the number of non-zero weight values in the weight matrix 1120 and the number of unique weight values that are to be transmitted to the plurality of multipliers 1005A-1005P in each iteration. For example, for a 2×2 weight matrix, if a single weight value is transmitted in each iteration, and if all four weight values in that weight matrix are non-zero values, then the process 1200 may include 4 iterations. If additional iterations remain, the process 1200 loops back to the operation 1210 to continue processing the next iteration. On the other hand, if at the operation 1245, it is determined that all the iterations have completed, at operation 1250, the accumulators 1025A-1025P load the portion obtained at the operation 1240 after completion of the last iteration back into the register bank 1030. At operation 1255, the register bank 1030 performs a shift operation, and at operation 1260, a ReLU and pooling operation is performed on the shifted values in the register bank to obtain an output sub-feature map. Optionally, at operation 1265, the output sub-feature map may be compressed. The process 1200 then ends at operation 1270 by sending the output sub-feature map to the associated sparse tensor memory cluster 400, 500, or to another sparse tensor compute unit.

In some embodiments, where depth separable convolutions are implemented (e.g., where the feature map has multiple channels), the result from each channel may be stored as an intermediate output sub-feature map. For example, the sub-feature maps of each channel may perform operations 1205-1255, and the result of those operations may be stored as an intermediate output sub-feature map. In some embodiments, ReLU and pooling operations may not be performed on the intermediate output sub-feature maps. Thus, depending upon the number of channels, multiple intermediate output sub-feature maps may be obtained. For example, for three channels, three intermediate output sub-feature maps may be obtained. (e.g., depthwise convolution or spatial convolution performed independently over each channel of an input). Each of the intermediate output sub-feature maps may then be combined by applying a 1×1 filter according to given hyperparameters of the neural network. (e.g., Pointwise convolution such as a 1×1 convolution, projecting the channels output by the depthwise convolution onto a new channel space.) The ReLU and pooling operations of the operation 1260 may then be performed on the combined intermediate output sub-feature maps to obtain the output sub-feature map.

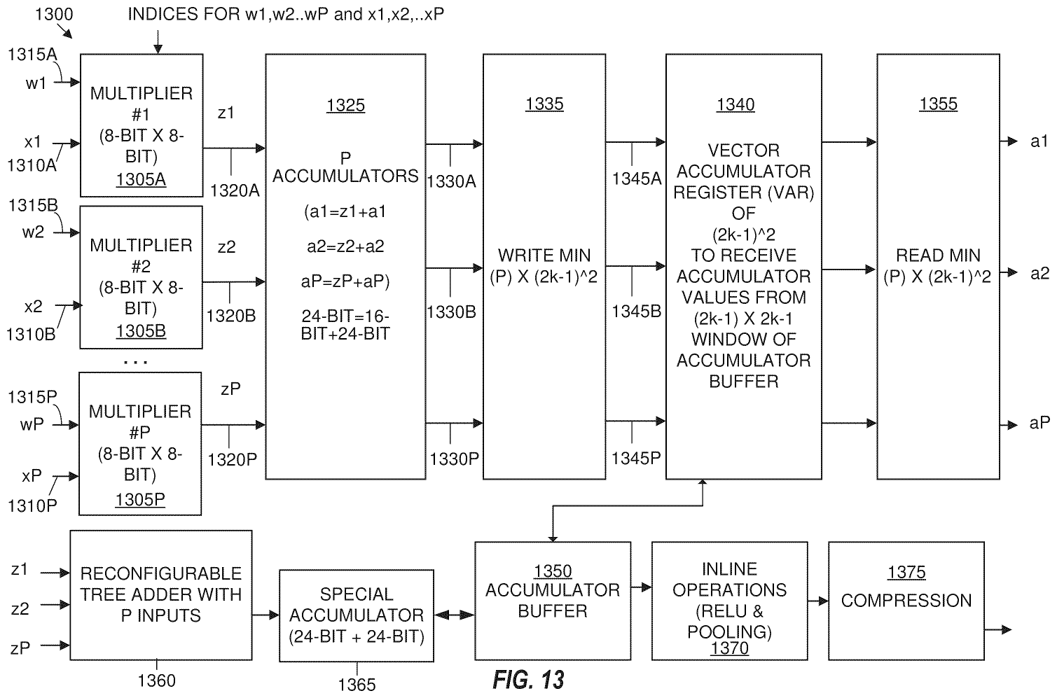

Referring now to FIG. 13, an example block diagram of a sparse tensor compute unit 1300 is shown, in accordance with some embodiments of the present disclosure. The sparse tensor compute unit 1300 is analogous to one of the plurality of sparse tensor compute units 805A-805M or 905A-905M. The sparse tensor compute unit 1300 is configured to perform various machine learning operations such as multiplication, addition, etc., that may need to be performed during a convolution operation in a CNN. The sparse tensor compute unit 1300, like the sparse tensor compute unit 1000, includes a plurality of multipliers 1305A-1305P. Each of the plurality of multipliers 1305A-1305P is configured similar to the plurality of multipliers 1005A-1005P, and therefore, is not described again.

Further, each of the plurality of multipliers 1305A-1305P is configured to receive a data value (e.g., data values 1310A-1310P) from a sub-feature map (e.g., the sub-feature map 1125A), as well as a weight value (e.g., weight values 1315A-1315P) from a kernel matrix (e.g., the kernel matrix 1120) that is to be applied to the sub-feature map. Each of the plurality of multipliers 1305A-1305P computes a product between the data value (e.g., the data values 1310A-1310P) and the weight value (e.g., the weight values 1315A-1315P) stored therein to generate product values 1320A-1320P, respectively. Also, similar to the sparse tensor compute unit 1000, the sparse tensor compute unit 1300 also processes the sub-feature map 1125A in multiple iterations (e.g., four iterations, as discussed above). In each iteration, a different weight value from the kernel matrix 1120 may be applied to the sub-feature map 1125A.

In some embodiments, each of the plurality of multipliers 1305A-1305P may also receive the index values of the data values 1310A-1310P, respectively, and the index values of each of the weight values 1315A-1315P. For example, the multiplier 1305A may receive the index value of the data value 1310A and the index values of each of the weight values from the kernel matrix 1120. Based upon the index values, each of the plurality of multipliers 1305A-1305P may determine the index value of where the product value (e.g., the product values 1320A-1320P) computed by that multiplier is to be located in the output sub-feature map. In some embodiments, each of the plurality of multipliers 1305A-1305P may compute the index value of the product values 1320A-1320P using the following formulae:

$$XW\_row \_idx = X\_row \_idx + ( ( W\_ROW \_LEN - 1 ) - W\_row \_idx )$$

$$XW\_col \_idx = X\_col \_idx + ( ( W\_COL \_LEN - 1 ) - W\_col \_idx )$$

In the formulae above, indices start from 0 and XW_row_idx, XW_col_idx are the row, column index values, respectively, of the product values (e.g., the product values 1320A-1320P) in the output sub-feature map. X_row_idx and X_col_idx are the row, column index values, respectively, of the first multiplicand (e.g., the data values 1310A-1310P). W_row_idx, W_col_idx are the row, column index values, respectively, of the second multiplicand (e.g., the weight values 1315A-1315P). W_ROW_LEN, W_COL_LEN are the dimensions (e.g., kernel size) of the kernel matrix 1120. Further, XW-row_idx may be the same as X_row_idx offset by the filter row length and filter coefficient row index filter coefficient row index takes the value from 0 to W_ROW_LEN−1.

Upon computing the index values of the product values 1320A-1320P, each of the plurality of multipliers 1305A-1305P may transmit their respective product value and the computed index value to an accumulator 1325. Although the plurality of multipliers 1305A-1305P have been described as computing the index values of the product values 1320A-1320P, in some embodiments, the accumulator 1325 may instead receive the various index values of the first and second multiplicands to compute the index values of those product values. In other embodiments, another component of the accelerator 200 may compute the index values for the product values 1320A-1320P in the output sub-feature map.

Thus, each of the product values 1320A-1320P and the computed index values are input into the accumulator 1325. In some embodiments, the accumulator 1325 may be a combination of “P” accumulators (where “P” is the total number of the plurality of multipliers 1305A-1305P) and each accumulator may be similar to the plurality of accumulators 1025A-1025P. The accumulator 1325 is, thus, configured similar to the accumulators 1025A-1025P. Similar to the accumulators 1025A-1025P, the accumulator 1325 may be configured to add each of the product values 1320A-1320P to the sum computed in the last iteration. For example, the accumulator 1325 may add the product value 1320A of the current iteration to the product value 1320A from the previous iterations. Thus, the accumulator 1325 may perform the following operations:

$$a 1 = a 1 + z 1$$

$$a 2 = a 2 + z 2$$

$$…$$

$$aP = aP + zP$$

In the equations above, z1 is the product value 1320A, z2 is the product value 1320B, zP is the product value 1320P, and so on. At the start of the first iteration, each of the values a1, a2, . . . , aP may be initialized to zero. Results 1330A-1330P, including the summation results (e.g., a1, a2, . . . aP) and the computed index values of each of those results may be sent from the accumulator 1325 to a Multi-stage Interconnection Network (“MIN”) 1335. The result 1330A may include the summation result, a1, and the index value computed by the multiplier 1305A for the product value 1320A. Similarly, the result 1330B may include the summation result, a2, as well as the index value computed by the multiplier 1305B for the product value 1320B, and so on.

The MIN 1335 may be used for local interleaving and connecting the accumulator 1325 to a variable accumulator register (“VAR”) 1340. Additional details of the MIN 1335 may be found in U.S. application Ser. No. 15/627,042, filed on Jun. 19, 2017, the entirety of which is incorporated by reference herein. The MIN 1335 may include a plurality of control states. In some embodiments, the total number of locations input to a READ MIN (e.g., MIN 1355 described below) are (2k−1)\hat{ }2. Since P values need to be accessed out of these (2k−1)\hat{ }2 values, the READ MIN (e.g., the MIN 1355) may be used. The total number of locations the WRITE MIN (e.g., the MIN 1335) is connected to are (2k−1)\hat{ }2. Since P values need to be written out of these (2k−1)\hat{ }2 values, the WRITE MIN (e.g., the MIN 1335) may be used. In some embodiments, if two of the product values 1320A-1320P have the same computed index values, the MIN 1335 may sort the results 1330A-1330P. The WRITE MIN (e.g., the MIN 1335) may, thus, be used to write to the VAR 1340 and the READ Min (e.g., the MIN 1355) may be used to read from the VAR 1340. Thus, the MIN 1335 may transmit sorted results 1345A-1345P, including the index values computed by the plurality of multipliers 1305A-1305P, to the VAR 1340.

Thus, the MIN 1335 and the MIN 1355 may provide a bi-directional connectivity (e.g., one direction for read and another direction for write) on first P ports (or k\hat{ }2 ports in case of no sparsity in an input sub-feature map) of a Benes network (total number of ports may be (2k−1)\hat{ }2), where the number of P ports may be based on a percentage of non-zero values in the input sub-feature map. For example, if there are 60% non-zero values in an input sub-feature map, and the kernel matrix is 3×3, then the P ports may be chosen to be 6. In some embodiments, the P ports may be chosen independent of the average sparsity and may be based on various hardware considerations.

The VAR 1340 is initialized with a portion from an accumulator buffer 1350 similar to the accumulators 1025A-1025P. The accumulator buffer 1350 is similar to the register bank 1030. However, the accumulator buffer 1350 does not implement a shifting operation. Similar to the register bank 1030, the accumulator buffer 1350 may be of a size of the output sub-feature map, as discussed above with respect to the register bank. For example, using the example of FIG. 11, the accumulator buffer 1350 may be of size 7×7. Further, at the start of the first iteration, the accumulator buffer 1350 may be initialized with all zero values, as discussed above.

Additionally, at the start of the first iteration, a portion of the accumulator buffer 1350 may be loaded into the VAR 1340. The size of the VAR 1340 may be computed using the formula: (2k−1)×(2k−1), where k is the kernel size of the kernel matrix 1120. Since in the example of FIG. 11, the kernel size, k, of the kernel matrix 1120 is 2, the size of the VAR 1340 is 3×3. Further, the 3×3 portion from the accumulator buffer 1350 that is copied into the VAR 1340 may be determined based on the following formula:

$$VAR = accumulator buffer ( i : i + acc\_length - 1 , j : j + acc\_length - 1 )$$

In the formula above, the first term corresponds to the row numbers (e.g., row index value) of the accumulator buffer 1350 and the second term corresponds to the column numbers (e.g., column index value) of the accumulator buffer. Further, in the formula above, “i” is the start of the row number and “j” is the start of the column number of the sub-feature map 1125A in the padded feature map 1115, and acc_length is the size of the accumulator buffer 1350. For example, since the size of the accumulator buffer 1350 in the example above is 3×3, the acc_length is 3. Thus, for example, for processing the sub-feature map 1125A, “i” in the formula above is 1, “j” is 1, and acc_length is 3. Thus, at the start of the first iteration, rows 1:3 and columns 1:3 of the accumulator buffer 1350 may be loaded into the VAR 1340.

Upon receiving the sorted results 1345A-1345P and the computed index values from the MIN 1335, the VAR 1340 stores the results in the appropriate index value of the portion copied from the accumulator buffer 1350. Upon storing the sorted results 1345A-1345P in the appropriate index values in the VAR 1340, the VAR may transmit the sorted results 1345A-1345P to the MIN 1355, which is structured similar to the MIN 1335. The MIN 1355 may send the sorted results 1345A-1345P back to the accumulator 1325 for use during the next iteration.

Further, after completing all iterations of processing the sub-feature map 1125A, the VAR 1340 may send the results stored therein back to the accumulator buffer 1350. For example, if rows 1:3 and columns 1:3 were copied from the accumulator buffer 1350 to the VAR 1340 at the start of the first iteration, at the end of the last iteration, the results from the VAR are loaded back into rows 1:3 and columns 1:3 of the accumulator buffer. Thus, the portion of the accumulator buffer 1350 that is loaded into the VAR 1340 at the start of the first iteration is replaced by the results from the VAR 1340 at the end of the last iteration.

In addition to sending the product values 1320A-1320P to the accumulator 1325, those product values are also input into an adder 1360. The results from the adder 1360 are stored within a special accumulator 1365. The adder 1360 and the special accumulator 1365 are analogous to the adder 1035 and the special accumulator 1040, respectively.

ReLU and pooling operations 1370 are performed, as discussed above, on the values stored in the accumulator buffer 1350 after the last iteration to obtain an output sub-feature map. The results of the ReLU and pooling operations 1370 may optionally be compressed in a compression block 1375, as discussed above. The compressed results may be sent back to the DRAM 215 via the associated memory storage memory cluster or to another sparse tensor compute unit.

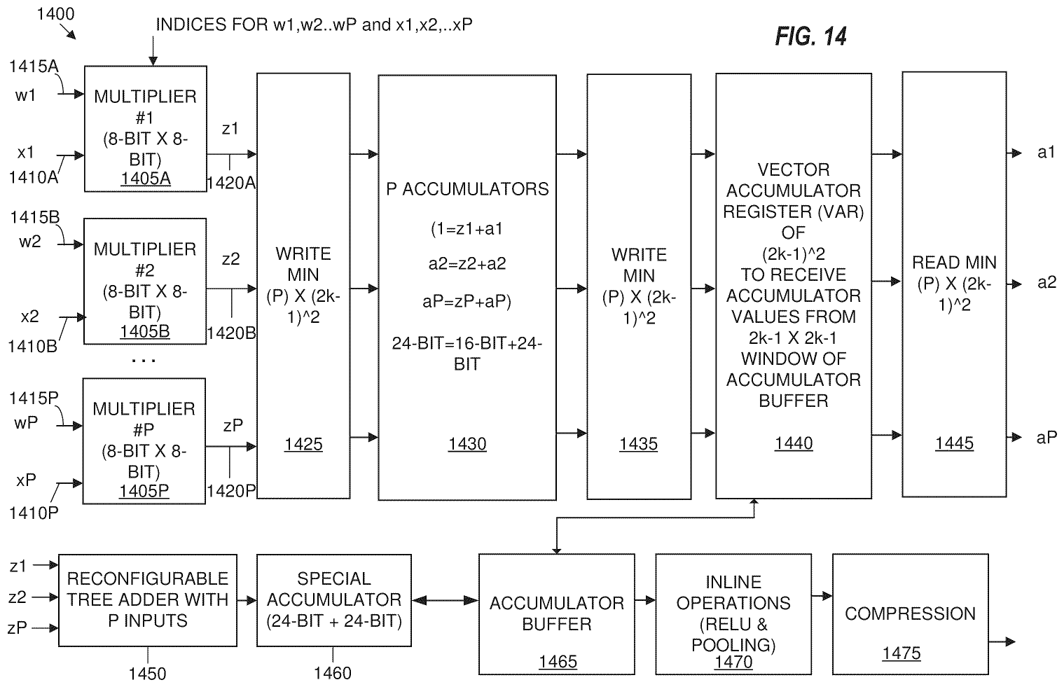

Referring now to FIG. 14, an example of a sparse tensor compute unit 1400 is shown, in accordance with some embodiments of the present disclosure. The sparse tensor compute unit 1400 is substantially similar to the sparse tensor compute unit 1300. For example, similar to the sparse tensor compute unit 1300, the sparse tensor compute unit 1400 includes a plurality of multipliers 1405A-1405P that receive data values 1410A-1410P and weight values 1415A-1415P to generate product values 1420A-1420P. Each of the plurality of multipliers 1405A-1405P may also receive the index values of the data values 1410A-1410P and the weight values 1415A-1415P to compute the index values of the product values 1420A-1420P, as explained above.

The sparse tensor compute unit 1300 is configured to receive one unique weight value at a time. In other words, the same weight value is transmitted to each of the plurality of multipliers 1305A-1305P in the sparse tensor compute unit 1300 in each iteration. However, the sparse tensor compute unit 1400 is configured to process more than one unique weight values in each iteration. In some embodiments, more than one unique weight values may need to be processed at a time. In such cases, multiple weight values may be broadcast to the plurality of multipliers 1405A-1405P at a time. For example, a first group of the plurality of multipliers 1405A-1405P may receive a first weight value, a second group of the plurality of multipliers may receive a second weight value, and so on. For example, when two weight values are used in each iteration, a first weight value may be transmitted to Q ones of the plurality of multipliers 1405A-1405P (where Q is the number of non-zeroes in a particular sub-feature map) and a second weight value may be transmitted to (P−Q) number of the plurality of multipliers. The number of unique weight values that may be used in each iteration may be computed using the following formula: max(1, ceiling (P−Q)) where Q is the number of non-zero values in a particular sub-feature map and P is the number of the plurality of multipliers 1405A-1405P that are engaged.

The product values 1420A-1420P and the computed index values may be transmitted to a MIN 1425. Specifically, the MIN 1425 may be a write arbiter MIN having “P” number of first in first out buffers and P×P control states. If more than one of the product values 1420A-1420P have the same computed index value in the output sub-feature map, the MIN 1425 may send one of the product values going to that index value, while store the remaining product values in the buffers. The MIN 1425 then sends the products values 1420A-1420P and the computed index values to an accumulator 1430. The accumulator 1430 is similar to the accumulator 1425. Further, MIN 1435, VAR 1440, MIN 1445, adder 1450, special accumulator 1460, accumulator buffer 1465, ReLU and pooling operations 1470, and compression block 1475 are configured similar to the MIN 1335, the VAR 1340, the MIN 1355, the adder 1360, the special accumulator 1365, the accumulator buffer 1350, the ReLU and pooling operations 1370, and the compression block 1375, and therefore, are not described again for conciseness of expression. Each of these elements process the sub-feature map 1125A as described above in FIG. 14.

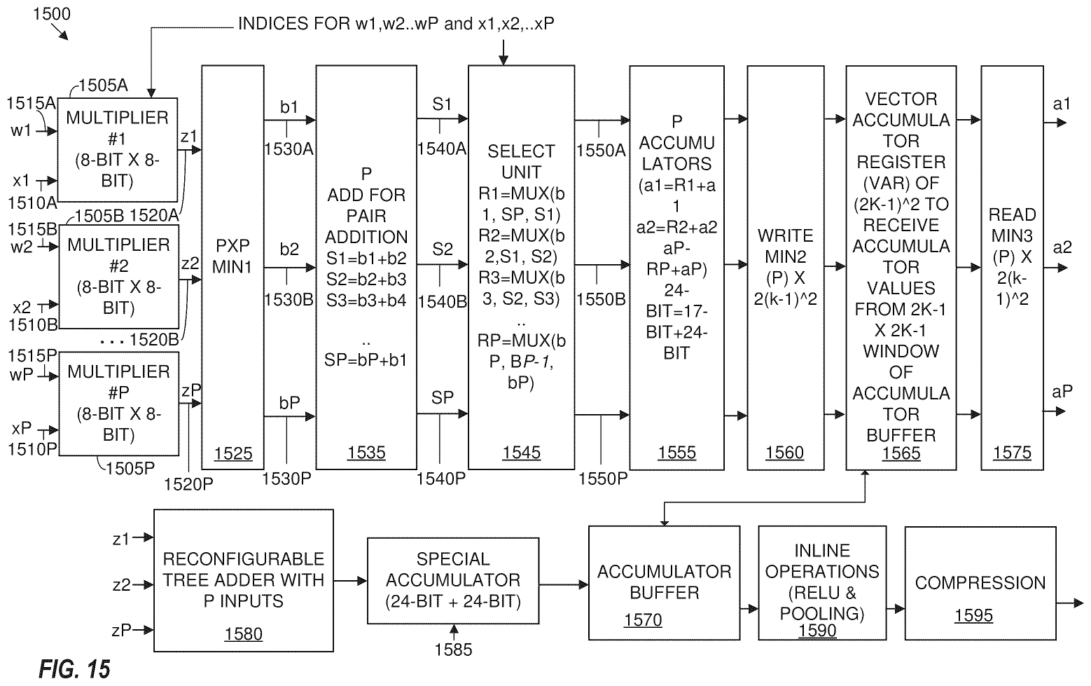

Turning to FIG. 15, an example of a sparse tensor compute unit 1500 is shown, in accordance with some embodiments of the present disclosure. The sparse tensor compute unit 1500 is substantially similar to the sparse tensor compute unit 1400. For example, similar to the sparse tensor compute unit 1400, the sparse tensor compute unit 1500 includes a plurality of multipliers 1505A-1505P that receive data values 1510A-1510P and weight values 1515A-1515P to generate product values 1520A-1520P, and compute the index values of those product values. Also similar to the sparse tensor compute unit 1400, the sparse tensor compute unit 1500 is configured to receive multiple weight values in each iteration. The product values 1520A-1520P and the computed index values may be transmitted to a MIN 1525, which may be structured similar to the MIN 1425. The MIN 1525 transmits values 1530A-1530P to an addition block 1535. The addition block 1535 may perform the following addition operation:

$$S 1 = b 1 + b 2$$

$$S 2 = b 2 + b 3$$

$$S 3 = b 3 + b 4$$

$$…$$

$$SP = bP + b 1$$

The added values (S1, S2, . . . SP) may be considered speculative computations. If two weight values are sent to the sparse tensor compute unit 1500, the two product values resulting from those two weight values may need to be added together before accumulation. The added values (S1, S2, . . . , SP) may be transmitted as values 1540A-1540P to a select unit 1545. The select unit 1545 may be a group of multiplexers that are configured to perform the following operations:

$$R 1 = MUX ( b 1 , SP , S 1 )$$

$$R 2 = MUX ( b 2 , S 1 , S 2 )$$

$$R 3 = MUX ( b 3 , S 2 , S 3 )$$

$$…$$

$$RP = MUX ( bP , S ( P - 1 ) , SP )$$

In some embodiments, the control for the selection of the multiplexers above may be based on the output index value for each product value. If two adjacent product values share the same output index value, then the sum value of the adjacent product values may be selected.

Although the select unit 1545 has been described as having a group of multiplexers, in other embodiments, other elements that are configured to select one input from a plurality of inputs based on selection criteria may be used.

Results 1550A-1550P (e.g., R1, R2, . . . , RP) may be transmitted to an accumulator 1555. The accumulator 1555 is similar to the accumulator 1430 and configured to perform the following addition operations:

$$a 1 = R 1 + a 2$$

$$a 2 = R 2 + a 3$$

$$a 3 = R 3 + a 4$$

$$…$$

$$aP = RP + a 1$$

The results from the accumulator 1555 may be sent to a MIN 1560, which is similar to the MIN 1435. Further, the results from the accumulator 1555 may be processed in a VAR 1565, accumulator buffer 1570, MIN 1575, adder 1580, special accumulator 1585, ReLU and pooling operations 1590, and compression block 1595 similar to that in the VAR 1435, the accumulator buffer 1465, the MIN 1445, the adder 1450, the special accumulator 1460, the ReLU and pooling operations 1470, and the compression block 1475, and therefore, not explained again.

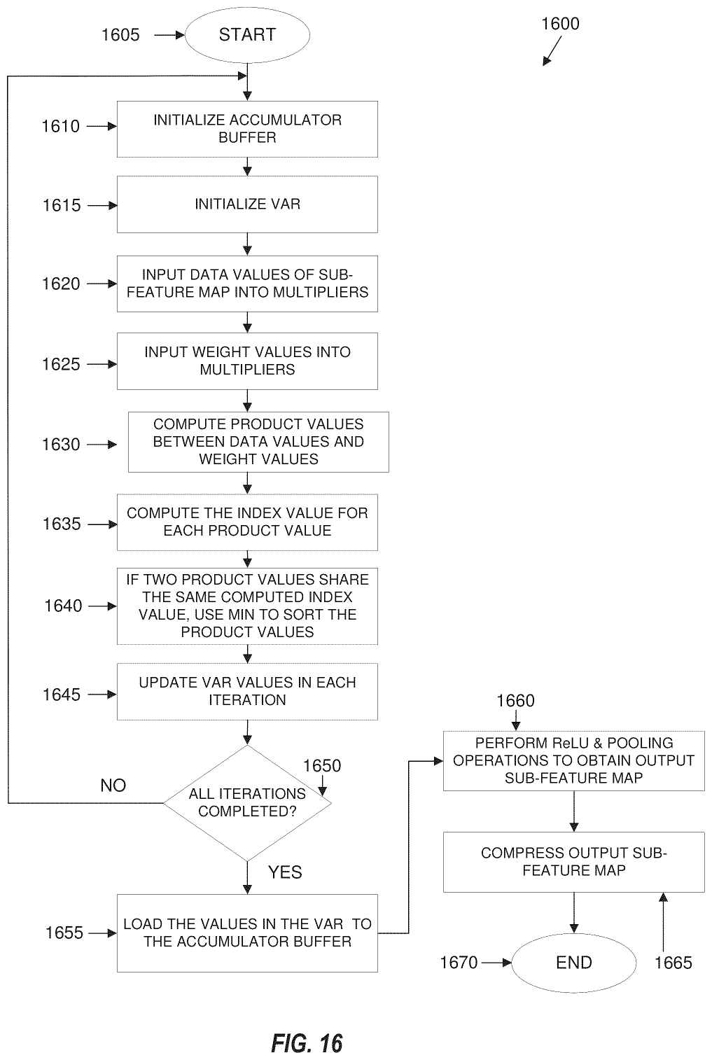

Turning to FIG. 16, an example flowchart outlining operations of a process 1600 is shown, in accordance with some embodiments of the present disclosure. The process 1600 may include other or additional operations depending upon the embodiment. The process 1600 may be implemented in the sparse tensor compute unit 1300, the sparse tensor compute unit 1400, or the sparse tensor compute unit 1500. In some embodiments, the sparse tensor compute unit implementing the process 1600 may include a controller that performs the process 1600. The controller may be associated with a memory for storing computer-readable instructions, which may be executed by a processor associated with the controller. In other embodiments, the scheduling engine 225 may be configured to perform the process 1600. The process 1600 may be implemented during a standard convolution operation in a CNN. The process 1600 may also be implemented in a fully connected 1×1 convolution operation in which a 1×1 weight matrix is applied.

Upon starting at operation 1605, the accumulator buffer (e.g., the accumulator buffer 1350, the accumulator buffer 1465, the accumulator buffer 1570) of the sparse tensor compute unit (e.g., the sparse tensor compute unit 1300, the sparse tensor compute unit 1400, or the sparse tensor compute unit 1500) that is implementing the process 1600 is initialized at operation 1610. The operation 1610 is similar to the operation 1210. As indicated above, at the start of the first iteration, the accumulator buffer may be initialized with all zero values. Further, upon initializing the accumulator buffer at the operation 1610, the VAR (e.g., the VAR 1340, the VAR 1440, the VAR 1565) of the sparse tensor compute unit implementing the process 1600 is initialized at operation 1615 such that a portion of the accumulator buffer is loaded into the VAR.

At operation 1620, data values from the sub-feature map (e.g., the sub-feature map 1125A) are input into the plurality of multipliers (e.g., the plurality of multipliers 1305A-1305P, the plurality of multipliers 1405A-1405P, the plurality of multipliers 1505A-1505P) of the sparse tensor compute unit implementing the process 1600, as discussed above. At the operation 1620, the index values corresponding to the data values may also be input into the plurality of multipliers. At operation 1625, one or more weight values (e.g., from the kernel matrix 1220) are transmitted to each of the plurality of multipliers (e.g., the plurality of multipliers 1305A-1305P, the plurality of multipliers 1405A-1405P, the plurality of multipliers 1505A-1505P) of the sparse tensor compute unit implementing the process 1600, as discussed above. The index values of those weight values may also be input into those multipliers. The number of weight values transmitted to each of the plurality of multipliers may be dependent upon the type of convolution being performed. For example, in some embodiments, two unique weight values may be transmitted to each of the plurality of multipliers in a standard convolution operation, while a single weight value may be transmitted to each of those multipliers in a fully connected 1×1 convolution operation. In some embodiments, the operations 1610/1615 and 1620/1625 may occur in parallel.

Each of the plurality of multipliers (e.g., the plurality of multipliers 1305A-1305P, the plurality of multipliers 1405A-1405P, the plurality of multipliers 1505A-1505P) computes a product between the data value of the sub-feature map received therein and the weight value(s) at operation 1630 to obtain a product value (e.g., the product values 1320A-1320P, the product values 1420A-1420P, the product values 1520A-1520P). The product values may be represented as a product matrix. At operation 1635, the plurality of multipliers (e.g., the plurality of multipliers 1305A-1305P, the plurality of multipliers 1405A-1405P, the plurality of multipliers 1505A-1505P) also compute the index values for those product values, as discussed above.

At operation 1640, if two product values share the same computed index, the MIN (e.g., the MIN 1335, the MIN 1435, the MIN 1460) of the sparse tensor compute unit implementing the process 1600 sorts the product values such that the product values sharing the same index value are adjacent to each other in the VAR (e.g., the VAR 1340, the VAR 1440, the VAR 1565) of the sparse tensor compute unit implementing the process 1600. The sorted results from the MIN are stored in the VAR at operation 1645. Then, at operation 1650, it is determined whether all the iterations have been completed. If additional iterations remain, the process 1600 loops back to the operation 1610 to continue processing the next iteration. On the other hand, if at the operation 1650, it is determined that all the iterations have completed, at operation 1655, the values in the VAR (e.g., the VAR 1340, the VAR 1440, the VAR 1565) obtained at the operation 1645 after completion of the last iteration are loaded back into the accumulator buffer (e.g., the accumulator buffer 1350, the accumulator buffer 1465, the accumulator buffer 1570). At operation 1660, ReLU and pooling operations are performed on the values in the accumulator buffer to obtain an output sub-feature map. Optionally, at operation 1665, the output sub-feature map may be compressed. The process 1600 then ends at operation 1670 by sending the output sub-feature map to the associated sparse tensor memory cluster 400, 500, or to another sparse tensor compute unit.

In some embodiments, the output sub-feature map may again be sub-divided into additional sub-feature maps, as discussed above in FIGS. 3A and 3B, based on sparsity to equalize the number of zeroes and non-zeroes in each of the additional sub-feature maps, and to equalize the workload in each of the sparse tensor compute units of the sparse tensor compute cluster 230. A similar rebalancing of the output sub-feature maps may be performed in the process 1200.

In some embodiments, where depth separable convolutions are implemented (e.g., where the feature map has multiple channels), the result from each channel may be stored as an intermediate output sub-feature map. For example, the sub-feature maps of each channel may perform operations 1605-1665, and the result of those operations may be stored as an intermediate output sub-feature map. In some embodiments, ReLU and pooling operations may not be performed on the intermediate output sub-feature maps. Thus, depending upon the number of channels, multiple intermediate output sub-feature maps may be obtained. For example, for three channels, three intermediate output sub-feature maps may be obtained. Each of the intermediate output sub-feature maps may then be combined by applying a 1×1 filter. The ReLU and pooling operations of the operation 1660 are then performed on the combined intermediate output sub-feature maps to obtain the output sub-feature map.

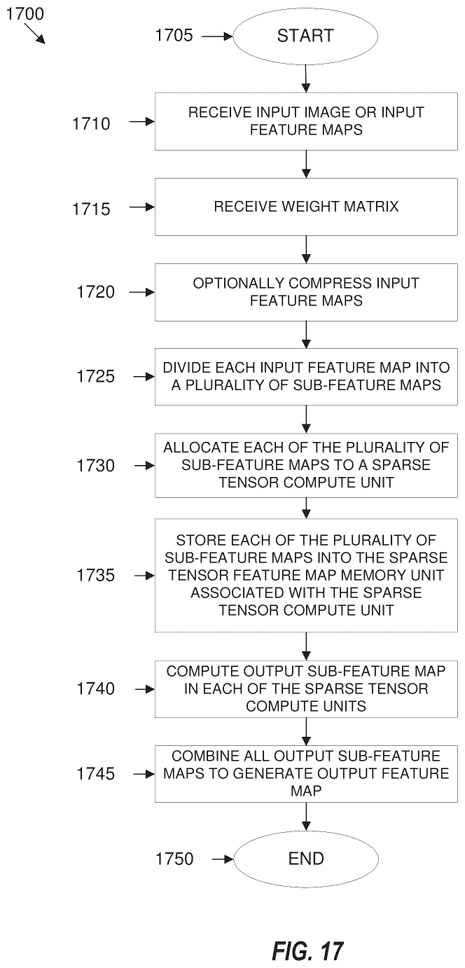

Turning now to FIG. 17, an example flowchart outlining operations of a process 1700 is shown, in accordance with some embodiments of the present disclosure. The process 1700 may include additional or other operations depending upon the particular embodiment. The process 1700 may be implemented by the accelerator 200. In some embodiments, the process 1700 may be implemented by the scheduling engine 225 of the accelerator 200. In other embodiment, the process 1700 may be implanted by another component of the accelerator 200. The process 1700 starts at operation 1705 when one or more machine learning operations are to be performed on a new input data (e.g., the input image 205) in a machine learning application. For example, when an image classification is to be done to identify one or more features in the input image, the process 1700 may be implemented. Thus, at operation 1710, the input image or the feature maps associated with the input image may be input into the accelerator 200.

The input image may be represented by an array of pixels based upon the size, height, and color scheme of the input image. Simply as an example and without intending to be limiting in any way, the process 1700 is explained below with respect to an input image of size 1024×1024×3. Thus, the input image is 1024 pixel wide and 1024 pixel high, and has 3 color channels. The input image may, thus, be treated as a combination of three feature maps, with one feature map for each color channel and each feature map having a size of 1024×1024×1. In some embodiments, the input image may be input into the accelerator 200, and the accelerator may derive the feature maps from the input image. In other embodiments, the conversion of the input image into the feature maps may occur outside the accelerator 200 (by another component on the host device (e.g., the host device 105) with which the accelerator 200 is associated), and the feature maps may be input into the accelerator instead of the input image. Further, the input image or the feature maps of the input image (whichever is input into the accelerator 200) may be stored within the DRAM 215 of the accelerator.

At operation 1715, the accelerator 200 receives a weight matrix (e.g., the weight matrix 220). Although the operation 1715 has been described as occurring after the operation 1710 in which the input image or the feature maps of the input image are received by the accelerator 200, in some embodiments, the operation 1715 may occur before the operation 1710. In some embodiments, the operations 1710 and 1715 may occur simultaneously or substantially simultaneously.

In some embodiments, the accelerator 200 may be configured for a neural network having a plurality of layers. For example, in some embodiments, the accelerator 200 may be configured for a convolutional neural network having a plurality of convolution layers. In some embodiments, each of the plurality of convolution layers may have a specific weight matrix that may be applied to the feature map of that layer. Thus, in such embodiments, the accelerator 200 may receive multiple weight matrices, with one weight matrix configured for one layer. Each weight matrix may include weight values that may be applied to the feature maps. Specifically, multiplication, addition, and other operations may be performed between corresponding weight values and the data values of the input feature map. In some embodiments, the weight matrix may also be compressed. In some embodiments, the weight matrix may at least temporarily be stored within the DRAM 215.

In some embodiments, the weight matrices, before or after compression, may also be reordered, and a static sparsity analysis performed on the weight matrices. The static sparsity analysis may be performed before or after the compression of the weight matrices. In some embodiments, the static sparsity analysis may be performed by the accelerator 200, while in other embodiments, the static sparsity analysis may be performed outside the accelerator. The static sparsity analysis identifies the weight values in a weight matrix that are zero. If a particular weight value is zero, the multiplication with that zero weight value is also zero. Thus, instead of allocating resources to multiply zero weight values with values in the feature maps, the results of those multiplication operations may directly be encoded as zero. Further, since the weight values that are zero in the weight matrix are known beforehand and do not change from one feature map to another, the sparsity in a weight matrix is static.

Thus, the weight matrices may be compressed and reordered, and a static sparsity analysis may be performed to identify zero weight values and obtain an input weight tensor from each weight matrix. Each of the input weight values may be stored within the DRAM 215, and assigned for computation with an input feature map based on a load and store schedule stored within the accelerator 200.

At operation 1720, each of the input feature maps of the input image are compressed, as discussed above. Although the operation 1720 is described after the operation 1715, in some embodiments, the operation 1720 may occur any time after the feature maps of the input image are available. Each of the feature maps may be compressed by recursively partitioning each of the feature maps into portions of smaller cell sizes, until a desired compression criteria is reached. The desired compression criteria may be based on the number of compression levels or the threshold minimum cell size, as discussed in greater detail in the U.S. application Ser. No. 16/726,084 mentioned above. The compression operations discussed throughout this disclosure may be performed as discussed in the U.S. application Ser. No. 16/726,084.

At operation 1725, each input feature map of the input image is divided into a plurality of sub-feature maps, as discussed in FIGS. 3A and 3B above. By dividing an input feature map into a plurality of sub-feature maps, each of the plurality of sub-feature maps may be processed in parallel. Further, the input feature map may be divided into the plurality of sub-feature maps, such that each of the plurality of sub-feature maps has the same or substantially similar sparsity. In some embodiments, the sparsity in each of the plurality of sub-feature maps satisfies a predetermined threshold (e.g., the predetermined percentage difference threshold discussed above). Thus, each of the plurality of sub-feature maps may have the same or similar number of zero values and/or non-zero values. Further, by dividing the input feature map into the plurality of sub-feature maps, the dynamic sparsity in the input feature map may be converted into static or close to static sparsity in each of the plurality of sub-feature maps.

Each of the plurality of sub-feature maps may be assigned to a sparse tensor compute unit based on the closeness of the where they are stored currently to the compute units (e.g., the sparse tensor compute units 1000, 1300, 1400, 1500) at operation 1730. At operation 1735, each of the plurality of sub-feature maps is stored in the sparse tensor feature map memory unit that is associated with the sparse tensor compute unit that is to process a particular one of the plurality of sub-feature maps. In some operations, a time folding operation may be performed if a particular sub-feature map is larger than the storage capacity of the sparse tensor feature map memory unit in which that sub-feature map is to be stored. In some embodiments, a time folding operation may be considered similar to the sub-feature partitioning described above in FIGS. 3A and 3B. In a time folding operation, the partitioning is based on the feature map size. For example, if the maximum size of an input image that is supported is 1024×1024 and if we have an input image that is 2048×2048 in size, then the large input image may be divided into four input feature maps, each input feature map having a size of 1024×1024.

At the operation 1735, the weight values to be applied to that particular one of the plurality of sub-feature maps are also transferred to the sparse tensor weight memory associated with the sparse tensor compute unit. When the sparse tensor compute unit becomes available, the sparse tensor feature map memory unit may transfer the particular sub-feature map to the sparse tensor compute unit. The sparse tensor weight memory may also transfer the weight matrix stored therein to the sparse tensor compute unit.

Each of the sparse tensor compute units processes the received sub-feature map to generate an output sub-feature map, at operation 1740 and as discussed above with respect to FIGS. 10-16. Each of the sparse tensor compute units may send their output sub-feature map back to the DRAM 215 or to another sparse tensor compute unit. In some embodiments, one or more output sub-feature maps may again be subdivided according to FIGS. 3A and 3B, and undergo further processing in a sparse tensor compute unit. Once all output sub-feature maps have completed processing, those output sub-feature maps may be combined to generate the output feature map at operation 1745. The process 1700 ends at operation 1750.

In some embodiments, at the output of each sparse tensor compute unit, the number of non-zeros in the output sub-feature map may be measured. As the output sub-feature maps are generated, it may be possible to redirect the output sub-feature map of one sparse tensor compute unit to another sparse tensor compute unit for balancing sparsity. However, in some embodiments, it may be easier and more efficient to balance the sparsity in output sub-feature maps after all the sub-feature maps are produced and stored in the sparse tensor feature map memories while supplying to the sparse tensor compute unit for the next convolution layer. For balancing sparsity in such a way, another network may be used to provide connectivity between sparse tensor feature map memories and sparse tensor compute units. When processing depthwise separable convolutions, point-wise or 1×1 convolutions may be performed using multiple intermediate feature maps. These intermediate feature maps may not be sparse as they just go through convolution only and not ReLU (activation). Also each intermediate feature map output may need to be stored back in DRAM. The sparsity arises at the final output of point-wise or lxi convolutions as these include ReLU(activation).

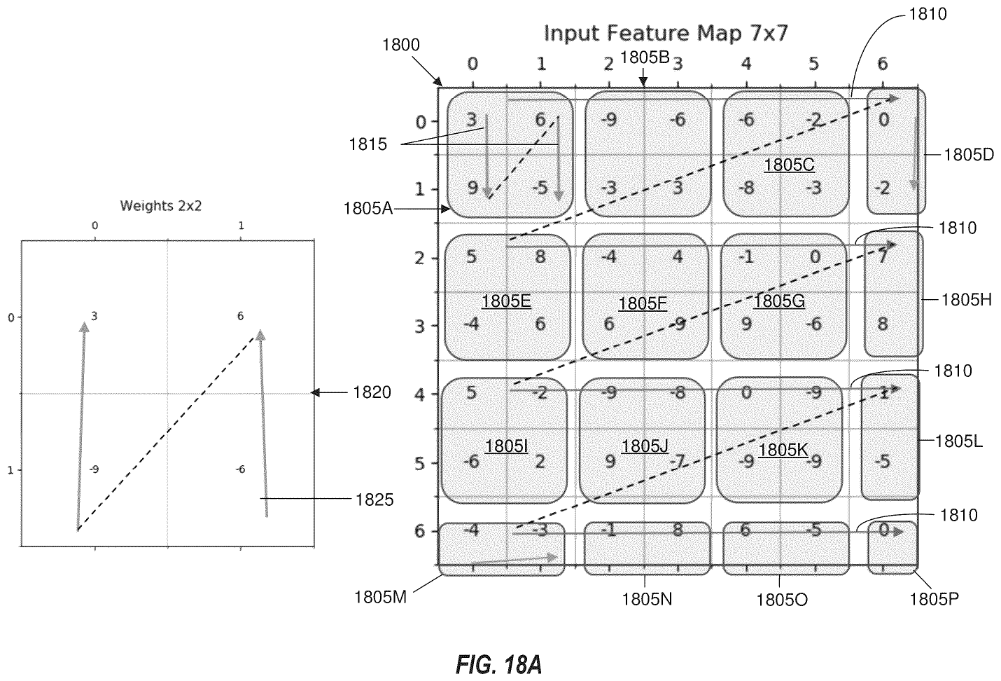

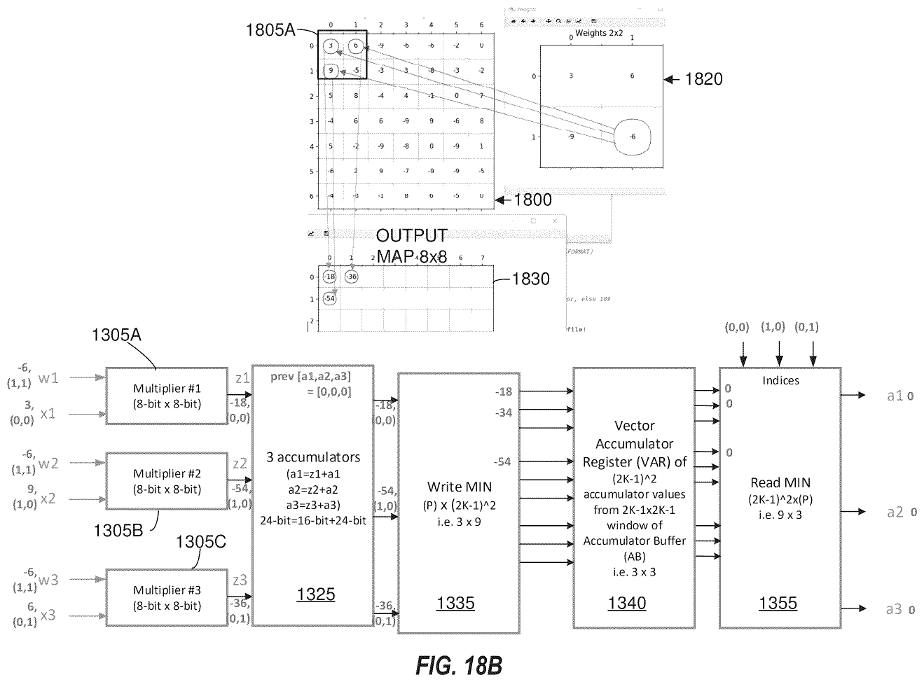

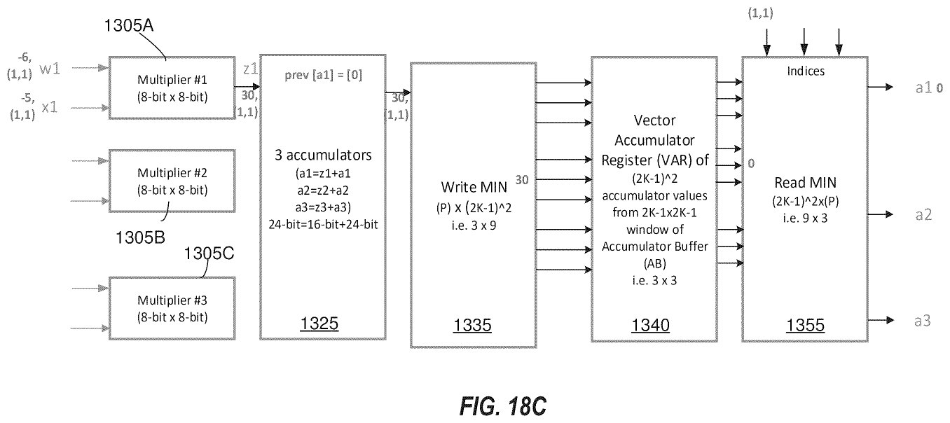

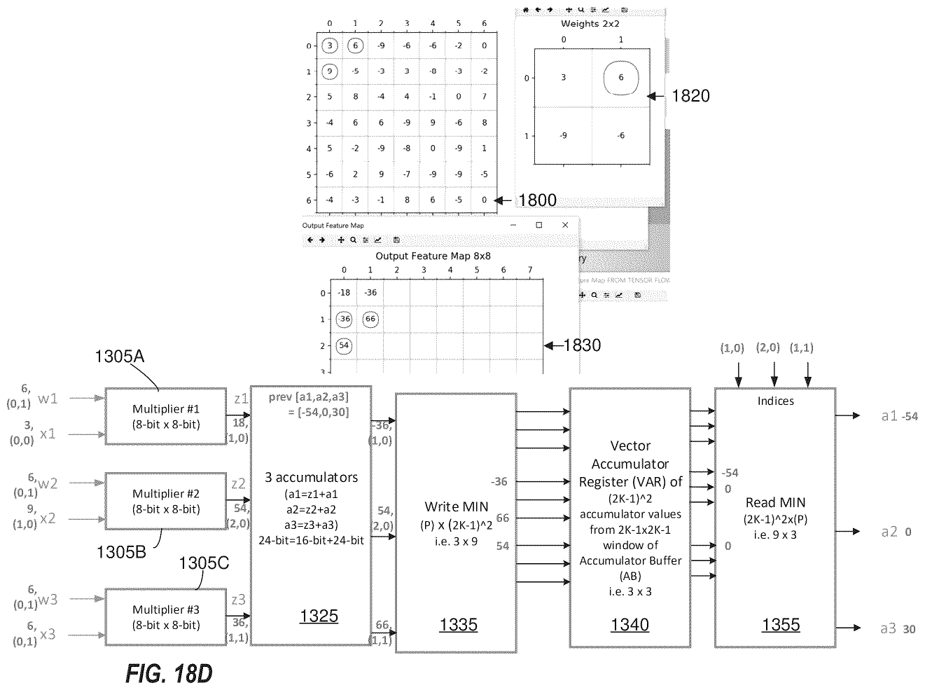

Turning now to FIGS. 18A-18D, an example of processing an input feature map 1800 in the sparse tensor compute unit 1300 is shown, in accordance with some embodiments of the present disclosure. It is to be understood that the input feature map 1800 is simply an example and is not intended to be limiting in any way. The present disclosure may be used to process input feature maps of any size and having any data values therein. The input feature map 1800 may be generated from the input image 205. As shown in FIG. 18A in particular, the input feature map 1800 may include a plurality of cells, each cell being formed at the intersection of a row (that extends in the X-direction 1105; see FIG. 11) and a column (that extends in the Y-direction 1110; see FIG. 11). Each of the plurality of cells in the input feature map 1800 includes a data value that is to be processed in the sparse tensor compute unit 1300.

Although not shown in FIG. 18A, in some embodiments, the input feature map 1800 may be padded by zeroes on all sides similar to the input feature map 1100. Further, in some embodiments, sub-feature maps may be created from the input feature map 1800 (or from the padded feature map when padding is used). In some embodiments, the input feature map 1800 may be divided into sub-feature maps in the partitioning block 210 or other component of the accelerator 200, as discussed above in FIGS. 3A and 3B. For example and as shown in FIG. 18A, the input feature map 1800 may be divided into a plurality of sub-feature maps 1805A-1805P. Each of the plurality of sub-feature maps 1805A-1805P may be processed in the sparse tensor compute unit 1300 in series (or in parallel in multiple instances of the sparse tensor compute unit 1300). In some embodiments, the plurality of sub-feature maps 1805A-1805P may be processed in an order shown by arrows 1810. For example, the sub-feature map 1805A may be processed first followed by the sub-feature maps 1805B-1805D. Then, the sub-feature maps 1805E-1805H may be processed, followed by the sub-feature maps 1805I-1805L, and so on. Further, within each of the plurality of sub-feature maps 1805A-1805P, the data values may be processed in an order shown by arrow 1815. The order in which the plurality of sub-feature maps 1805A-1805P are processed and/or the order in which the data values of each of the plurality of sub-feature maps are processed may vary in other embodiments. Additionally, in some embodiments, only non-zero data values may be input into the sparse tensor compute unit 1300.

Although each of the plurality of sub-feature maps 1805A-1805P includes two rows and two columns and those sub-feature maps are all of the same size, it is to be understood that in other embodiments, those sub-feature maps may be of varying sizes, may include varying numbers of rows and columns, and the data values within each of the plurality of sub-feature maps 1805A-1805P may vary. Further, depending upon the number of the plurality of multipliers 1305A-1305P in the sparse tensor compute unit 1300, multiple data values of each of the plurality of sub-feature maps 1805A-1805P may be processed in parallel. For purposes of explanation, FIGS. 18B-18D are explained with respect to the sub-feature map 1805A. However, the other ones of the plurality of sub-feature maps 1805B-1805P may be similarly processed. Further, FIGS. 18A-18D are described assuming that the number of the plurality of multipliers 1305A-1305P is three. Since the sub-feature map 1805A includes four non-zero data values, each iteration may include two rounds. In the first round, three data values of the sub-feature map 1805A may be processed and in the second round, the last data value of that sub-feature map may be processed. Since the data values are processed in the order shown by the arrow 1815, in the first round, the data values having the indices (0, 0), (0, 1), and (1, 0) may be processed, while in the second round the data value having the index (1, 1) may be processed.

The data values of the sub-feature map 1805A may be combined with weight values of a kernel matrix 1820. It is to be understood that the kernel matrix 1820 is simply an example and is not intended to be limiting in any way. The kernel matrix 1820 may assume other sizes (e.g., the number of rows and number of columns may vary from that shown) and the values within the kernel matrix may also vary. (There may also be separate memory allocations for special kernel cases, (all 0's, 1-value, 2-value, etc.), which can reduce the meta-data or descriptive mapping information needed to point to the right mapping.) Further, although each of the plurality of sub-feature maps 1805A-1805P has the same number of rows and the columns as the kernel matrix 1820, in some embodiments, one or more of the plurality of sub-feature maps may have varying number of rows and/or columns than the kernel matrix. The weight values in the kernel matrix 1820 may be applied in a designated order as shown by arrow 1825. Further, since the sparse tensor compute unit 1300 is configured for one unique weight value in each iteration, a single weight value is broadcast to each of the plurality of multipliers 1305A-1305P in each iteration.

Thus, to process the sub-feature map 1805A, the data values from that sub-feature map may be input into the plurality of multipliers 1305A-1305P. Assuming three multipliers, and as shown in FIG. 18B, the first three data values may be input into the plurality of multipliers 1305A-1305P. Specifically, the data value “3” may be input into the multipliers 1305A, the data value “9” may be input into the multiplier 1305B, and the data value “6” may be input into the multiplier 1305C. Further, each of the multipliers 1305A-1305C may receive the first weight value of “−6,” as shown in FIG. 18B and compute a product between their respective data values and the first weight value. Each of the multipliers 1305A-1305C may also receive the index values of the data values that each of those multipliers receive, as well as the index value of the first weight value. Based on the received index values, each of those multipliers 1305A-1305C may compute the result index values in the output sub-feature map where the results of the multiplication are to be stored. In some embodiments, the multipliers 1305A-1305C may compute the result index values using the formulae discussed above in FIG. 13.

The product values from the multipliers 1305A-1305C and the result index values may be sent to the accumulator 1325. The accumulator 1325 may also receive the addition results from the previous iterations from the MIN 1355, as shown in FIG. 18B. Specifically, the MIN 1355 may also receive the result index values and read the values from the VAR 1340 corresponding to the result index values, and send those values to the accumulator 1325, as shown in FIG. 18B. The accumulator 1325 may then add the product values of the current iteration to the product values of the previous iterations. The accumulator 1325 may transmit the results of the addition, as well as the result index values to the MIN 1335. The MIN 1335 may write the results of the addition to the VAR 1340 at the index locations identified by the result index values. As indicated above, the VAR 1340 is initialized with a portion from the accumulator buffer 1350. Thus, upon writing the results of the additions to the VAR 1340 at the index locations identified by the result index values, the VAR 1340 may have values as shown in an output map 1830, only a portion of which is shown in FIG. 18B.

In the second round of the first iteration, the remaining data value, “−5,” of the sub-feature map 1805A is input into the multiplier 1305A. The first weight value, “−6,” is also input into the multiplier 1305A, as shown in FIG. 18C. The index values of the data value and the first weight value are also input into the multiplier 1305A. The product value and the result index value are sent to the accumulator 1325, which adds the product value to the product value from the previous iterations, and sends the result to the VAR 1340 via the MIN 1335, as shown in the output map 1830 of FIG. 18C.

Referring now to FIG. 18D, in the first round of the second iteration, the data values “3,” “9,” and “6” are input into the multipliers 1305A, 1305B, and 1305C, respectively. Further, the second weight value “6” is input into the multipliers 1305A-1305C, as shown in FIG. 18D. Additionally, the index values of the data values and the second weight value may be input into the multipliers 1305A-1305C. The data values and the second weight value may be combined in the sparse tensor compute unit 1300, as discussed above with respect to the first round of the first iteration. The output of the first round of the second iteration may be stored in the output map 1830, as shown in FIG. 18D. The second round of the second iteration may be similar to the second round of the first iteration but with the second weight value instead of the first weight value. Similarly, each of the third weight value, “−9,” and the fourth weight value, “3” may be processed in the third iteration and the fourth iteration, respectively. Each of the third iteration and the fourth iteration may have two rounds, similar to the first iteration and the second iteration. The values in the output map 1830 at the end of the fourth iteration may form the output sub-feature map and may be stored within the accumulator buffer 1350.

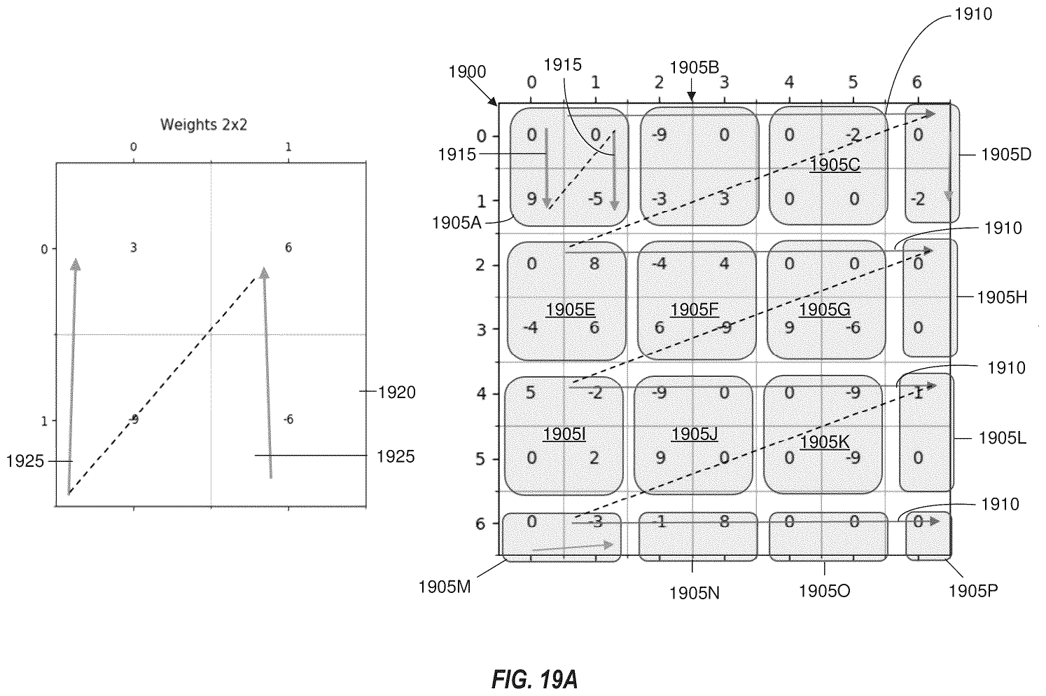

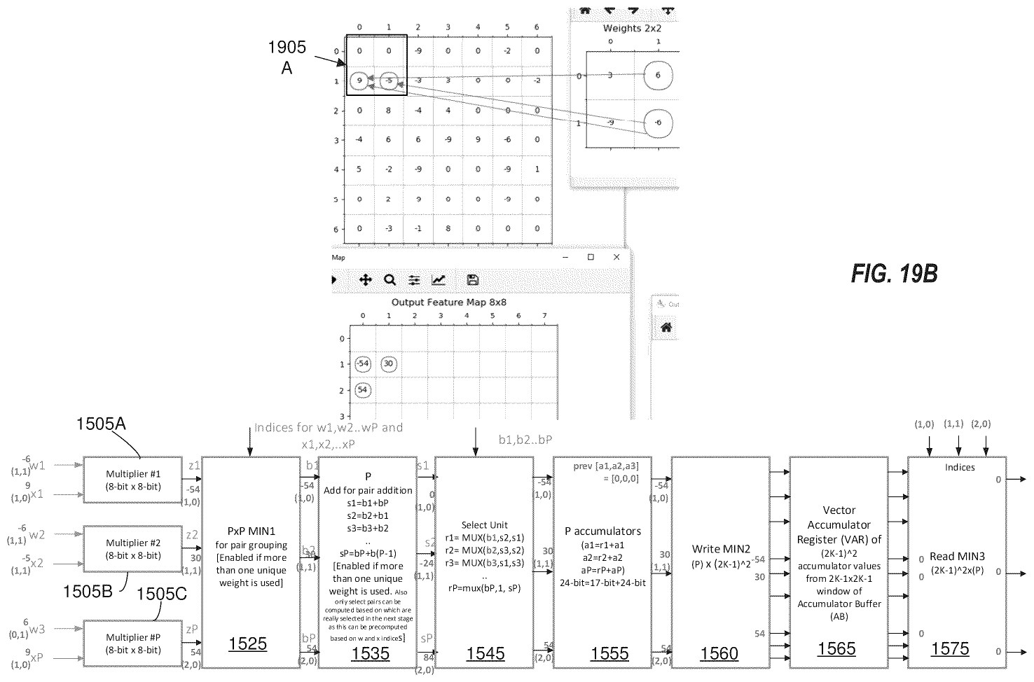

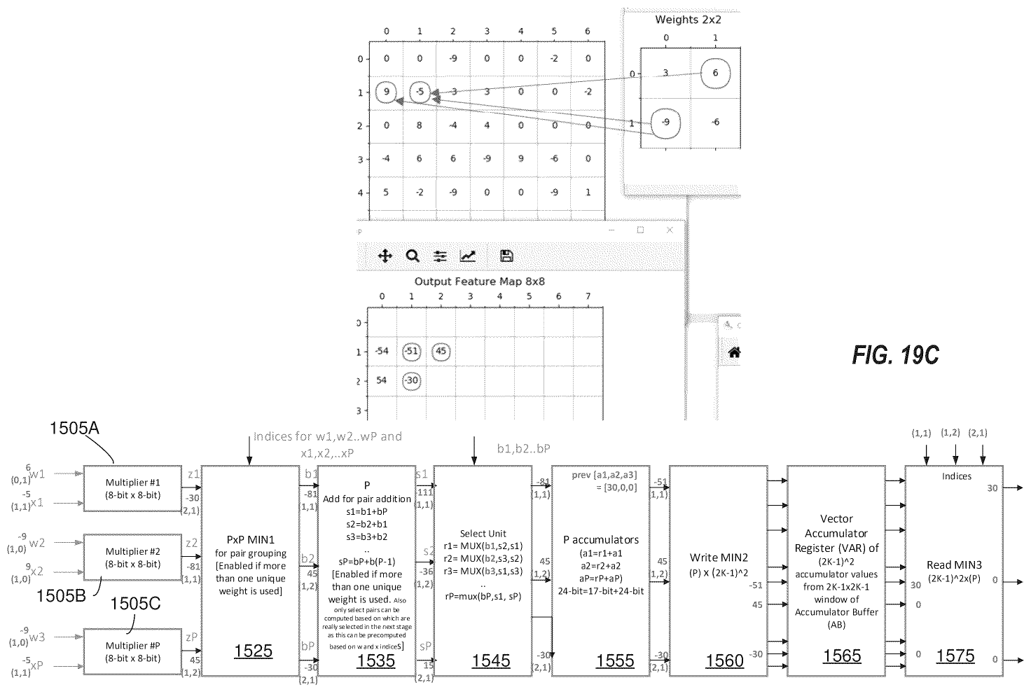

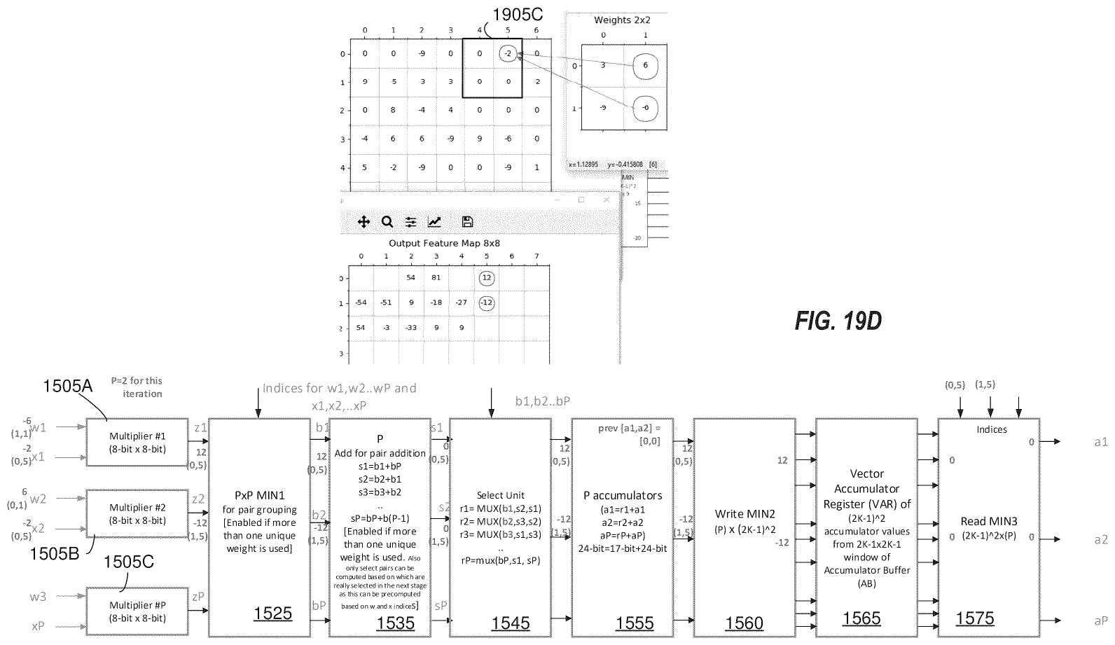

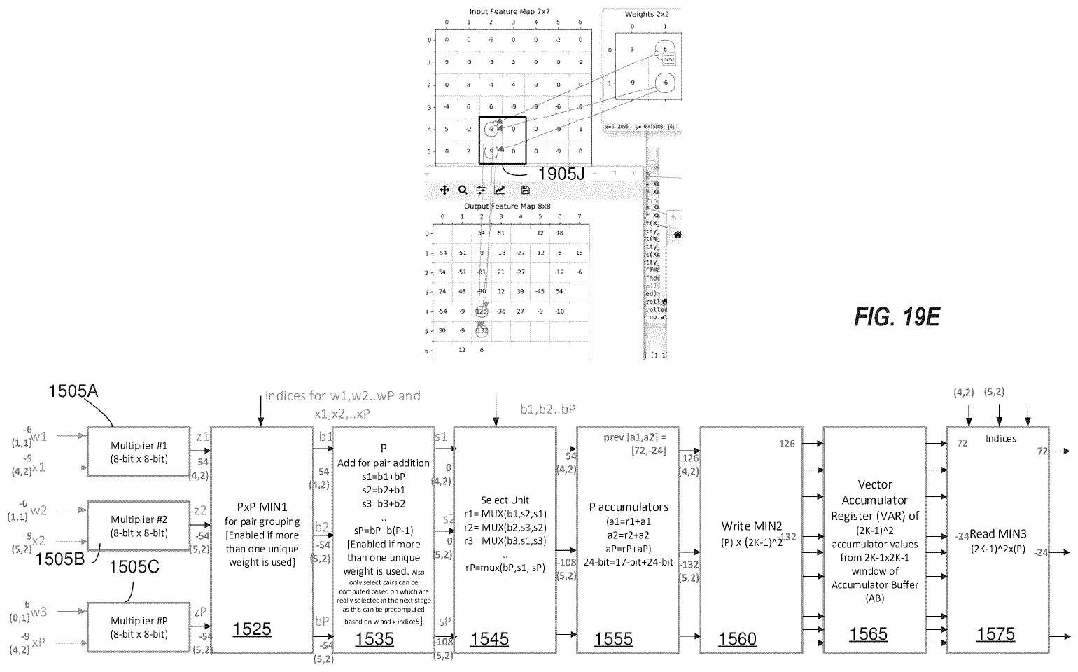

Turning now to FIGS. 19A-19E, an example of processing an input feature map 1900 in the sparse tensor compute unit 1500 is shown, in accordance with some embodiments of the present disclosure. It is to be understood that the input feature map 1900 is simply an example and is not intended to be limiting in any way. The present disclosure may be used to process input feature maps of any size and having any data values therein. The input feature map 1900 may be generated from the input image 205. As shown in FIG. 19A in particular, the input feature map 1900 may include a plurality of cells, each cell being formed at the intersection of a row (that extends in the X-direction 1105; see FIG. 11) and a column (that extends in the Y-direction 1110; see FIG. 11). Each of the plurality of cells in the input feature map 1900 includes a data value that is to be processed in the sparse tensor compute unit 1500.

Although not shown in FIG. 19A, in some embodiments, the input feature map 1900 may be padded by zeroes on all sides similar to the input feature map 1100. Further, in some embodiments, sub-feature maps may be created from the input feature map 1900 (or from the padded feature map when padding is used). In some embodiments, the input feature map 1900 may be divided into sub-feature maps in the partitioning block 210 or other component of the accelerator 200, as discussed above in FIGS. 3A and 3B. For example and as shown in FIG. 19A, the input feature map 1900 may be divided into a plurality of sub-feature maps 1905A-1905P. In some embodiments, at least some of the plurality of sub-feature maps 1905A-1905P may be processed in the sparse tensor compute unit 1500 in series (e.g., one after another). In other embodiments, at least some of the plurality of sub-feature maps 1905A-1905P may be processed in parallel in multiple instances of the sparse tensor compute unit 1500. In some embodiments, the plurality of sub-feature maps 1905A-1905P may be processed in an order shown by arrows 1910. Further, within each of the plurality of sub-feature maps 1905A-1905P, the data values may be processed in an order shown by arrow 1915. The order in which the plurality of sub-feature maps 1905A-1905P are processed and/or the order in which the data values of each of the plurality of sub-feature maps are processed may vary in other embodiments. Additionally, in some embodiments, only non-zero data values may be input into the sparse tensor compute unit 1500.

Although each of the plurality of sub-feature maps 1905A-1905P includes two rows and two columns and those sub-feature maps are all of the same size, it is to be understood that in other embodiments, those sub-feature maps may be of varying sizes, may include varying numbers of rows and columns, and the data values within each of the plurality of sub-feature maps 1905A-1905P may vary. Further, depending upon the number of the plurality of multipliers 1505A-1505P in the sparse tensor compute unit 1500, multiple data values of each of the plurality of sub-feature maps 1505A-1505P may be processed in parallel. For purposes of explanation, FIGS. 19B-19E are explained with respect to the sub-feature map 1905A. However, the other ones of the plurality of sub-feature maps 1905B-1905P may be similarly processed. Further, FIGS. 19A-19E are described assuming that the number of the plurality of multipliers 1505A-1505P is three. Since the sub-feature map 1905A includes only two non-zero data values, each iteration may include a single round. It is to be understood that the number of rounds in each iteration may vary from one sub-feature map to another sub-feature map. For example, the sub-feature map 1905B includes three non-zero data values and since three multipliers are used in the current example, each iteration of processing that sub-feature map may still include a single round. On the other hand, the sub-feature map 1905F includes four non-zero data values. Thus, with three multipliers, each iteration of processing the sub-feature map 9105F may include two rounds.

The data values of the sub-feature map 1905A may be combined with weight values of a kernel matrix 1920. It is to be understood that the kernel matrix 1920 is simply an example and is not intended to be limiting in any way. The kernel matrix 1920 may assume other sizes (e.g., the number of rows and number of columns may vary from that shown) and the values within the kernel matrix may also vary. Further, although each of the plurality of sub-feature maps 1905A-1905P has the same number of rows and the columns as the kernel matrix 1920, in some embodiments, one or more of the plurality of sub-feature maps may have varying number of rows and/or columns than the kernel matrix. The weight values in the kernel matrix 1920 may be applied in a designated order as shown by arrow 1925. Further, as indicated above, the sparse tensor compute unit 1500 is configured to process multiple weight values in each iteration. Thus, depending upon the number of non-zero data values and the number of multipliers, multiple weight values may be broadcast in each iteration. The example of FIGS. 19A-19E is explained assuming two unique weight values may be broadcast in each iteration.

For example and as shown in FIG. 19B, the sub-feature map 1905A includes two non-zero values only. Thus, only the first two of the three multipliers need to be engaged in the first iteration to process the two non-zero data values. However, to increase performance and utilize resources at full capacity, a second weight value and the first non-zero data value may be broadcast to the third multiplier. For example, the data values “9” and “−5” of the sub-feature map 1905A may be input into the multiplier 1505A and 1505B, respectively. Further, the first weight value “−6” may be input into the multipliers 1505A and 1505B. Since we have three multipliers, the first non-zero data value in the order shown by the arrow 1915 is “9,” which is input into the multiplier 1505C. Further, the second weight value “6” is input into the multiplier 1505C to start the second iteration. Thus, the second iteration overlaps with the first iteration.

Each of the multipliers 1505A-1505C may also receive the index values of the data values that each of those multipliers receive, as shown in FIG. 19B. Further, each of the multipliers 1505A and 1505B receives the index value of the first weight value and the multiplier 1505C receives the index value of the second weight value. Based on the received index values of the data values, the first weight value, and the second data value, each of those multipliers 1505A-1505C may compute the result index values in the output sub-feature map where the results of the multiplication are to be stored, as discussed above. The product results as well as the result index values may be transmitted to the MIN 1525. Since the result index values computed in the multipliers 1505A-1505C are different from one another, the MIN 1525 simply passes the product results and the result index values to the addition block 1535.

The addition block 1535 may perform the following additions:

$$s 1 = b 1 + b 3$$

$$s 2 = b 2 + b 1$$

$$s 3 = b 3 + b 2$$

In the formulae above, b1, b2, and b3 are the outputs from the MIN 1525 and correspond to the product results generated by the multipliers 1505A, 1505B, and 1505C, respectively. As further shown in FIG. 19B, the sums from the addition block 1535 and the result index values may be input into the select unit 1545, which includes a plurality of multiplexers. In some embodiments, to process results from three multipliers, the select unit 1545 may include three multiplexers.

The results from the multiplexers of the select unit 1545 and the result index values may be sent to the accumulator 1555, which adds the s1, s2, and s3 values respectively to those values from the previous iteration, as discussed above and shown in FIG. 19B. Specifically, the result index values may be input into the MIN 1575, which may read values corresponding to those index values from the VAR 1565 and transmit those read values to the accumulator 1555. The results from the accumulator and the result index values may be transmitted to the MIN 1560 and written into the VAR 1565.

FIG. 19C shows the second iteration (or rather the second half of the second iteration), which overlaps with the second iteration. As discussed above, the second weight value and the data value “9” are processed during the first iteration (or the first half of the second iteration). In the second half of the second iteration, the remaining non-zero data value “−5” is input into the multipliers 1505A along with the second weight value. Since there are three multipliers, the remaining two non-zero data values are input into the multipliers 1505B and 1505C along with the third weight value, “−9.” Thus, the second half of the second iteration and the third iteration occur in parallel. The processing of the second iteration is similar to that of the first iteration, and therefore, not described again. Similarly, the sub-feature map 1905A may be processed with the remaining weight values.

FIG. 19D shows an example of the sub-feature map 1905C having a single non-zero data value. With a single non-zero data value and three multipliers, in some embodiments, three weight values may be applied in a single iteration. For example, in the first iteration, the non-zero data value “−2” may be input into the multiplier 1905A along with the first weight value “−6.” With two remaining multipliers, the non-zero data value “−2” may also be input into the multiplier 1905B along with the second weight value “6” and into the multiplier 1905C along with the third weight value “−9.” However, if the sparse tensor compute unit 1900 is configured to limit the number of unique weight values in a particular iteration to two, only the first and the second data weight values may be processed in the first iteration. In such a case, the multiplier 1905C may not receive the non-zero data value “−2” with the third weight value. Rather, the multiplier 1905C may sit idle, as shown in FIG. 19D. The processing in the first iteration using the multipliers 1905A and 1905B may proceed similar to what is described above.

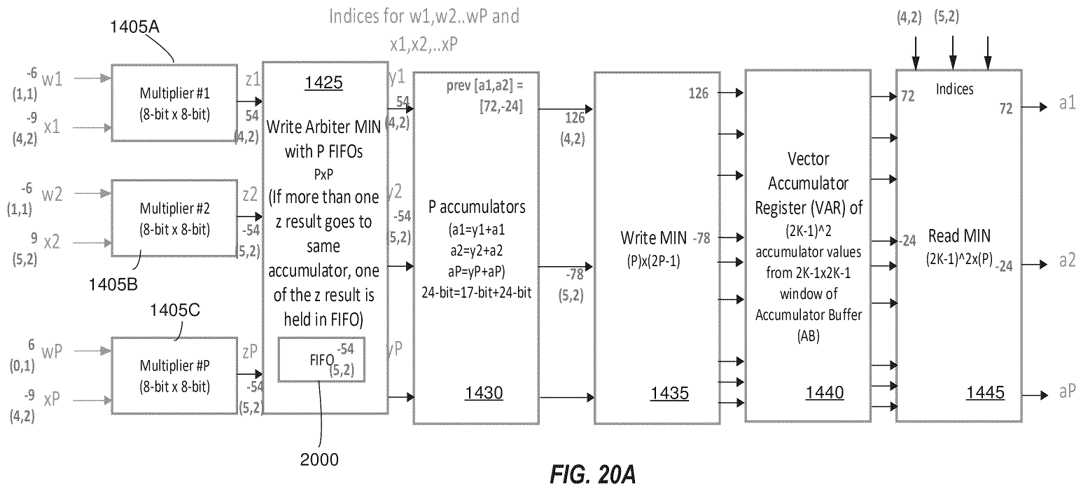

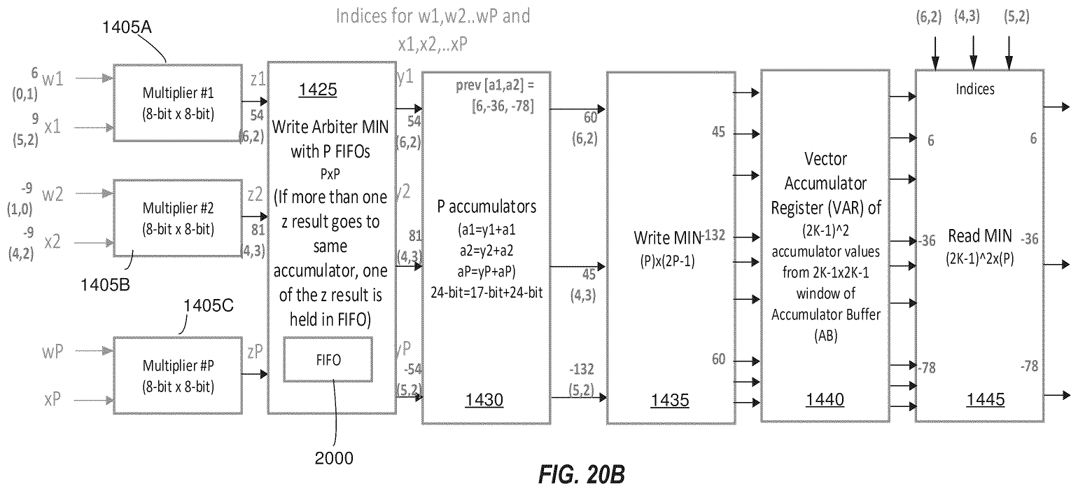

FIG. 19E shows an example in which the result index values of one iteration and the overlapping half of the next iteration overlap. For example, the sub-feature map 1905J includes two non-zero values, which may be processed similar to what is describe above for the sub-feature map 1905A. However, the result index value of (5, 2) computed for the product of the data value “9” and the first weight value of “−6” is same as the result index value of (5, 2) computed for the product of the data value “−9” and the second weight value of “6.” In such a case, a merge operation may be performed, as discussed in FIGS. 20A and 20B below.

The example of FIGS. 19A-19E may also be used to process the input feature map 1900 using the sparse tensor compute unit of FIG. 14. The sparse tensor compute unit 1400 is intended to be used with two unique weight values. Thus, the example of FIGS. 19A-19E may also apply to the sparse tensor compute unit 1400. The sparse tensor compute unit 1400 is similar to the sparse tensor compute unit 1500 with the exception of the addition block 1535 and the select unit 1545. Since the MIN 1525 is similar to the MIN 1425, the data from the MIN 1425 may be transmitted directly to the accumulator 1430 in the sparse tensor compute unit 1400 instead of the MIN 1525 transmitting the data to the addition block 1535 in the sparse tensor compute unit 1500. The MIN 1425 and the MIN 1525 may both be used to avoid a collision when two product values have the same result index value. When such a collision occurs, the MIN 1425 and the MIN 1525 apply a merging operation, discussed in FIGS. 20A and 20B below.

Turning now to FIGS. 20A and 20B, an example of a merging operation is explained, in accordance with some embodiments of the present disclosure. The merging operation is described with respect to the sparse tensor compute unit 1400, but the merging operation may similarly be implemented in the sparse tensor compute unit 1500. As discussed above with respect to the sub-feature map 1905J and FIG. 19E, the result index value of (5, 2) computed for the product of the data value “9” and the first weight value of “−6” is same as the result index value of (5, 2) computed for the product of the data value “−9” and the second weight value of “6.” The merging operation resolves the collision in the result index value. The merging operation may be implemented by the MIN 1425 in the sparse tensor compute unit 1400 (or the MIN 1525 in the sparse tensor compute unit 1500). In some embodiments, the MIN 1425 (and the MIN 1525) may include a FIFO (first in first out buffer) 2000 to resolve the collision.

When the MIN 1425 (or the MIN 1525) receives the result index values from the plurality of multipliers 1405A-1405P, upon detecting the collision, the MIN may transfer one of the product values and the corresponding result index value to the FIFO 2000. In some embodiments, the product value and the corresponding result index value that is transferred to the FIFO 2000 may be based on the order in which the weight values are being processed. For example, in the example of the sub-feature map 1905J, the product value corresponding to the second weight value may be transmitted to the FIFO 2000 instead of the product value corresponding to the first weight value. In some embodiments, the MIN 1425 (and the MIN 1525) may be programmed with which product value to transfer to the FIFO 2000. If there are more than two collisions (e.g., more than two product values having the same result index value), all colliding product values may be sent to the FIFO 2000 except one.

Upon transferring the product value(s) to the FIFO 2000, the remaining product values and their corresponding result index values may be transmitted to the accumulator 1430 (in the sparse tensor compute unit 1400) or to the addition block 1535 (in the sparse tensor compute unit 1500). Thus, when three values are being processed in parallel in the plurality of multipliers 1405A-1405C and there is a collision between two product values, one of the colliding product values is stored in the FIFO 2000, and only two product values are further processed. The product value stored in the FIFO 2000 is processed in the next round/iteration. Thus, as shown, in FIG. 20B, in the next round/iteration of processing the sub-feature map 1905J, only two data values are input into the plurality of multipliers 1405A-1405P to generate two product values. The two product values are sent to the MIN 1425, and if there is no collision between the product values received by the MIN and the product value stored in the FIFO 2000, three product values are output by the MIN, as shown in FIG. 20B. The remaining downstream processing then proceeds normally, as discussed above.

Index Value Compression and Separation of Data Path Processing from Index Processing

In this section, further information pertaining to exemplary FAST CNN systems is provided, along with various enhancements and/or alternatives to the systems and procedures described above, including index value compression and the separation of index processing from data path processing.

Generally speaking, 2D convolution is a process in which a kernel is convolved with a feature map as the region of overlap is stepped by a “stride” value. Each step involves a point by point multiplication with the kernel and the region of overlap, and then a summation of the product. As explained above, the feature-map value may be read from a memory/cache multiple times as the region of overlap is stepped for each convolution point. By separating the multiplications additions and accumulations, FAST-CNN improves the efficiency by exploiting the sparsity. Herein, systems are described wherein multiplication operations for different regions of overlap are computed only if the entry is non-zero (e.g., non-0). Additionally, storage is skipped for any zero entries in the feature maps. This can achieve the additional benefit of reading the feature-map memory/cache just once. In this manner, the number of reads required for feature maps can be minimized. As noted above, there may also be separate memory allocations for special kernel cases, (all 0's, 1-value, 2-value, etc.), which can reduce the meta-data or descriptive mapping information needed to point to the right mapping. Note also that the compression schemes described herein can be used in connection with a variety of memory or storage devices, including volatile or non-volatile (persistent) storage devices, including processor memory/caches, DRAM, or NAND storage devices. For example, if there is a multi-tier memory stack, the compression schemes may be applied to various tiers in the stack.

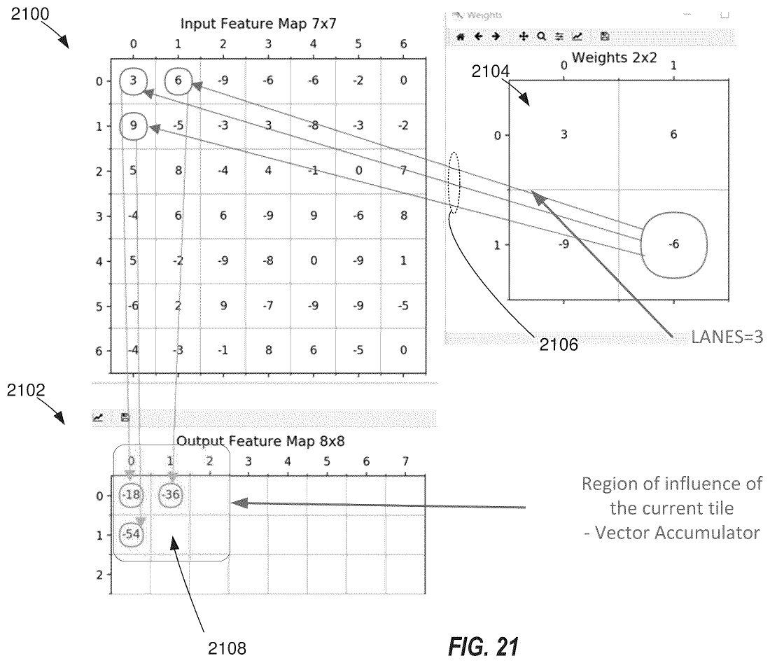

FIG. 21 illustrates an exemplary input feature map 2100, a portion of an output feature map 2102, and various exemplary weights 2104. In this example (which is also shown on the top of FIG. 18B), the input feature map is 7×7, the output feature map is 8×8, and the exemplary weights are represented by a 2×2 matrix or tile. The figure also illustrates three “lanes” 2106, which correspond to the number of parallel multiply-accumulate (MAC) operations allowed in the particular hardware system used to implement the FAST CNN. The parallel lanes thus provide for parallelization of operations. The figure further illustrates a region of influence 2108 of a current tile within a vector accumulator, such as the various vector accumulator registers (VAR) discussed above. Note that the region of influence may correspond to a cache of accumulated destinations that are influenced by a current tile.

For convenience, the following terms or nomenclature are used herein:
Tile: a k×k grouping of the feature map (FM) data; ‘k’ is the dimensions square weight matrix
nK: the number of non-0 entries in the weight matrix;
nX: the number of non-0 entries in the current tile;
Lanes: the number of parallel MAC operations allowed in the system;
Vector Accumulator: a cache of accumulate destinations that are influenced by a current tile; and
Accumulate buffer: a memory block containing past (and future un-accumulated) entries of the accumulator.

Note that, although a square k×k weight matrix may be used, in other examples a rectangular weight matrix (kh×kw) may be used. The schemes described herein work for the generalized rectangular weight matrix, which covers the normal case when kh=kw.

Index-value compression may be exploited in FAST CNN. For example, each non-0 feature-map value may be stored in sequence in the memory, along with its relative index within the tile. A “tile-marker” may be used to denote the end-of-tile. So if the last value of the tile is in-fact zero, then a zero value may be forced back on this entry to denote the end-of-tile.

Note that 2D convolution provided in accordance with unroll and compression operations described herein uses a 2-level nested unroll of the weight feature-map matrix over every entry in the weight matrix. As each element-wise product is computed, it is spatially accumulated in the accumulate buffer at the particular index that was determined based on the indices of the multiplicands. This compression scheme allows the input feature map to be read sequentially (tile-by-tile) and the accumulate buffer result computed in such a sequence that at most one successive column comes into the “region of influence” of the current tile computation. This allows for the accumulate buffer to be implemented with a single read-only path and single write-only path, and a simple address generator. Hence, there is no need for caching/read-modify-write structures. This simplifies the memory control design, including simple sequential address generators, eliminating requirements for expensive cache-like structures and also reduces power.

Referring again briefly to the example of FIG. 18A, which illustrates the same input feature map values, the vertical arrows (e.g., arrows 1815 and 1825) indicate an order of compression of the feature-map and weights. When this order is used to “unroll” the weights of the feature-map, the region of influence moves sequentially column-by-column in the VAR. The cell groupings are shown with a shaded background and correspond to a “Tile.” In some examples, the cell dimensions=kh×kw (or the residue of the remainder is less than kh (in height dimension and kw (in the width dimension), respectively) referenced in the illustrations. The direction of vertical arrows thus shows the sequence of elements picked to unroll a given cell. Arrows 1810 show the sequence of cells picked. That is, the horizontal arrows 1810 show a tile-wise step-through of the FM. Tiles are unrolled nK times in the sequence shown by the other arrows. These index-value compression operations and unroll operations will be described in greater detail below.

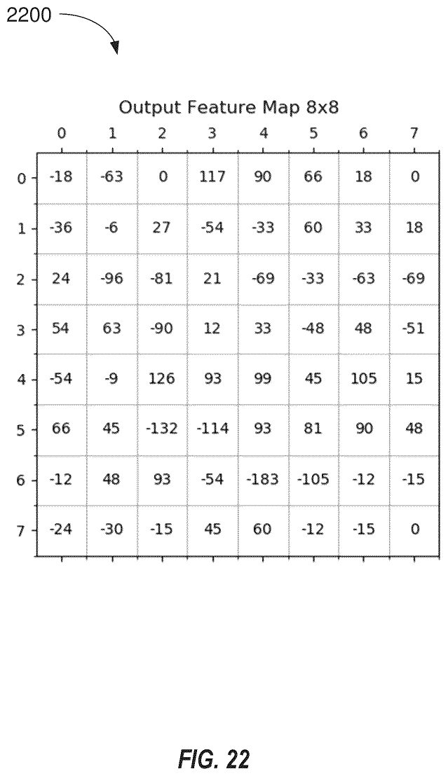

FIG. 22 illustrates an exemplary convolution result 2200, which in this example is 8×8 output feature map. In the descriptions above, several iterations are described (primarily with reference to FIGS. 18A-20B) of a convolution procedure. Further details of these iterations will now be provided.

Exemplary values for the first iteration of the procedure are as follows.

###### Iteration 1 ######
x_arr: [3 9 6]
x_idx:
[[0 0 0 0]
[0 0 1 0]
[0 0 0 1]]
w_arr: [−6 −6 −6]
w_idx:
[[0 0 1 1]
[0 0 1 1]
[0 0 1 1]]
prev_a [0 0 0]
z_arr [−18 −54 −36]
z_idx:
[[0 0 0 0]
[0 0 1 0]
[0 0 0 1]]
a [−18 −54 −36]

Exemplary values for the second iteration are as follows.

###### Iteration 2 ######
x_arr: [−5]
x_idx:
[[0 0 1 1]]
w_arr: [−6]
w_idx:
[[0 0 1 1]]
prev_a [0]
z_arr [30]
z_idx:
[[0 0 1 1]]
a [30]

Exemplary values for the third iteration are as follows.

###### Iteration 3 ######
x_arr: [3 9 6]
x_idx:
[[0 0 0 0]
[0 0 1 0]
[0 0 0 1]]
w_arr: [6 6 6]
w_idx:
[[0 0 0 1]
[0 0 0 1]
[0 0 0 1]]
prev_a [−54 0 30]
z_arr [18 54 36]
z_idx:
[[0 0 1 0]
[0 0 2 0]
[0 0 1 1]]
a [−36 54 66]

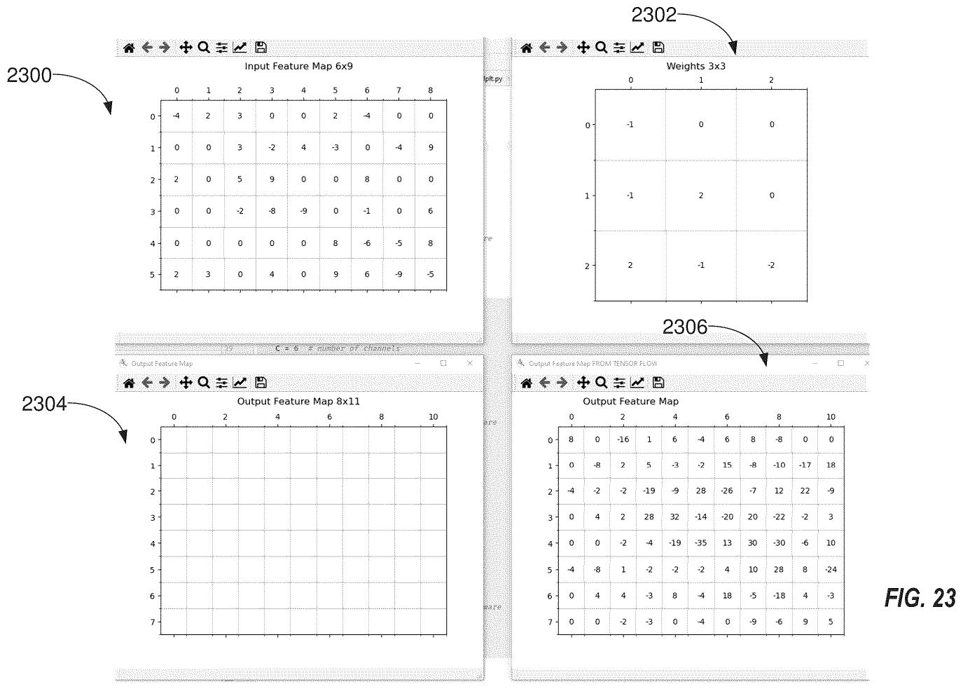

Turning now to FIGS. 23-27, further details of an exemplary CONV2D compression procedure are provided in which zero entries are suppressed. FIG. 23 illustrates a 3×3 kernel 2302 showing some sparsity, a 6×9 input feature-map 2300 showing some sparsity, an output feature map 2304 that has not been populated, and an expected output feature map 2306, as algorithmically computed. Note that the output feature map 2304 is initialized to all-0s (shown as blank cell in the figure).

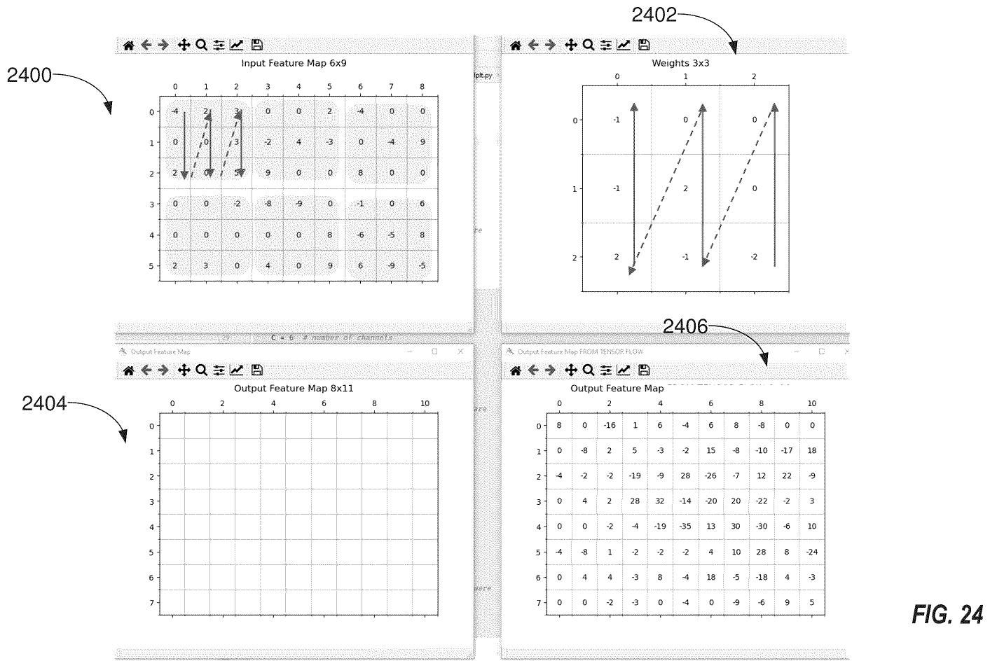

FIG. 24 illustrates the same kernel 2402, input feature-map 2400, output feature map 2404 and expected output feature map 2406 of FIG. 23, but with arrows illustrating aspects CONV2D operations. For a given kernel size K×K (3×3 here), the input feature map is divided into the K×K sized logical groupings, that we call “tiles.” For computation, the kernel and input feature map (iFM) are linearized in the sequence shown, then each element of the linear weights array is multiplied with every element of linear tile array. Each product is positionally accumulated to generate the output feature map 2406. The Weights array is linearized as [−2,0,0,−1,2,0,2,−1,−1]. The Input array is linearized as [−4,0,2,2,0,0,3,3,5]. When compressed by zero suppression, the resultant arrays are shortened to W=[−2,−1,2,2,−1,−1] and X=[−4,2,2,3,3,5],[0,−2,9 . . . −3,0], . . . .

In a next stage: the Weights array is linearized as [−2,0,0,−1,2,0,2,−1,−1]. The Input array is linearized as [−4,0,2,2,0,0,3,3,5],[0,−2,9 . . . −3,0] . . . . When compressed by zero suppression, the resultant arrays are shortened to W=[−2,−1,2,2,−1,−1] and X=[−4,2,2,3,3,5],[−2,9,2,−3] . . . . Each value element of the compressed data structure needs an index also stored to maintain its positional information Widx=[(2,2),(1,2),(1,1),(0,2),(0,1),(0,0)] and Xidx=[(0,0),(0,2),(1,0) . . . (2,2)],[(0,1) . . . (2,1) with X indices are relative to its own tile top-left index. The max number of bits used to store an index element: IDX_WID=log₂(W_ROW_LEN*W_COL_LEN). While the zero suppression reduces the depth of feature map/weight memory by a proportion equal to the proportion of zeroes (i.e. sparsity), the width is increased by IDX_WID number of bits.

Thus, in some aspects, zeroes are suppressed, which represents a form of run-length compression. For data sets that are mostly zero, significant compression is achieved. Still further, special processing may be provided for handling “near-zero” kernels, e.g., kernels with all values except one being zero. A kernel with all values except one being zero may also be called a “single value kernel.” Similarly to an all-zero kernel reducing to zero in the kernel MAC, a single value in one kernel results in that value multiplied by the sum of the values in the other kernel, so an optimization may be performed to accumulate (add) all of the other kernels together and then multiply the sum and the lone value together, rather than performing a multiplication of the lone value with every value in the other kernel (thus saving numerous multiplication steps and allowing for more efficient pipelining of the addition operations.) To this end, it may be advantageous to perform an accumulate on the memory pipeline when the kernel is pulled to calculate the sum of each kernel. It may also be advantageous to: perform a check in hardware for only one value that is non-zero when pulling data from memory; operate on all-zero kernels as a kernel with a single zero value; and store the sum of the values in memory for faster calculations. In cases where all of the kernel elements are positive, accumulations and max values can be captured and compared using simple logic. If both the accumulation and the maximum value are the same, that can trigger a single-value-type operation. (This may also be combined with a “is the max equal to zero?” operation to trigger a zero assignment instead of the calculation as well.)

Still further, it may be advantageous to take near 2^{N} values and make them 2^{N} values in the case of single non-zero element kernels. For example, since 9 is close to 8, multiplication by 8 might be used instead, since multiplication by 8 can be done by shifting data. This may be acceptable, for example, if the data corresponds to a neural network (NN) where precise calculations are not needed. In other aspects, near zero data may be trimmed to zero. This has advantage of putting more of the data into zero categories. For example, a kernel with all values except for one being zero, with that value being a 1 (or even a 2), may not add much to the overall result, and therefore can be assigned to zero so that the kernel result could be dropped. Such trimming can be done on the fly or in advance in the NN weights.

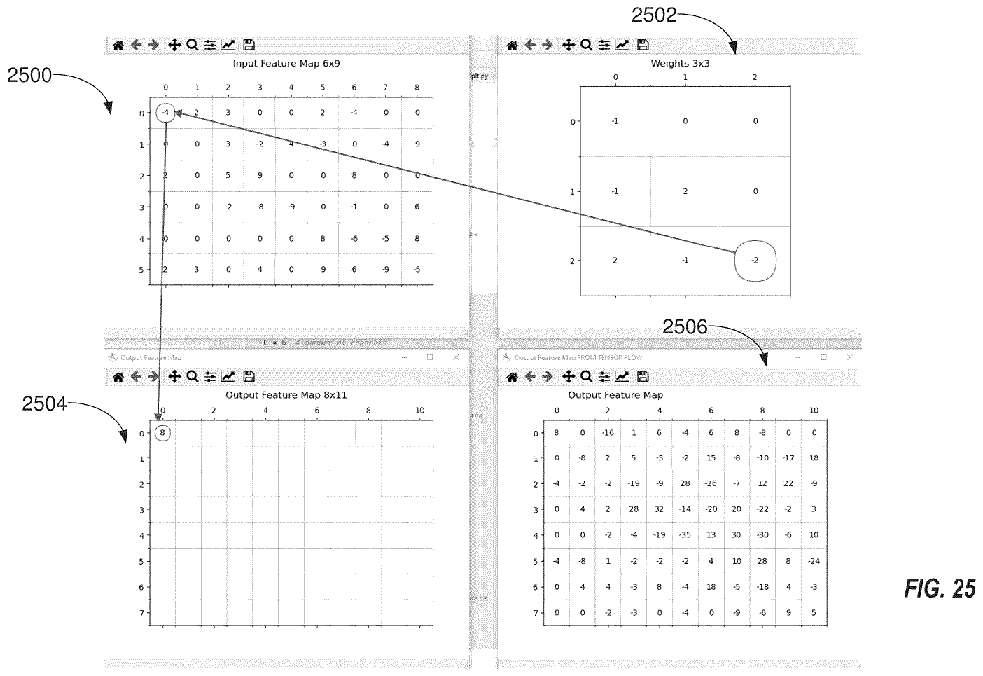

FIG. 25 illustrates the same kernel 2502, input feature-map 2500, output feature map 2504 and expected output feature map 2506 of FIGS. 23 and 24, but with arrows illustrating a first operational stage of CONV2D operations. In this stage: Weights array element: W_{2,2}=−2; Input feature map element: X_{0,0}=−4; The destination index for this product is calculated as:

$$XW\_row \_idx = X\_row \_idx - W\_row \_idx + W\_ROW \_LEN - 1$$

$$XW\_col \_idx = X\_col \_idx - W\_col \_idx + W\_COL \_LEN - 1$$

### Where:

XW_row/col_idx: is the index of the product in the destination accumulate buffer;
X_row/col_idx: is the index of the first multiplicand (from the Input feature map buffer);
W_row/col_idx: is the index of the second multiplicand (from the weights buffer);
W_ROW/COL_LEN: is the dimensions of the weights buffer.

The product element XW is accumulated at the index 0,0: XW_{0,0}=8.

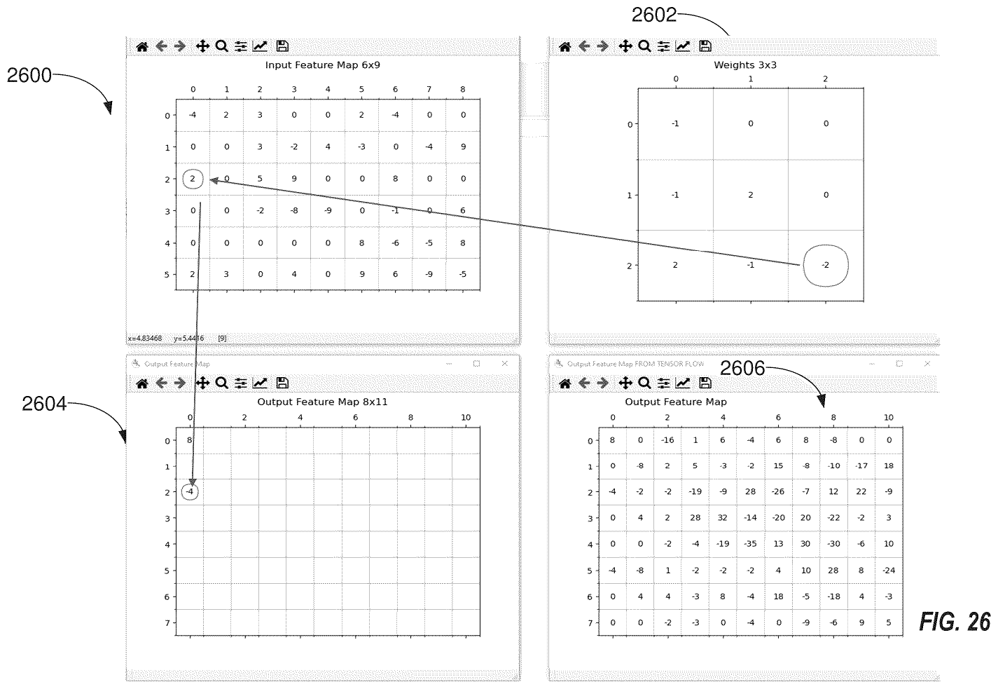

FIG. 26 illustrates the same kernel 2602, input feature-map 2600, output feature map 2604 and expected output feature map 2606 of FIGS. 23-25, but with arrows illustrating a second operational stage of CONV2D operations. In this stage: Weights array element: W_{2,2}=−2; and Input feature map element: X_{0,2}=−2. The product element XW is accumulated at the index 0,2: XW_{0,2}=−4. If other combinations of X and W indices result in XW index that has been addressed before, the result is accumulated with (added to) the previous result.

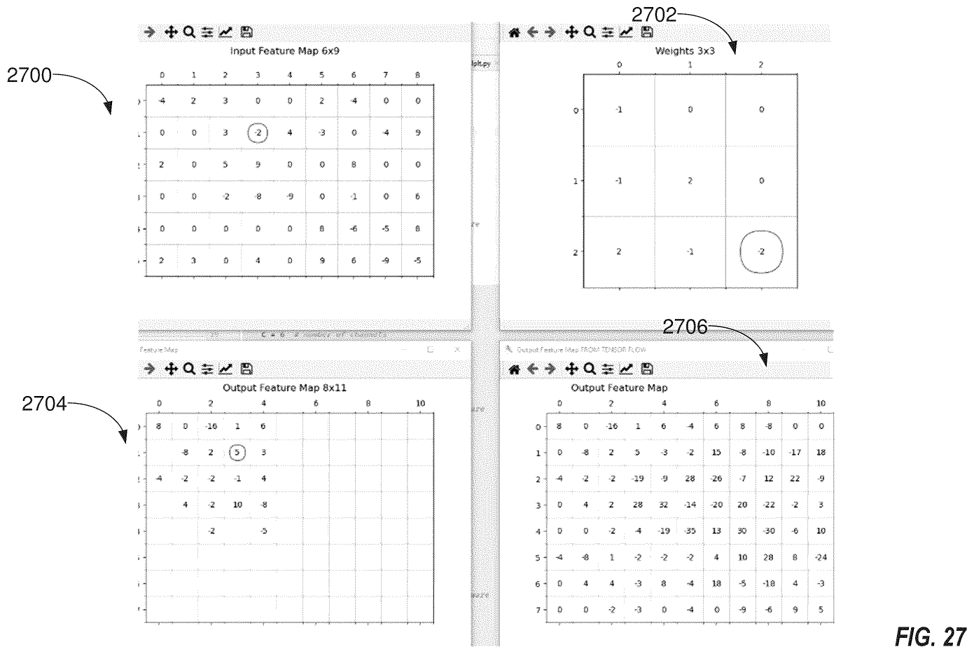

FIG. 27 illustrates the same kernel 2702, input feature-map 2700, output feature map 2704 and expected output feature map 2706 of FIGS. 23-26, but with additional intermediate values shown within feature map 2704 (which correspond to a tile that may be referred to as Tile #1). This figure shows the significance of the column-wise operation and how the “region of influence” (RoI) moves to the right as the computation progresses. As the RoI moves to the right, the retired column can be committed to local memory and does not need to be in the active region (performing the positional accumulation). Note that all operations in Tile #1 result in destination updates in the destination indices within (0,0) to (4,4). This is the “region of influence” of Tile #1. The region of influence is computed as (2*WROW_LEN−1)×(2*WCOL_LEN−1). Note that since the zero operands and weights have been suppressed, these operations are implicitly dropped from the multiply-accumulate sequence, thus providing a computational and/or algorithmic advantage of FAST-CNN.

Still further note that the specific linearization sequence chosen allows for the sequential movement of the RoI, allowing for column-wise retiring of the local accumulate buffer. In one aspect, the compression scheme uses an “anchor index” that always should be present in order to demarcate the tile-boundary. For X arrays, element (2,2) may be forced into the array (even if it is a zero value), and this leads to a 1/9 reduction in the compression efficiency. For W arrays this marker element may be (0,0).

Turning now to the next set of figures, various aspects of exemplary hardware implementations of a FAST CNN system will now be described, which provide, among other features, efficient procedures for processing the indexes, including compressing the indexes.

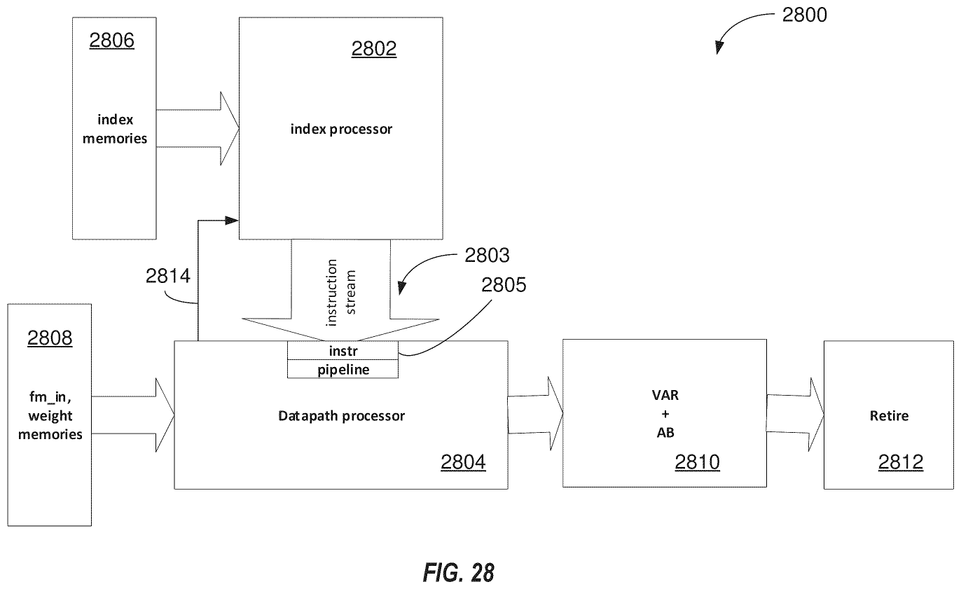

FIG. 28 provides a high level overview of an exemplary hardware architecture 2800 that can be used to implement a FAST CNN system. The hardware architecture includes an index processor (IP) 2802 and a data path processor (DP) 2804. A stream of data-processing instructions 2803 are passed from the IP 2802 to the DP 2804 to enable independent processing/pipelining of an (otherwise) complicated index processing path. More specifically, index processor 2802 receives index values from one or more index memories 2806 and generates a stream of instructions 2803 for feeding into the data path processor 2804. The instruction stream 2803 may be fed into an instruction pipeline 2805 of data path processor 2804. Concurrently, the data path processor 2804 receives feature map input values (fm_in) and weight inputs (w) from feature map/weight memory components 2808. The data path processor 2804 performs convolution operations as described above and feeds the results into a VAR/AB component 2810, which in turn outputs information to a retirement unit 2812.

In some examples, the data path processor 2804 corresponds to or includes the multipliers 1305, accumulators 1325 and Write-MIN 1335 components of FIG. 13. The VAR/AB component 2810 may correspond to or include the VAR 1340 and accumulator buffer (AB) 1350 of FIG. 13. The retirement unit 2812 may correspondence to or include the RELU/pooling 1370 of FIG. 13. Note also that the memory components 2806 and 2808 may correspond to or include the memory components of FIGS. 1 and 2, such as the STMC 250 of FIG. 2. The index processor 2802 is comprised of components that are not separately shown in FIG. 13. The stream interface between the index processor and data path processor may be a standard FIFO operation where the “producer” or “writer” (in this case the IP 2802) writes into the stream when the stream is not full. The FIFO itself may be instantiated outside the stream generation logic. In some examples, feedback is provided from the data path processor 2804 to the index processor 2802 along a feedback line 2814. This enables, e.g., the instruction streams 2803 to be precomputed by the index processor 2802 and fed over a first in first out (FIFO) queue (not shown) to the data path processor 2804 to smooth over possible pipeline bubbles/stalls that might otherwise occur during processing. In some examples, an extra clock cycle may be provided to give the index processor 2802 time to stop when the FIFO becomes full.

The following tables set forth exemplary parameters that may correspond to the instructions streams that pass from the index processor 2802 to the data path processor 2804.

TABLE I provides an exemplary tile-pump feature-map stream (TP FM stream). This provides a stream of the number of entries to extract from the feature-map memory.

TABLE I

| Data type | Total Width |
|---|---|
| Uint | CLOG2(K_SIZE + 1) |
| | Where K_SIZE = W_ROWS*W_COLS |

TABLE II provides an exemplary tile-pump weights stream (TP Wt stream). This provides a stream of the number of entries to extract from the feature-map memory.

TABLE II

| Data type | Total Width |
|---|---|
| Uint | CLOG2(TILE_LEN + 1) |
| | Where TILE_LEN = W_ROWS*W_COLS |

TABLE III provides an exemplary tile-pump unroll stream (TP unroll stream). This stream generates the unroll schedule for all lanes of the DP, i.e., this is the index schedule of a crossbar processor within the DP 2804. Each element of the array represents one lane, as tile boundary conditions may need some lanes to be stalled. The fm_idx_vld indicates which of the lane streams are valid (left justified).

TABLE III

| Data type (struct) | Total Width |
|---|---|
| Uint fm_idx[LANES] | CLOG2(K_SIZE) (each entry of array) |
| Uint w_idx[LANES] | CLOG2(K_SIZE) (each entry of array) |
| Uint fm_idx_vld | CLOG2(K_SIZE + 1) |
| | Where K_SIZE = W_ROWS*W_COLS |

In this example, if the kernel size is 3×3, and LANES=8, then
Fm_idx is 4*8=32-bits wide
W_idx is 4*8=32-bits wide
Fm_idx_vld=4-bits wide.

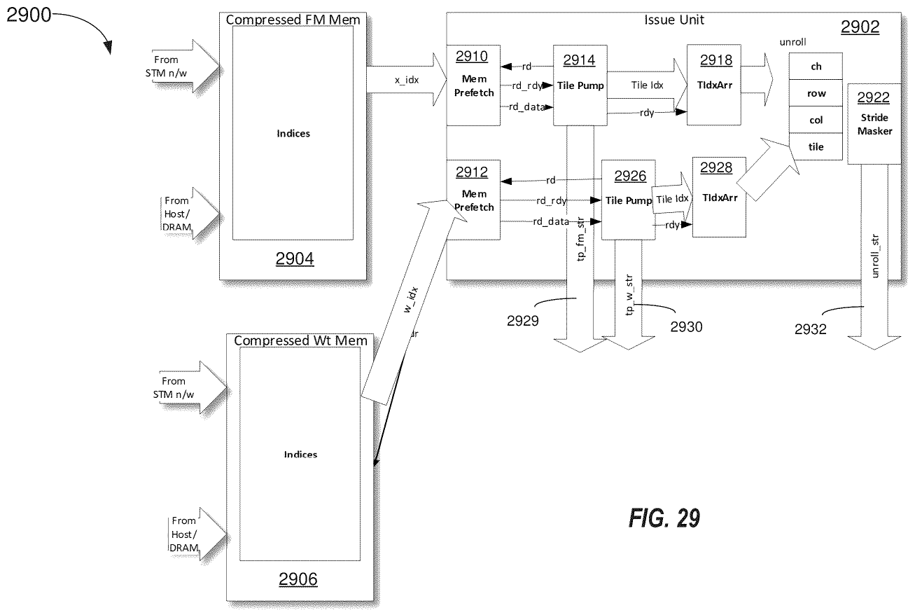

FIG. 29 illustrates features of an exemplary index processor 2900. The index processor 2900 of FIG. 29 includes an issue unit 2902 and a compressed feature map index memory 2904 for storing x_idx indices, as well as a compressed weight memory 2906 for storing x_idx weight indices. (FIG. 29 differs somewhat from the embodiment of FIG. 23, in which the index memories are separate components from the index processor.) Feature map index memory 2904 receives information from a sparse tensor memory (STM, e.g. STMC 250 of FIG. 2) and from the host or DRAM. See again FIGS. 1 and 2. The weight index memory 2906 likewise receives information from the STM (e.g. STMC 250 of FIG. 2) and from the host or DRAM. Feature map index memory 2904 feeds FM indices (X_IDX) to a first memory prefetch unit 2910 of the issue unit 2902, while the weight index memory 2906 feeds weight indices (W_IDX) to a second memory pre-fetch unit 2912 of the issue unit 2902. Prefetch unit 2910 may fetch X_IDX and prefetch memory 2912 may fetch W_IDX values. For example, prefetch unit 2910 may fetch a TILE_LEN number of X_IDX entries from the compressed FM index memory 2904 and keep the entries available for the tile pump 2914 to use (with minimum latency). Prefetch unit 2912 may operate in a similar manner to fetch and hold a number of w_IDX entries.

Prefetch unit 2910 exchanges information with the index feature map tile pump 2914, which in turn feeds tile indices to a TIdxArr unit 2918 (where TId refers to a tile index and Arr refers to an array) which in turn forwards unroll information (including channel, row, column and tile information) to a stride masker unit 2922. The tile pump 2914 also feeds a tile pump feature map stream to the separate data path processor (not shown in FIG. 29) as shown by output arrow 2924. Concurrently, the weight memory prefetch unit 2912 exchanges signals with a weight tile pump 2926, which feed tile information to another TIdxArr component 2928, which forwards channel, row, column and tile unroll information to the stride masker 2922. The weight tile pump 2926 feeds a tile pump weight stream 2930 as output to the data path processor (not shown in FIG. 29). The tile path feature map stream (tp_fm_str) 2924, the tile pump weight stream (tp_W_str) 2930 and an unroll stream (unroll_str) 2932 generated by the stride masker 2922 comprise the instruction stream provided by the index processor to the data path processor (not shown n FIG. 29). Collectively, the tile pump 2914, tile pump 2926, TIdxArr unit 2918 and the TIdxArr unit 2928 provide an unroll controller or unroll circuit that controls the unrolling of the features maps and the corresponding weights to achieve index-value compression.

Insofar as masking is concerned, note that if the map is not separate, then it might either increase significantly in size or hinder the alignment to memory boundaries. For example: if it takes 1-2 bits to represent the state of the next kernel but the data is accessed on 32-bit boundaries, then the device may either shift the data over (requiring extra computation to shift and unshift the data) or the device sacrifices another 30-31 bits. However, if the device stores the maps separately, then the device does not need to perform an adjustment to all the kernel values. Rather, masking may be performed.

As noted above, the 2D convolution provided in accordance with unroll and compression operations described herein uses a 2-level nested unroll of the weight feature-map matrix over every entry in the weight matrix. As each element-wise product is computed, it is spatially accumulated in the accumulate buffer at the particular index that determined based on the indices of the multiplicands. This compression scheme allows the input feature map to be read sequentially (tile-by-tile) and the accumulate buffer result computed in such a sequence that at most one successive column comes into the “region of influence” of the current tile computation. This allows for the accumulate buffer to be implemented with a single read-only path and single write-only path and a simple address generator. This simplifies the memory control design, including simple sequential address generators, eliminating requirements for expensive cache-like structures and also reduces power.

Turning now to the unroll operations performed by the issue unit 2902 of FIG. 29, the feature map is unrolled in the following order: Channel, Row, Col, Tile. For each tile of the FM, the multiply operations (to be performed by the data path processor of FIG. 23) using the weights tile are unrolled and scheduled.

The following provides pseudo-code for an exemplary unroll operation:

```
  ARR_WALK_K_LOOP:
  for(int k=0; k < csr.csr4; ++k) {
    assert(csr.csr2 < MAX_A);
    b_prefetch(b_ram, b_n_pump, b_arr_prefetch, curr_b_ptr, csr); //prefetch the weights
indices
    b_n_pump = b_arr_pump(b_arr_prefetch); //identify how many weight entries are valid
    n_b_str << b_n_pump; // transmit the instruction to the datapath
    ARR_WALK_J_LOOP:
    for (int j = 0; j < csr.csr2; j += CONST_A) {
      assert(csr.csr3 < MAX_B);
      ARR_WALK_I_LOOP:
      for (int i = 0; i < csr.csr3; i += CONST_B) {
        a_prefetch(a_ram, a_n_pump, a_arr_prefetch, curr_a_ptr, csr); //prefetch the fm
indices
        a_n_pump = a_arr_pump(a_arr_prefetch); //identify how many fm entries are valid
        n_a_str << a_n_pump; //transmit instruction to datapath
        ap_uint<2 * CLOG2(CONST_C) + 1> n_issues = a_n_pump * b_n_pump;
//compute total number of ops for the tile
        n_c_t a_arr_idx = 0, b_arr_idx = 0;
        T_UNROLL:
        for (ap_uint<2 * CLOG2(CONST_C) + 1> iss = 0; iss < n_issues; iss += LANES) {
#pragma HLS PIPELINE II=1 rewind
#pragma HLS LOOP_FLATTEN
          // we know the number of iss needed for a given # of lanes
          unroll_str_t out_val;
          L_UNROLL:
          for (unsigned 1 = 0; 1 < LANES; ++1) {
#pragma HLS UNROLL
            out_val.a_idx((1 + 1) * CLOG2(CONST_C) − 1, 1 * CLOG2(CONST_C)) =
a_arr_idx;
            out_val.b_idx((1 + 1) * CLOG2(CONST_C) − 1, 1 * CLOG2(CONST_C)) =
b_arr_idx;
            b_arr_idx = nxt_b_arr_idx(b_arr_idx, a_arr_idx, a_n_pump);
            a_arr_idx = nxt_a_arr_idx(a_arr_idx, a_n_pump);
          }
          if ((iss + LANES) >= n_issues) // this is the last issue
            out_val.idx_vld = n_issues − iss;
          else
            out_val.idx_vld = LANES;
          unroll_str << out_val;
        }
      }
    }
  }
```

After unroll, the indices are strided by the stride masker 2922 using various stride masks. Exemplary pseudocode for the stride operation as follows:

# precomputing validity for strides - for row and col separately
# valid if both X and W index is even, or both are odd
# finally valid if both row and col are valid
W_idx_unrolled_col_stride_mask = W_idx_unrolled[col]%self.stride == 0
W_idx_unrolled_row_stride_mask = W_idx_unrolled[row]%self.stride == 0
X_idx_unrolled_col_stride_mask = X_idx_unrolled[col] %self.stride == 0
X_idx_unrolled_row_stride_mask = X_idx_unrolled[row] %self.stride == 0
XW_idx_unrolled_col_stride_mask =
~np.logical_xor(X_idx_unrolled_col_stride_mask, W_idx_unrolled_col_stride_mask)
XW_idx_unrolled_row_stride_mask =
~np.logical_xor(X_idx_unrolled_row_stride_mask, W_idx_unrolled_row_stride_mask)
XW_idx_unrolled_stride_mask = np.logical_and(XW_idx_unrolled_col_stride_mask,
XW_idx_unrolled_row_stride_mask)
W_arr_unrolled_strided = W_arr_unrolled[XW_idx_unrolled_stride_mask]
W_idx_unrolled_strided = W_idx_unrolled[XW_idx_unrolled_stride_mask]
X_arr_unrolled_strided = X_arr_unrolled[XW_idx_unrolled_stride_mask]
X_idx_unrolled_strided = X_idx_unrolled[XW_idx_unrolled_stride_mask]

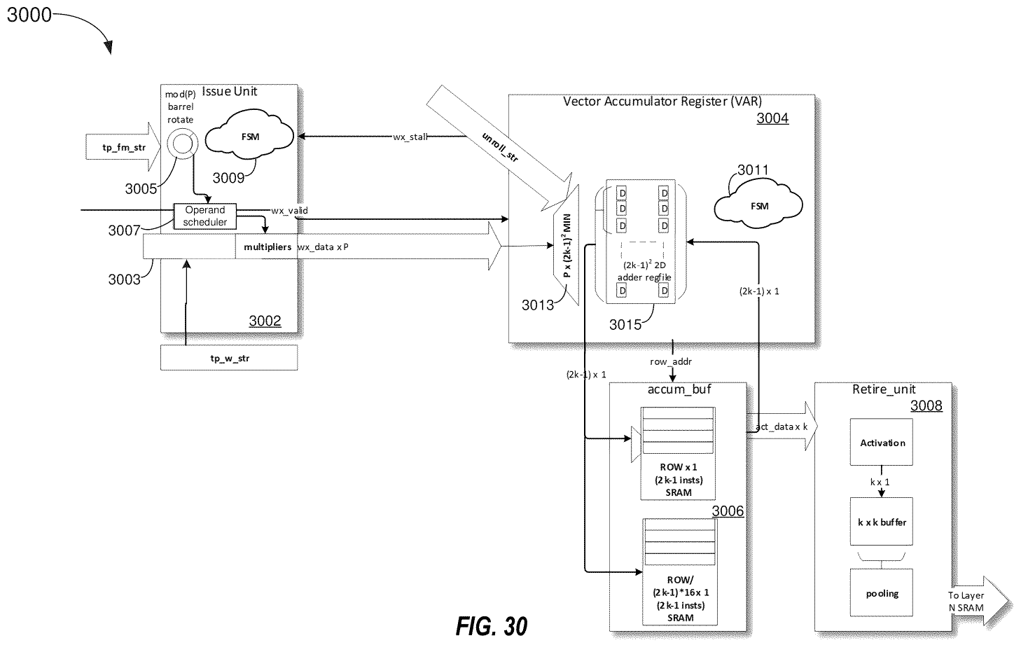

FIG. 30 illustrates an exemplary data path processor 3000, which in this example includes its own issue unit 3002, which receives the tile path feature map stream (tp_fm_str) and the tile pump weight stream (tp_W_str) from the IP processor of FIG. 24. The issue unit 3002 includes multipliers 3003 for generating P output streams of wx_data from the input streams, which are fed to a VAR 3004, which also receives the unroll_str from the IP processor of FIG. 24. Additional components of the issue unit 3002 include a mod(P) barrel rotator 3005 that receives the tile path feature map stream (tp_fm_str) and feeds its values to an operand scheduler 3007, which, in turn, applies the feature maps to the multipliers 3003. A finite-state machine (FSM) 3009 controls the overall operations of the issue unit 3002. A wx_valid value is asserted to the VAR 3004 to denote valid data being sent to it. A wx_stall signal may be returned if the VAR 3004 stalls.

As shown the VAR 3004 includes various components for processing the input data in combination with an accumulator buffer 3006, which includes first and second SRAM buffers for storing the accumulated information. The accumulator buffer 3006 outputs k streams for act_data to a retire unit 3008, which in turn outputs values to a layer of an SRAM. As shown, the retire unit 3008 may include an activation unit (or ReLU unit), a k×k buffer and a pooling unit. These functions components were described above in connection activation and pooling. See, e.g., the descriptions of FIGS. 11 and 13.

Components of the VAR 3004 include an FSM 3011 for controlling the operations of the VAR 3004, a P×(2k−1)² MIN demultiplexer 3013 that demultiplexes the input wx_data×P stream in accordance with the unroll stream, and (2k−1)² 2D adder reg file 3015, which provides the register files that store the data before it is sent to the accumulator buffer 3006 and update the stored data using values received from the accumulate buffer 3015. Note that the overall operations of these components, such as the VAR, the accumulator buffer, etc., were described above with reference to FIG. 13-27. In the following, further details are provided.

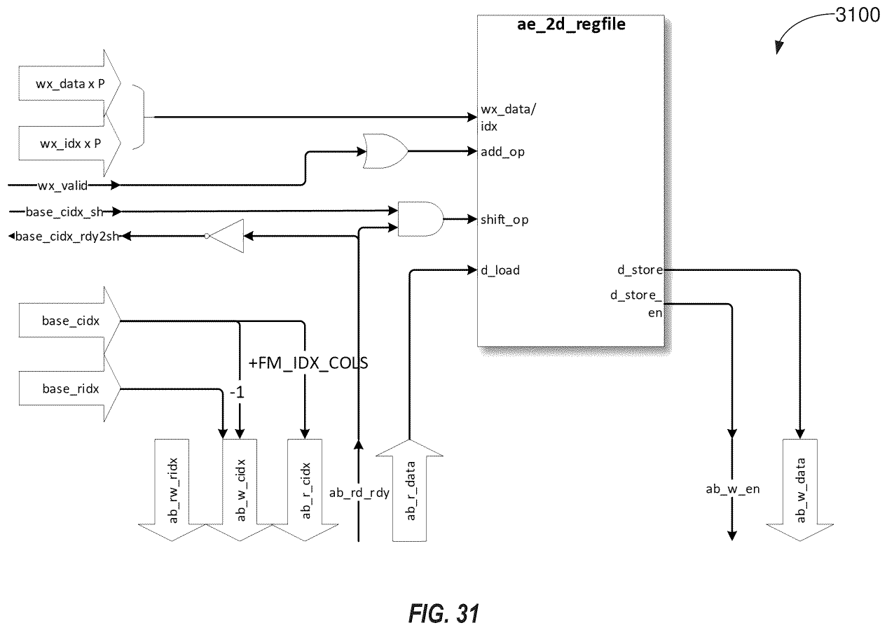

FIG. 31 illustrates exemplary components of a vector accumulator register 3100 of the data path processor, e.g., reg 3015 of FIG. 30. The vector accumulator register 3100 spatially accumulates the individual products of the convolution unroll process. Once a tile is fully processed, the vector accumulator 3100 retires the “out-of-focus” region and brings in the next “in-focus” region from the accumulate buffer. The vector accumulator 3100 may be designed as a 2D reg-file.

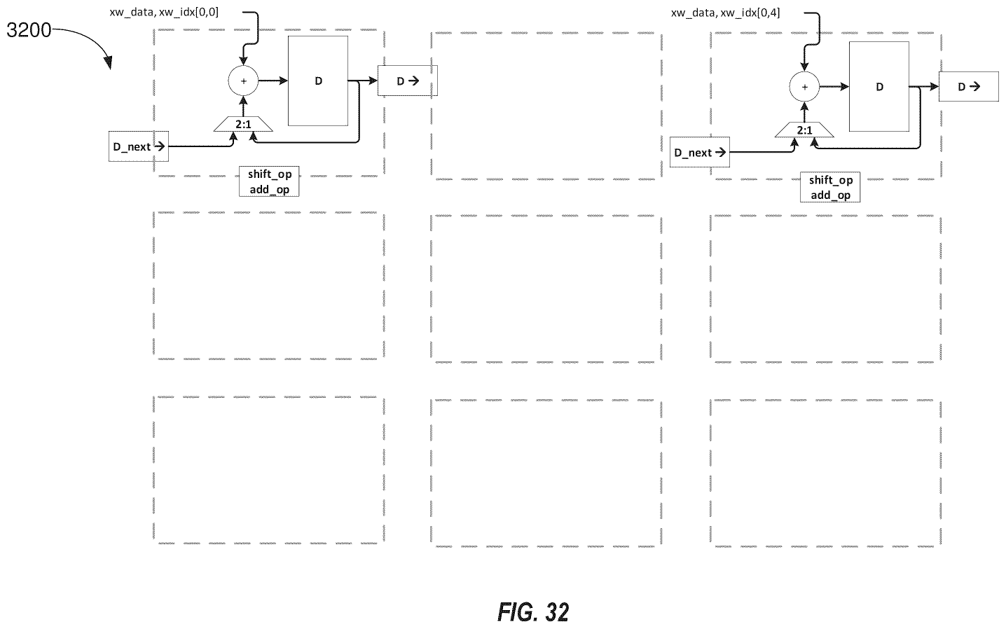

FIG. 32 illustrates an array of accumulator elements 3200 that form the 2D reg file of the vector accumulator register 3100, with tiles corresponding to a (2k−1)×(2k−1) array. In FIG. 32, internal components are only shown for two instances of the array. Each element of the array can be configured in the same manner.

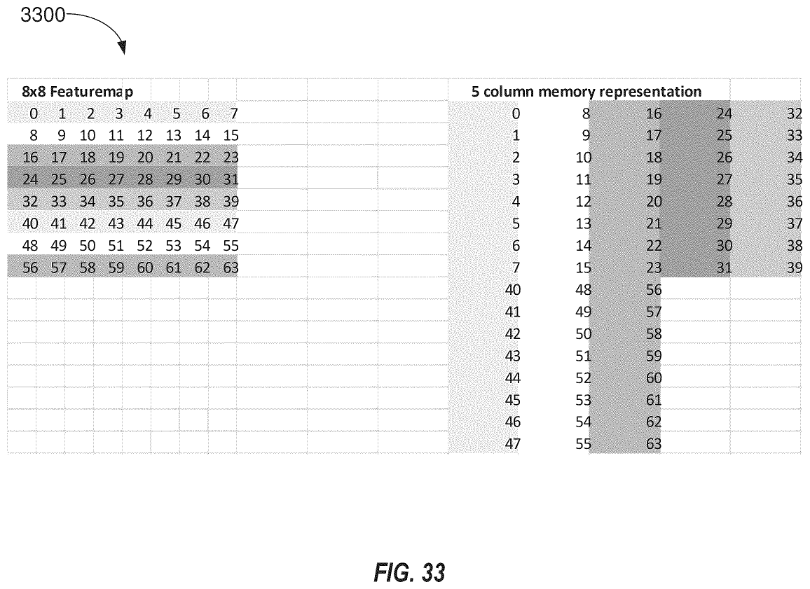

FIG. 33 illustrates exemplary values 3300 for use within the accumulate (or accumulator) buffer 3006 of FIG. 30. The accumulate buffer feeds and retires the data from the VAR 3004 of FIG. 30. In order to keep all lanes of the accumulator occupied, the block uses a read and write bandwidth of (2k−1). For a 3×3 kernel, a 5 bank memory is used.

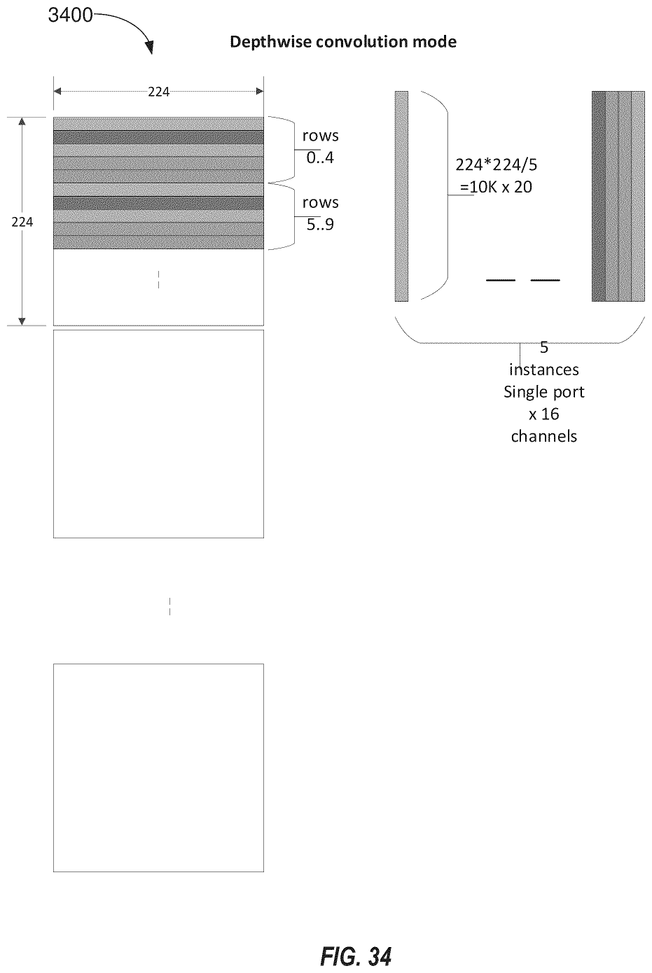

FIG. 34 illustrates aspects of an exemplary depthwise convolution mode 3400. In depthwise convolution mode, the output feature map is not accumulated over different kernels. The representation of this mode within the accumulate buffer is shown in FIG. 34. For further information regarding the depthwise convolution mode, see above, e.g. FIG. 12.

Turning again the compression scheme that may be used, FAST CNN supports multiple compression formats, one of which is index-value compression. Each non-0 feature-map value is stored in a sequence in the memory, along with its relative index within the tile. A “tile-marker” is used to denote the end-of-tile. So if the last value of the tile is in-fact zero, then a zero value forced back on this entry to denote the end-of-tile. The compression may be performed by compression block 1375 of FIG. 13 of similar compression blocks shown in FIGS. 14 and 15.

The following exemplary compile parameters may be used for the compressor block in some implementations:
DATABITS: Bitwidth in Feature Map elements
DATAINLANE: Number of elements in each input memory row
PACKEDBITS: Bits in Compressed data=(DATABITS+Bits in Index)
PACKEDINLANE: Number of elements in each output memory row
MAX_CHAN, MAX_ROW, MAX_COL: Maximum Dimension for Feature Map
MAX_KERNROW, MAX_KERNCOL: Maximum Size of the Kernel/Tile

Note that:
DATAINLANE is limited to only power-of-2 values. It should be bigger than number of kernel rows to not be the bottleneck in the system.
PACKEDBITS is DATABITS+$clog2(MAX_KERNROW)+$clog2(MAX_KERNCOL)
PACKEDINLANE should be more than MAX_KERNROW. It doesn't have to be a multiple of 2. For example, PACKEDBITS=14 and PACKEDINLANE=9 could use 126 bits in a 128 bits wide memory bank.

Exemplary module inputs are:
clock,
reset,
start,
num_chans, num_rows, num_cols,
num_kernrows, num_kerncols,
kern_elements,
part_row, part_col, part_height, part_width,
part_available,
part_offset,
row_offset,
tilerow_offset,
chan_offset,

Note also that in some examples:
start should be asserted after all configuration inputs are set.
kern_elements=num_kernrows*num_kerncols; precomputed input only necessary when FLATTENED is defined. Indicates the number of elements in the tile.
part_available indicates there are more partitions to be processed. Should be high at the beginning (since start is asserted) until at least the first part_read signal-- Since at least one partition needs to be available. For N partitions, it should stay asserted until the N-th part_read strobe. The behavior is similar to the empty signal of a FIFO queue.
part_row, part_col, part_height, part_width can be set and are read after the cycle part_read signal is asserted.
part_offset=offset of the first element in the partition=part_row*num_cols+part_col; precomputed.
row_offset=offset between two rows; typically=number of columns
tilerow_offset=offset between first element of one tile below another=number of columns*number of kernel rows
chan_offset=offset between two channels first elements; =number of rows*columns

Exemplary module outputs are:
ready,
done,
part_read,
mem_read_addr,
mem_read,
mem_write_addr,
mem_write,
mem_write_data

Note also that in some examples:
ready indicates the module is ready to take a start signal. It de-asserts in the next cycle of start is received. It asserts high again after the cycle done is asserted.
done indicates the current task is complete. The output memory is in valid state and the system will be ready in next cycle.
part_read is asserted to indicate a partition is read from the input. The partition data is read in the cycle after it's asserted.
mem_read_addr and mem_read is set to read input memory. The data is expected in the cycle after address and read is valid.
mem_write_addr, mem_write_data are valid on the same cycle as mem_write is asserted. Instead of writing to a memory, mem_write can be used as a strobe for streaming source, since the address only goes up like a counter. It doesn't have to be saved in memory.

At least some precomputed values may be used. The different offset inputs are multiplication operations using feature map dimensions. They can be precomputed in the software and passed down as configuration values.

Insofar as partitioning is concerned, partition inputs may be used that are designed to be read as if from a FIFO queue with registered output. The FIFO's empty signal can be passed down to part_available. The partition information needs to be visible to the module in the cycle following part_read. There needs to be at least one partition set to the system. The following code snippet (or pseudocode) can set the inputs for one partition.

reg pavail;
wire part_row = 32′h00; // ... and similar
always @(posedge clk or negedge reset_n)
pavail <= (~reset_n ?1 : (part_read ? 0 : (done ? 1 : pavail))

For cases when there are no partitions, the partition start point may be set to (0, 0) and dimension to (num_rows, num_cols) of the Feature Map.

Note that, in the illustrative implementation, there are three units inside the compressor--Reader Unit, TileCache and Compactor. Data is streamed from one unit to the next. The Reader Unit takes the feature map dimensions and starts reading data from one end. For example, consider the following matrix:

| | C0 | C1 | C2 | C3 | C4 | C5 |
|----|----|----|----|----|----|----|
| R0 | 01 | 02 | 03 | 04 | 05 | 06 |
| R1 | 07 | 08 | 09 | 10 | 11 | 12 |
| R2 | 13 | 14 | 15 | 16 | 17 | 18 |
| R3 | 19 | 20 | 21 | 22 | 23 | 24 |
| R4 | 25 | 26 | 27 | 28 | 29 | 30 |
| R5 | 31 | 32 | 33 | 34 | 35 | 36 |
| R6 | 37 | 38 | 39 | 40 | 41 | 42 |

The corresponding memory representation may be:

| | L0 | L1 | L2 | L3 |
|-----|----|----|----|----|
| A00 | 01 | 02 | 03 | 04 |
| A01 | 05 | 06 | 07 | 08 |
| A02 | 09 | 10 | 11 | 12 |
| A03 | 13 | 14 | 15 | 16 |
| A04 | 17 | 18 | 19 | 20 |
| A05 | 21 | 22 | 23 | 24 |
| A06 | 25 | 26 | 27 | 28 |
| A07 | 29 | 30 | 31 | 32 |
| A08 | 33 | 34 | 35 | 36 |
| A09 | 37 | 38 | 39 | 40 |
| A10 | 41 | 42 | 00 | 00 |

The first column of tile for a 3×3 kernel needs to read data from locations R0C0 at A00-L0, RIC0 at A01-L2, and R2C0 at A03-L0. We keep three pointers—P0, P1, P2—for these locations. The first read for P0 at line A00 returns 01-02-03-04. The value 04 is unnecessary for the kernel. But it will be read on the next tile anyway. So, all four elements are kept and the whole line is sent to TileCache. P0 is incremented by 4 to point to A01-L0. The second read for P1 at line A01 returns 0506-07-08. The procedure only needs 07-08 for this tile. So, the line 05-06-07-08 is shifted by the offset 2 (L2) and goes to TileCache as 07-08-00-00. The third read for P2 at line A03 reads 13-14-15-16 and all 4 elements are kept as before. P2 increments by 4. The same process repeats until each pointer crosses the boundary. During this time it reads the elements in all the tiles in a row. Then it starts for the next row of tiles in the same way.

In an illustrative example, the data that passes to TileCache may be:

| Read Set 1 | Read Set 2 |
|---|---|
| Row0: 01--02--03--04 | 05--06--07--08 |
| Row1: 07--08--00--00 | 09--10--11--12 |
| Row2: 13--14--15--16 | 17--18--19--20 |

The last elements in the last read of a row may be outside the tiles (like 19--20 in Row2-Read2). The unnecessary reads happen only at the very first and last reads for a row. Total number of unnecessary reads cannot exceed num_rows*DATAINLANE.

The TileCache Unit receives memory lines from the reader with corresponding row id. Each line gets stored in a different FIFO queue for the corresponding row. There is an active buffer for each row, which, when empty, reads one line from the queue. Only when all the buffers are non-empty, it starts emitting one column at a time. In an illustrative example, the active buffer is as follows after all the rows have their first data:

| Buffer | Queue |
|---|---|
| Row0: 01--02--03--04 | 05--06--07--08 |
| Row1: 07--08--00--00 | 09--10--11--12 |
| Row2: 13--14--15--16 | 17--18--19--20 |

The TileCache Unit then emits the first column data: 01--07-13 for the compactor with their row, column index attached. Rest of the buffer is shifted once. After first emit:

| Buffer | Queue |
|---|---|
| Row0: 02--03--04--00 | 05--06--07--08 |
| Row1: 08--00--00--00 | 09--10--11--12 |
| Row2: 14--15--16--00 | 17--18--19--20 |

The 2nd emit (02-08-14) makes Row 2 buffer empty and pulls from the queue.

| Buffer | Queue |
|---|---|
| Row0: 03--04--00--00 | 05--06--07--08 |
| Row1: 09--10--11--12 | 00--00--00--00 |
| Row2: 15--16--00--00 | 17--18--19--20 |

This process repeats until all columns in the row is emitted. The remaining elements in the buffer in the end (07-08 and 19-20) are discarded.

The reader can process DATAINLANE elements in one cycle. TileCache processes num_kernrow elements in a cycle. The throughput is limited by the smaller among them.

The Compactor removes the zero elements and make the remaining elements contiguous. The column from TileCache moves through num_kernel_row stages.

| Cycle 1 | Cycle 2 | Cycle 3 | Cycle 4 | Cycle 5 |
| Stage 1 | Stage 2 | Stage 3 | Stage 4 | Stage 5 |
|---------|---------|---------|---------|---------|
| 15 | 15 | 15 | 15 | 15 |
| 0 | 27 | 27 | 27 | 27 |
| 27 | 0 | 39 | 39 | 39 |
| 0 | 39 | 0 | 0 | 0 |
| 39 | 0 | 0 | 0 | 0 |

After that, the elements are shifted to fill a write buffer and the write buffer is written to the memory when it is full.

### Additional Exemplary Methods and Embodiments

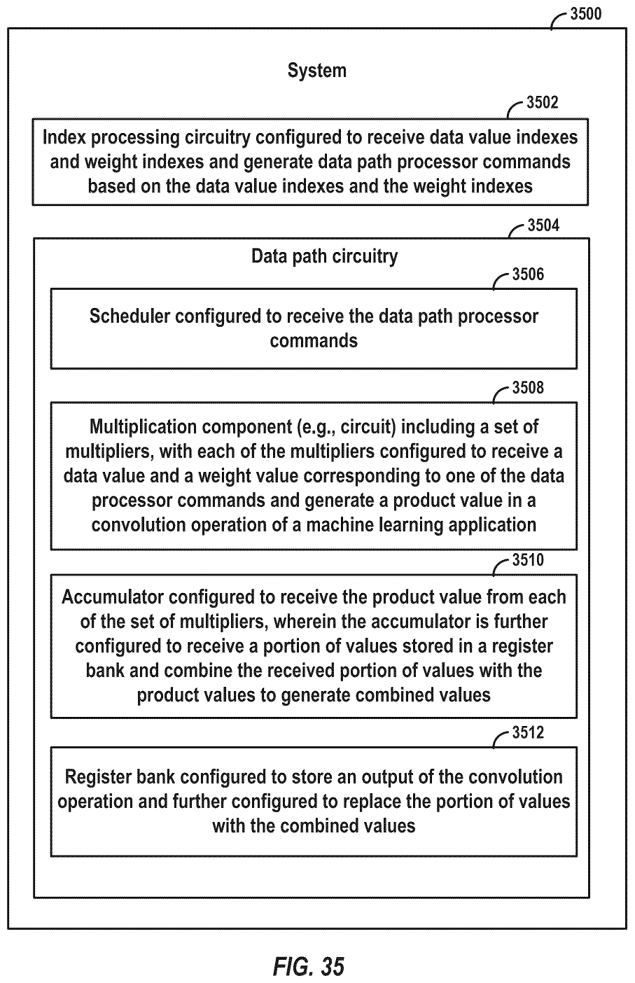

FIG. 35 illustrates an exemplary system 3500 that includes index processing circuitry 3502 (e.g., index processor 2802) configured to receive data value indexes and weight indexes and generate data path processor commands based on the data value indexes and the weight indexes. The system 3500 also includes data path circuitry 3504 (e.g., data path processor 2804) that includes a scheduler 3506 (e.g., scheduler 3007 of FIG. 30) configured to receive the data path processor commands and a multiplication component (e.g., circuit) 3506 that includes a set (or plurality) of multipliers (e.g., multipliers 3003 of FIG. 30), with each of the multipliers configured to receive a data value and a weight value corresponding to one of the data processor commands and generate a product value in a convolution operation of a machine learning application. The data path circuitry 3504 also includes accumulator (such as an accumulate buffer) 3510 (e.g., accumulate buffer 3006) configured to receive the product value from each of the set (or plurality) of multipliers, wherein the accumulator is further configured to receive a portion of values stored in a register bank and combine the received portion of values with the product values to generate combined values and a register bank (such as a VAR 3004) configured to store an output of the convolution operation and further configured to replace the portion of values with the combined values. The system 3500 may be, e.g., a computational storage device (CSD). The system 3500 may be configured as part of a data storage controller, such as a NAND controller, with at least some data is stored in a non-volatile memory (NVM) array but the system can be implemented without NVM using, for example, volatile memory.

In some examples, the data path processor commands include a feature map stream and a weight stream. The index processing circuitry includes a first tile pump configured to convert the data value indexes into the feature map stream and a second tile pump configured convert the weight indexes into the weight stream. (See, above, FIG. 29.) The index processing circuitry further includes a stride masker configured to generate an unroll stream from values output from the first tile pump and the second tile pump. (See, above, FIG. 29.) The unroll controller is further configured to unroll the feature maps in the following order: Channel, Row, Column, Tile. The scheduler is configured to receive the feature map stream and the weight stream and to apply the feature map stream and the weight stream to the multiplication circuit. (See, above, FIG. 30.) The register bank, which may be a VAR, is configured to receive the output of the convolution operation and the unroll stream and process the output of the convolution operation in accordance with the unroll stream. (See, above, FIG. 30.) The accumulator may include an accumulator buffer. (See, above, FIG. 30.)

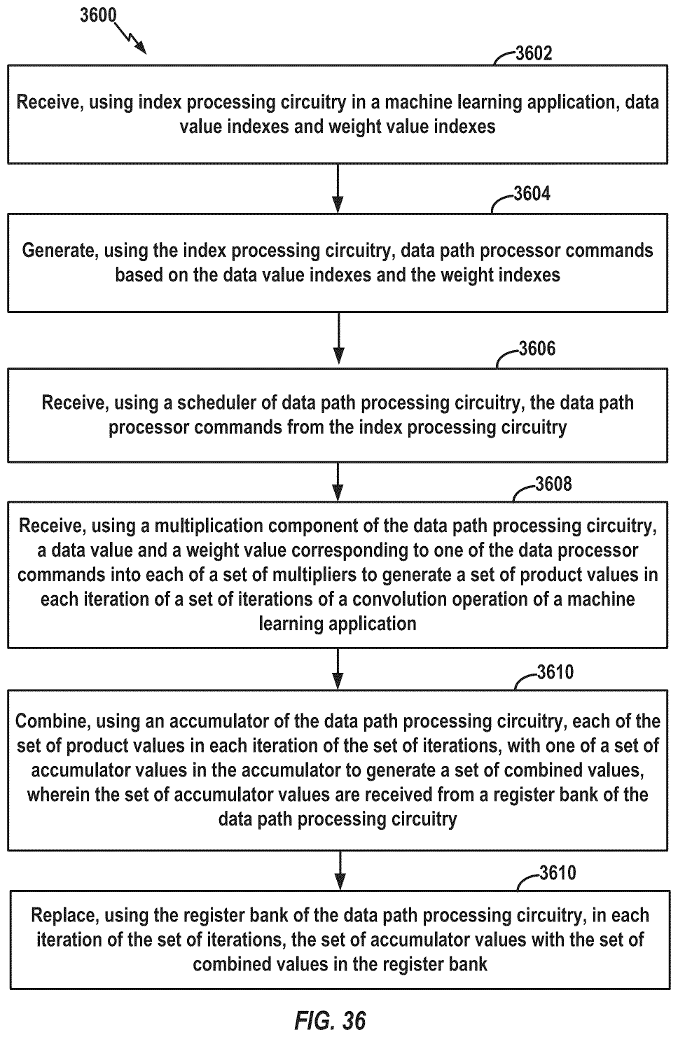

FIG. 36 illustrates an exemplary method 3600 that may be performed by the system of FIG. 35 or by other suitably equipped systems or devices. Briefly, at block 3602, the system receives, using index processing circuitry in a machine learning application, data value indexes and weight value indexes. At block 3604, the system generates, using the index processing circuitry (e.g., index processor 2802), data path processor commands based on the data value indexes and the weight indexes. At block 3606, the system receives, using a scheduler (e.g. scheduler 3007 of FIG. 30) of data path processing circuitry, the data path processor commands from the index processing circuitry. At block 3608, the system receives, using a multiplication component or circuit (e.g., multipliers 3003 of FIG. 30) of the data path processing circuitry, a data value and a weight value corresponding to one of the data processor commands into each of a set (or plurality) of multipliers to generate a set (or plurality) of product values in each iteration of a set (or plurality) of iterations of a convolution operation. At block 3610, the system combines, using an accumulator (e.g., accumulate buffer 3006) of the data path processing circuitry, each of the set (or plurality) of product values in each iteration of the set (or plurality) of iterations, with one of a set (or plurality) of accumulator values in the accumulator to generate a set (or plurality) of combined values, wherein the set (or plurality) of accumulator values are received from a register bank of the data path processing circuitry (e.g., VAR 3004). At block 3612, the system replaces, using the register bank of the data path processing circuitry, in each iteration of the set (or plurality) of iterations, the set (or plurality) of accumulator values with the set of combined values in the register bank.

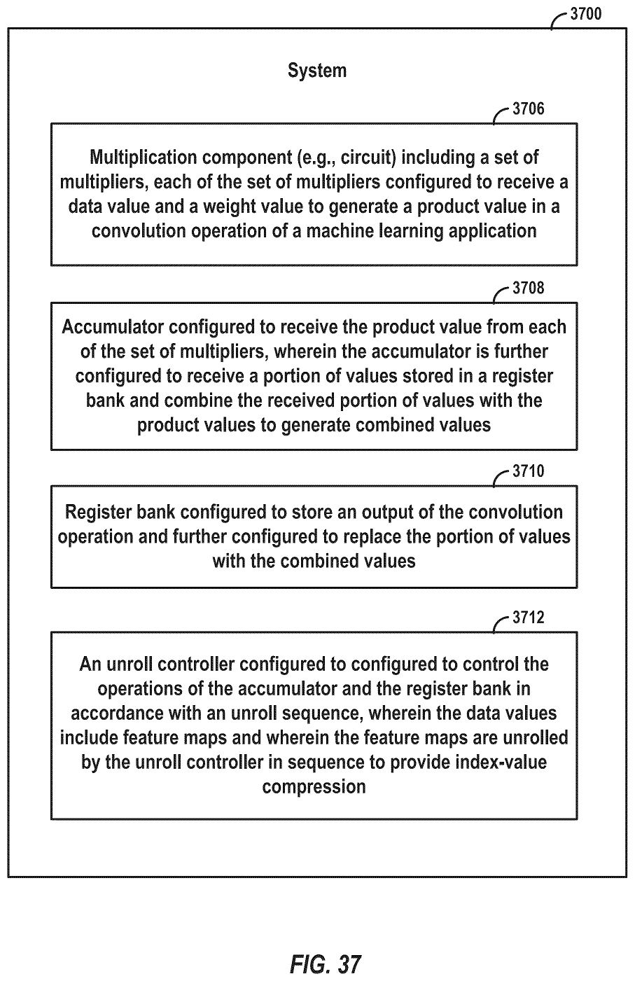

FIG. 37 illustrates an exemplary system 3700 that that includes an unroll controller configured to provide index-value compression. (See, for example, FIG. 29 where, collectively, the tile pump 2914, tile pump 2926, TIdxArr unit 2918 and the TIdxArr unit 2928 provide an unroll controller.) System 3700 includes a multiplication component (e.g., circuit) 3706 including a set (or plurality) of multipliers (e.g., multipliers 3003 of FIG. 30), each of the set (or plurality) of multipliers configured to receive a data value and a weight value to generate a product value in a convolution operation of a machine learning application. System 3700 also includes an accumulator 3708 (e.g., accumulate buffer 3006) configured to receive the product value from each of the set (or plurality) of multipliers, wherein the accumulator is further configured to receive a portion of values stored in a register bank and combine the received portion of values with the product values to generate combined values. System 3700 also includes a register bank 3710 (e.g., VAR 3004) configured to store an output of the convolution operation and further configured to replace the portion of values with the combined values. System 3700 also includes an unroll controller 3712 configured to configured to control the operations of the accumulator and the register bank in accordance with an unroll sequence, wherein the data values include feature maps and wherein the feature maps are unrolled by the unroll controller in sequence to provide index-value compression. The system 3700 may be, e.g., a CSD. The system 3700 may be configured as part of a data storage controller, such as a NAND controller, with at least some data is stored in an NVM array, but the system can be implemented without NVM using, for example, volatile memory.

In some examples, the unroll controller unrolls the feature maps in the following order: Channel, Row, Column, Tile. The feature maps may include a plurality of non-zero feature maps each including a plurality of tiles for storing in sequence in the register bank, the tiles including a plurality of weights. A corresponding index for each tile is stored in an accumulate buffer of the accumulator. The unroll controller may unroll the feature maps in sequence based on the corresponding index values to provide the index-value compression. The unroll controller may be configured to control the register bank to store each non-zero feature map value in sequence along with its corresponding index within the tile and with a tile-marker to denote end-of-tile. The unroll controller may be further configured to insert a zero value into the tile to denote the end-of-tile if a last value of a tile is zero. The unroll controller may be configured to unroll the feature maps so that the features maps and corresponding weights are each accessed only once per convolution iteration. The unroll controller may be configured to perform a 2-level nested unroll of the feature maps. The unroll controller may be configured to provide spatial accumulation of computational products in a buffer of the accumulator at an index determined based on indices of the product values. The unroll controller may be configured to read feature maps sequentially tile-by-tile and control the accumulator to compute values in a sequence with at most one successive column providing a region of influence of a current tile computation. The accumulator may be configured with a single read-only path and a single write-only path.

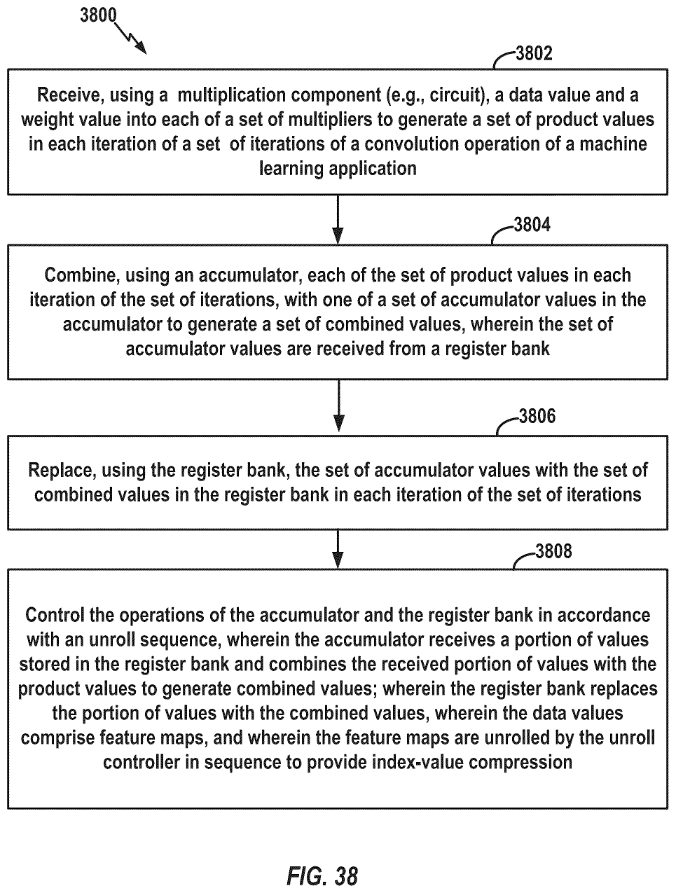

FIG. 38 illustrates an exemplary method 3800 that may be performed by the system of FIG. 37 or by other suitably equipped systems or devices. Briefly, at block 3802, the system receives, using a multiplication component (e.g., circuit), a data value and a weight value into each of a set (or plurality) of multipliers (e.g., multipliers 3003 of FIG. 30), to generate a set (or plurality) of product values in each iteration of a set (or plurality) of iterations of a convolution operation of a machine learning application. At block 3804, the system combines, using an accumulator (e.g., accumulate buffer 3006), each of the set (or plurality) of product values in each iteration of the set (or plurality) of iterations, with one of a set (or plurality) of accumulator values in the accumulator to generate a set (or plurality) of combined values, wherein the set (or plurality) of accumulator values are received from a register bank. At block 3806, the system replaces, using the register bank (e.g., VAR 3004, the set (or plurality) of accumulator values with the set (or plurality) of combined values in the register bank in each iteration of the set (or plurality) of iterations. At block 3808, the system controls the operations of the accumulator and the register bank in accordance with an unroll sequence, wherein the accumulator receives a portion of values stored in the register bank and combines the received portion of values with the product values to generate combined values; wherein the register bank replaces the portion of values with the combined values, wherein the data values comprise feature maps, and wherein the feature maps are unrolled by the unroll controller in sequence to provide index-value compression. See, for example, FIG. 29 where, collectively, the tile pump 2914, tile pump 2926, TIdxArr unit 2918 and the TIdxArr unit 2928 provide an unroll controller.)

### Additional Aspects

Aspects of the subject matter described herein can be implemented in any suitable device. In some examples, the device includes NAND flash memory, such as 3D NAND flash memory. Semiconductor memory devices include volatile memory devices, such as DRAM) or SRAM devices, NVM devices, such as ReRAM, EEPROM, flash memory (which can also be considered a subset of EEPROM), ferroelectric random access memory (FRAM), and MRAM, and other semiconductor elements capable of storing information. See, also, 3D XPoint (3DXP)) memories. Each type of memory device may have different configurations. For example, flash memory devices may be configured in a NAND or a NOR configuration.

Regarding the application of the features described herein to other memories besides NAND: NOR, 3DXP, PCM, and ReRAM have page-based architectures and programming processes that usually require operations such as shifts, XORs, ANDs, etc. If such devices do not already have latches (or their equivalents), latches can be added to support the latch-based operations described herein. Note also that latches can have a small footprint relative to the size of a memory array as one latch can connect to many thousands of cells, and hence adding latches does not typically require much circuit space.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured. The semiconductor memory elements located within and/or over a substrate may be arranged in two or three dimensions, such as a two-dimensional memory structure or a three-dimensional memory structure.

In a two-dimensional memory structure, the semiconductor memory elements are arranged in a single plane or a single memory device level. Typically, in a two-dimensional memory structure, memory elements are arranged in a plane (e.g., in an x-y direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon. The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three-dimensional memory array is arranged so that memory elements occupy multiple planes or multiple memory device levels, thereby forming a structure in three dimensions (i.e., in the x, y and z directions, where the z direction is substantially perpendicular and the x and y directions are substantially parallel to the major surface of the substrate). As a non-limiting example, a three-dimensional memory structure may be vertically arranged as a stack of multiple two-dimensional memory device levels. As another non-limiting example, a three-dimensional memory array may be arranged as multiple vertical columns (e.g., columns extending substantially perpendicular to the major surface of the substrate, i.e., in the z direction) with each column having multiple memory elements in each column. The columns may be arranged in a two-dimensional configuration, e.g., in an x-y plane, resulting in a three-dimensional arrangement of memory elements with elements on multiple vertically stacked memory planes. Other configurations of memory elements in three dimensions can also constitute a three-dimensional memory array.

By way of non-limiting example, in a three-dimensional NAND memory array, the memory elements may be coupled together to form a NAND string within a single horizontal (e.g., x-y) memory device levels. Alternatively, the memory elements may be coupled together to form a vertical NAND string that traverses across multiple horizontal memory device levels. Other three-dimensional configurations can be envisioned wherein some NAND strings contain memory elements in a single memory level while other strings contain memory elements which span through multiple memory levels. Three-dimensional memory arrays may also be designed in a NOR configuration and in a ReRAM configuration.

Typically, in a monolithic three-dimensional memory array, one or more memory device levels are formed above a single substrate. Optionally, the monolithic three-dimensional memory array may also have one or more memory layers at least partially within the single substrate. As a non-limiting example, the substrate may include a semiconductor such as silicon. In a monolithic three-dimensional array, the layers constituting each memory device level of the array are typically formed on the layers of the underlying memory device levels of the array. However, layers of adjacent memory device levels of a monolithic three-dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three-dimensional memory arrays. Further, multiple two-dimensional memory arrays or three-dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements. One of skill in the art will recognize that the subject matter described herein is not limited to the two dimensional and three-dimensional exemplary structures described but cover all relevant memory structures within the spirit and scope of the subject matter as described herein and as understood by one of skill in the art.

The examples set forth herein are provided to illustrate certain concepts of the disclosure. The apparatus, devices, or components illustrated above may be configured to perform one or more of the methods, features, or steps described herein. Those of ordinary skill in the art will comprehend that these are merely illustrative in nature, and other examples may fall within the scope of the disclosure and the appended claims. Based on the teachings herein those skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein.

Aspects of the present disclosure have been described above with reference to schematic flowchart diagrams and/or schematic block diagrams of methods, apparatus, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

The subject matter described herein may be implemented in hardware, software, firmware, or any combination thereof. As such, the terms “function,” “module,” and the like as used herein may refer to hardware, which may also include software and/or firmware components, for implementing the feature being described. In one example implementation, the subject matter described herein may be implemented using a computer readable medium having stored thereon computer executable instructions that when executed by a computer (e.g., a processor) control the computer to perform the functionality described herein. Examples of computer readable media suitable for implementing the subject matter described herein include non-transitory computer-readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

The various features and processes described above may be used independently of one another, or may be combined in various ways. All possible combinations and sub-combinations are intended to fall within the scope of this disclosure. In addition, certain method, event, state or process blocks may be omitted in some implementations. The methods and processes described herein are also not limited to any particular sequence, and the blocks or states relating thereto can be performed in other sequences that are appropriate. For example, described tasks or events may be performed in an order other than that specifically disclosed, or multiple may be combined in a single block or state. The example tasks or events may be performed in serial, in parallel, or in some other suitable manner. Tasks or events may be added to or removed from the disclosed example embodiments. The example systems and components described herein may be configured differently than described. For example, elements may be added to, removed from, or rearranged compared to the disclosed example embodiments.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The word “exemplary” is used herein to mean “serving as an example, instance, or illustration.” Any aspect described herein as “exemplary” is not necessarily to be construed as preferred or advantageous over other aspects. Likewise, the term “aspects” does not require that all aspects include the discussed feature, advantage or mode of operation.

While the above descriptions contain many specific embodiments of the invention, these should not be construed as limitations on the scope of the invention, but rather as examples of specific embodiments thereof. Accordingly, the scope of the invention should be determined not by the embodiments illustrated, but by the appended claims and their equivalents. Moreover, reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise.

The terminology used herein is for the purpose of describing particular aspects only and is not intended to be limiting of the aspects. As used herein, the singular forms “a,” “an” and “the” are intended to include the plural forms as well (i.e., one or more), unless the context clearly indicates otherwise. An enumerated listing of items does not imply that any or all of the items are mutually exclusive and/or mutually inclusive, unless expressly specified otherwise. It will be further understood that the terms “comprises,” “comprising,” “includes” “including,” “having,” and variations thereof when used herein mean “including but not limited to” unless expressly specified otherwise. That is, these terms may specify the presence of stated features, integers, steps, operations, elements, or components, but do not preclude the presence or addition of one or more other features, integers, steps, operations, elements, components, or groups thereof. Moreover, it is understood that the word “or” has the same meaning as the Boolean operator “OR,” that is, it encompasses the possibilities of “either” and “both” and is not limited to “exclusive or” (“XOR”), unless expressly stated otherwise. It is also understood that the symbol “/” between two adjacent words has the same meaning as “or” unless expressly stated otherwise. Moreover, phrases such as “connected to,” “coupled to” or “in communication with” are not limited to direct connections unless expressly stated otherwise.

Any reference to an element herein using a designation such as “first,” “second,” and so forth does not generally limit the quantity or order of those elements. Rather, these designations may be used herein as a convenient method of distinguishing between two or more elements or instances of an element. Thus, a reference to first and second elements does not mean that only two elements may be used there or that the first element must precede the second element in some manner. Also, unless stated otherwise a set of elements may include one or more elements. In addition, terminology of the form “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As a further example, “at least one of: A, B, or C” is intended to cover A, B, C, A-B, A-C, B-C, and A-B-C, as well as multiples of the same members (e.g., any lists that include AA, BB, or CC). Likewise, “at least one of: A, B, and C” is intended to cover A, B, C, A-B, A-C, B-C, and A-B-C, as well as multiples of the same members. Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, choosing, establishing, and the like.

What is claimed is:

1. A system comprising:
a multiplication component comprising a plurality of multipliers, each of the plurality of multipliers configured to receive a data value and a weight value to generate a product value in a convolution operation of a machine learning application;
an accumulator configured to receive the product value from each of the plurality of multipliers;
a register bank configured to store an output of the convolution operation; and
an unroll controller configured to control the operations of the accumulator and the register bank in accordance with an unroll sequence,
wherein the accumulator is further configured to receive a portion of values stored in the register bank and combine the received portion of values with the product values to generate combined values,
wherein the register bank is further configured to replace the portion of values with the combined values, and
wherein the data values comprise feature maps and wherein the feature maps are unrolled by the unroll controller in sequence to provide index-value compression.

2. The system of claim 1, wherein the feature maps are configured in accordance with Channel, Row, Column, and Tile features and wherein the unroll controller is further configured to unroll the feature maps in the following order: Channel, Row, Column, Tile.

3. The system of claim 1,
wherein the feature maps comprise a plurality of non-zero feature maps each comprising a plurality of tiles for storing in sequence in the register bank, the tiles comprising a plurality of weights,
wherein a corresponding index value for each tile is stored in an accumulate buffer of the accumulator, and
wherein the unroll controller is further configured to unroll the feature maps in sequence based on the corresponding index values to provide the index-value compression.

4. The system of claim 3, wherein the unroll controller is further configured to control the register bank to store each non-zero feature map value in sequence along with its corresponding index within the tile and with a tile-marker to denote an end-of-tile.

5. The system of claim 4, wherein the unroll controller is further configured to insert a zero value into the tile to denote the end-of-tile if a last value of a tile is zero.

6. The system of claim 1, wherein the unroll controller is further configured to unroll the feature maps so that the features maps and corresponding weights are each accessed only once.

7. The system of claim 1, wherein the unroll controller is further configured to perform a 2-level nested unroll of the feature maps.

8. The system of claim 1, wherein the unroll controller is further configured to provide spatial accumulation of computational products in a buffer of the accumulator at an index determined based on indices of the product values.

9. The system of claim 1, wherein the unroll controller is configured to read feature maps sequentially tile-by-tile and control the accumulator to compute values in a sequence with at most one successive column providing a region of influence of a current tile computation.

10. The system of claim 1, wherein the accumulator is configured with a single read-only path and a single write-only path.

11. A method comprising:
receiving, using a multiplication component, a data value and a weight value into each of a plurality of multipliers to generate a plurality of product values in each iteration of a plurality of iterations of a convolution operation of a machine learning application;
combining, using an accumulator, each of the plurality of product values in each iteration of the plurality of iterations, with one of a plurality of accumulator values in the accumulator to generate a plurality of combined values, wherein the plurality of accumulator values are received from a register bank;
replacing, using the register bank, the plurality of accumulator values with the plurality of combined values in the register bank in each iteration of the plurality of iterations; and
controlling, using an unroll controller, the operations of the accumulator and the register bank in accordance with an unroll sequence,
wherein the accumulator receives a portion of values stored in the register bank and combines the received portion of values with the product values to generate combined values,
wherein the register bank replaces the portion of values with the combined values, and
wherein the data values comprise feature maps and wherein the feature maps are unrolled by the unroll controller in sequence to provide index-value compression.

12. The method of claim 11, wherein the feature maps are configured in accordance with Channel, Row, Column, and Tile features and wherein the feature maps are unrolled in the following order: Channel, Row, Column, Tile.

13. The method of claim 11,
wherein the feature maps comprise a plurality of non-zero feature maps each comprising a plurality of tiles for storing in sequence in the register bank, the tiles comprising a plurality of weights,
wherein a corresponding index value for each tile is stored in an accumulate buffer of the accumulator, and
wherein the feature maps are unrolled in sequence based on the corresponding index values to provide the index-value compression.

14. The method of claim 13, further comprising unrolling the feature maps by controlling the register bank to store each non-zero feature map value in sequence along with its corresponding index within the tile and with a tile-marker to denote an end-of-tile.

15. The method of claim 14, further comprising inserting a zero value into the tile to denote the end-of-tile if a last value of a tile is zero.

16. The method of claim 11, further comprising unrolling the feature maps by so that the features maps and corresponding weights are each accessed only once.

17. The method of claim 11, further comprising unrolling the feature maps by performing a 2-level nested unroll of the feature maps.

18. The method of claim 11, further comprising unrolling the feature maps by providing spatial accumulation of computational products in a buffer of the accumulator at an index determined based on indices of the product values.

19. The method of claim 11, further comprising unrolling the feature maps by reading the feature maps sequentially tile-by-tile and controlling the accumulator to compute values in a sequence with at most one successive column providing a region of influence of a current tile computation.

20. An apparatus comprising:
means for applying a data value and a weight value to each of a plurality of means for multiplying to generate a plurality of product values in each iteration of a plurality of iterations of a convolution operation of a machine learning application;
means for accumulating each of the plurality of product values in each iteration of the plurality of iterations with one of a plurality of accumulator values to generate a plurality of combined values, wherein the plurality of accumulator values are received from a means for registering data;
means for replacing the plurality of accumulator values with the plurality of combined values in the means for registering data in each iteration of the plurality of iterations; and
means for controlling the operations of the means for accumulating and the means for registering in accordance with an unroll sequence,
wherein the means for accumulating receives a portion of values stored in the means for registering data and combines the received portion of values with the product values to generate combined values,
wherein the means for registering data replaces the portion of values with the combined values, and
wherein the data values comprise feature maps and wherein the feature maps are unrolled by the means for controlling in sequence to provide index-value compression.
